(19) United States
(12) Patent Application Publication
(10) Pub. No.: US 2025/0391750 A1
(43) Pub. Date: Dec. 25, 2025

(54) SEMICONDUCTOR DEVICE, SEMICONDUCTOR ASSEMBLY, AND VEHICLE

(71) Applicant: Rohm Co., Ltd., Kyoto-shi, Kyoto (JP)

(72) Inventor: Yoshihisa TSUKAMOTO, Kyoto-shi (JP)

(21) Appl. No.: 19/314,308

(22) Filed: Aug. 29, 2025

Related U.S. Application Data
(63) Continuation of application No. PCT/JP2024/004975, filed on Feb. 14, 2024.

(30) Foreign Application Priority Data
Mar. 6, 2023 (JP) 2023-033629

(51) Int. Cl. H01L 23/495; H01L 23/31; H01L 23/373

(52) U.S. Cl. CPC H01L 23/49575; H01L 23/3107; H01L 23/3735

(57) ABSTRACT

A semiconductor device includes: a supporting conductor including a first obverse surface facing a first side in a thickness direction; a plurality of semiconductor elements including four or more semiconductor elements disposed on the first obverse surface; and a sealing resin covering the plurality of semiconductor elements and the supporting conductor. The plurality of semiconductor elements are disposed side by side in a first direction perpendicular to the thickness direction, and include a first semiconductor element and a second semiconductor element that are located near a center in the first direction. A first distance, which is a distance between a center of the first semiconductor element and a center of the second semiconductor element, is greater than a second distance, which is a distance between the center of one of the first semiconductor element and the second semiconductor element and a center of one of a third semiconductor element and a fourth semiconductor element that is adjacent to the one of the first semiconductor element and the second semiconductor element in the first direction.

### TECHNICAL FIELD

The present disclosure relates to a semiconductor device, a semiconductor device assembly, and a vehicle.

### BACKGROUND ART

Semiconductor devices incorporating a plurality of power switching elements, such as metal oxide semiconductor field effect transistors (MOSFETs) and insulated gate bipolar transistors (IGBTs), have been conventionally known. Such semiconductor devices are mounted in various electronic devices, ranging from industrial devices to home appliances and information terminals, or even to vehicle-mount devices. WO 2019/244372 discloses a conventional semiconductor device. In the semiconductor device disclosed in WO 2019/244372, a plurality of semiconductor chips (semiconductor elements) are disposed on a lead (a conductor). The semiconductor chips are linearly aligned at predetermined intervals in an x direction perpendicular to a thickness direction of the lead.

During the use of the semiconductor device, the semiconductor chips generate heat. In recent years, the amount of heat generated by semiconductor chips has been increasing along with an increase in the current capacity of a semiconductor device. In the semiconductor chips aligned as described above, the interference of heat generated by the semiconductor chips causes a rise in temperature. A semiconductor chip disposed near the center in the x direction in which the semiconductor chips are aligned is greatly affected by thermal interference from an adjacent semiconductor chip, and may reach a high temperature due to heat concentration. The effect of such thermal interference causes an increase in thermal resistance, and prevents a large current from flowing through the semiconductor device.

### BRIEF DESCRIPTION OF THE DRAWINGS

FIG. 1 is a perspective view showing a semiconductor device according to a first embodiment of the present disclosure.

FIG. 2 is a plan view showing the semiconductor device according to the first embodiment of the present disclosure.

FIG. 3 is a plan view showing the semiconductor device according to the first embodiment of the present disclosure.

FIG. 4 is a bottom view showing the semiconductor device according to the first embodiment of the present disclosure.

FIG. 5 is a cross-sectional view taken along line V-V in FIG. 3.

FIG. 6 is a cross-sectional view taken along line VI-VI in FIG. 3.

FIG. 7 is a cross-sectional view taken along line VII-VII in FIG. 3.

FIG. 8 is a cross-sectional view taken along line VIII-VIII in FIG. 3.

FIG. 9 is a schematic plan view showing the arrangement of a plurality of semiconductor elements in the semiconductor device according to the first embodiment of the present disclosure.

FIG. 10 is a schematic view showing a vehicle that includes the semiconductor device according to the first embodiment of the present disclosure.

FIG. 11 is a cross-sectional view showing a first example of a semiconductor device assembly that includes the semiconductor device according to the first embodiment of the present disclosure.

FIG. 12 is a block diagram showing a configuration of the semiconductor device assembly in FIG. 11.

FIG. 13 is a cross-sectional view showing a second example of a semiconductor device assembly that includes the semiconductor device according to the first embodiment of the present disclosure.

FIG. 14 is a schematic plan view showing a variation of the arrangement of the semiconductor elements.

FIG. 15 is a schematic plan view showing a variation of the arrangement of the semiconductor elements.

FIG. 16 is a schematic plan view showing a variation of the arrangement of the semiconductor elements.

FIG. 17 is a schematic plan view showing a variation of the arrangement of the semiconductor elements.

FIG. 18 is a plan view showing a semiconductor device according to a second embodiment of the present disclosure.

FIG. 19 is a cross-sectional view taken along line XIX-XIX in FIG. 18.

FIG. 20 is a cross-sectional view taken along line XX-XX in FIG. 18.

FIG. 21 is a cross-sectional view taken along line XXI-XXI in FIG. 18.

FIG. 22 is a schematic plan view showing the arrangement of a plurality of semiconductor elements in the semiconductor device according to the second embodiment of the present disclosure.

FIG. 23 is a plan view showing a semiconductor device according to a third embodiment of the present disclosure.

FIG. 24 is a schematic plan view showing the arrangement of a plurality of semiconductor elements in the semiconductor device according to the third embodiment of the present disclosure.

FIG. 25 is a schematic view showing a vehicle that includes the semiconductor device according to the third embodiment of the present disclosure.

FIG. 26 is a schematic plan view showing the arrangement of a plurality of semiconductor elements in a semiconductor device according to a first variation of the third embodiment.

FIG. 27 is a schematic plan view showing the arrangement of the plurality of semiconductor elements in the semiconductor device according to the first variation of the third embodiment.

FIG. 28 is a schematic plan view showing the arrangement of the plurality of semiconductor elements in the semiconductor device according to the first variation of the third embodiment.

FIG. 29 is a schematic plan view showing the arrangement of the plurality of semiconductor elements in the semiconductor device according to the first variation of the third embodiment.

### DETAILED DESCRIPTION OF EMBODIMENTS

The following describes preferred embodiments of the present disclosure in detail with reference to the drawings.

The terms such as “first”, “second” and “third” in the present disclosure are used merely for identification, and are not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a part of an object B”. Further, the phrase “a plane A faces (a first side or a second side) in a direction B” is not limited to the case where the angle of the plane A with respect to the direction B is 90°, but also includes the case where the plane A is inclined to the direction B.

### First Embodiment

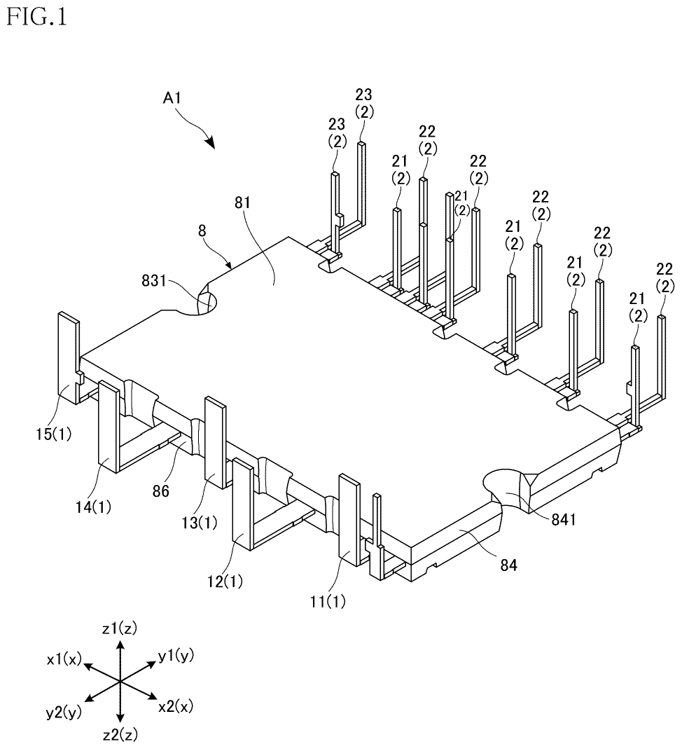

FIGS. 1 to 8 show a semiconductor device according to a first embodiment of the present disclosure. A semiconductor device A1 of the present embodiment includes a plurality of leads 1, a plurality of leads 2, a support 3, a supporting conductor 32, a plurality of semiconductor elements 4, a wiring portion 5, a thermistor 6, a plurality of wires 71, a plurality of wires 72, a plurality of wires 73, a plurality of wires 74, and a sealing resin 8.

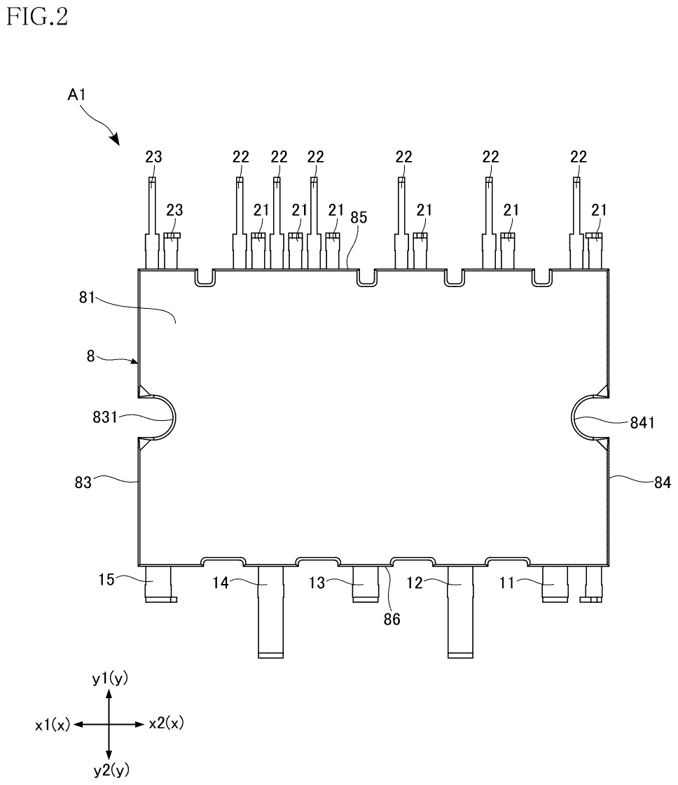

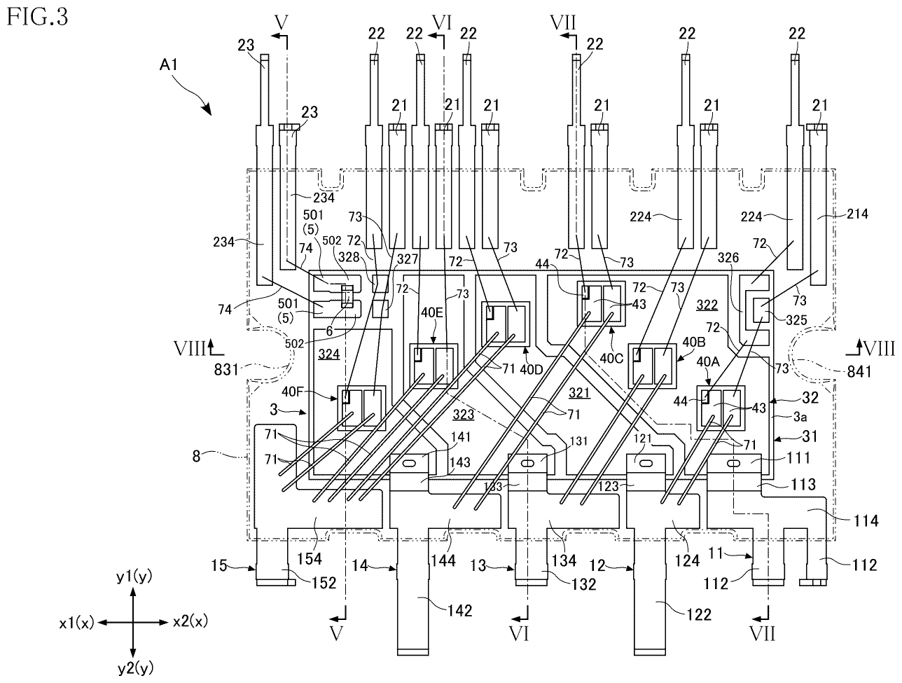

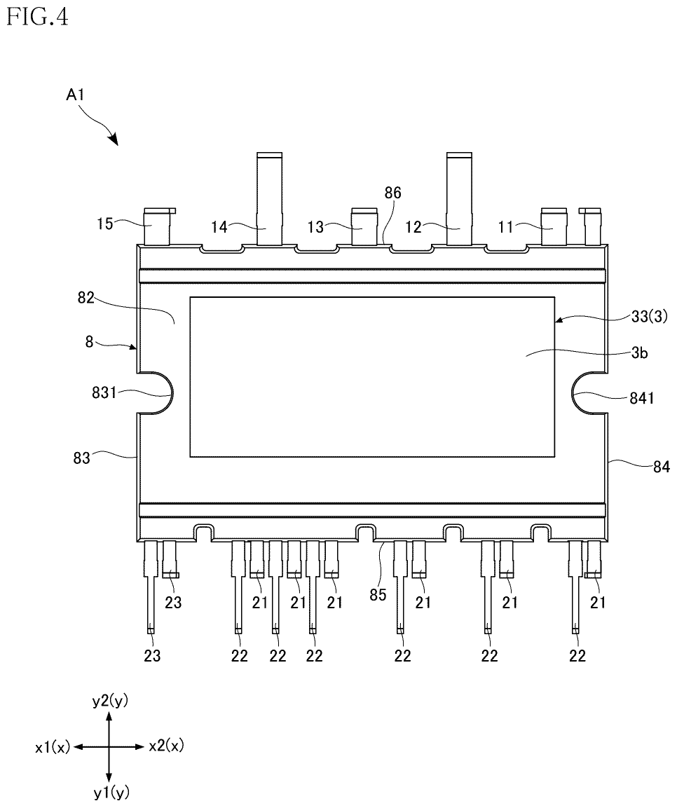

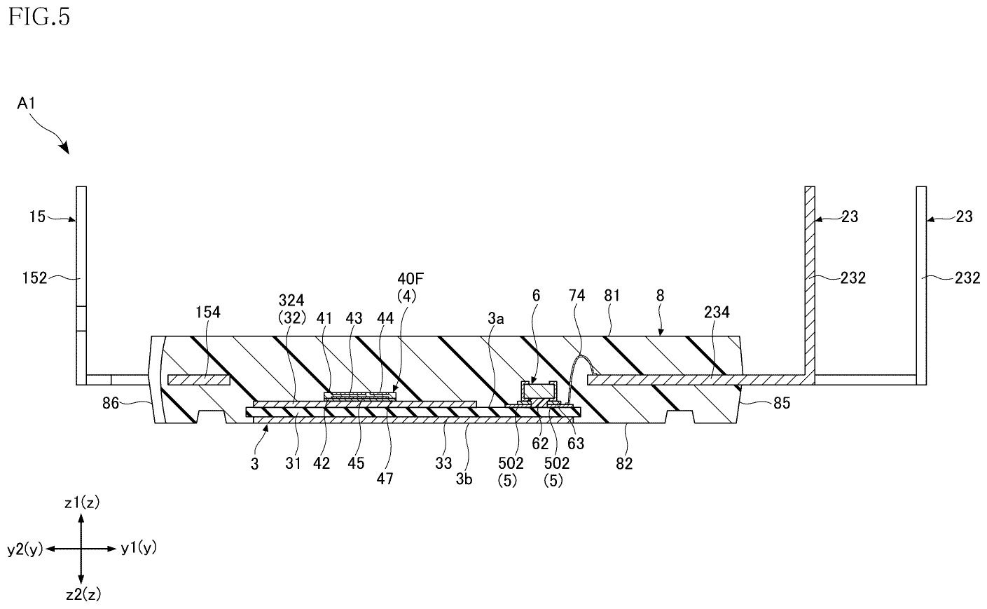

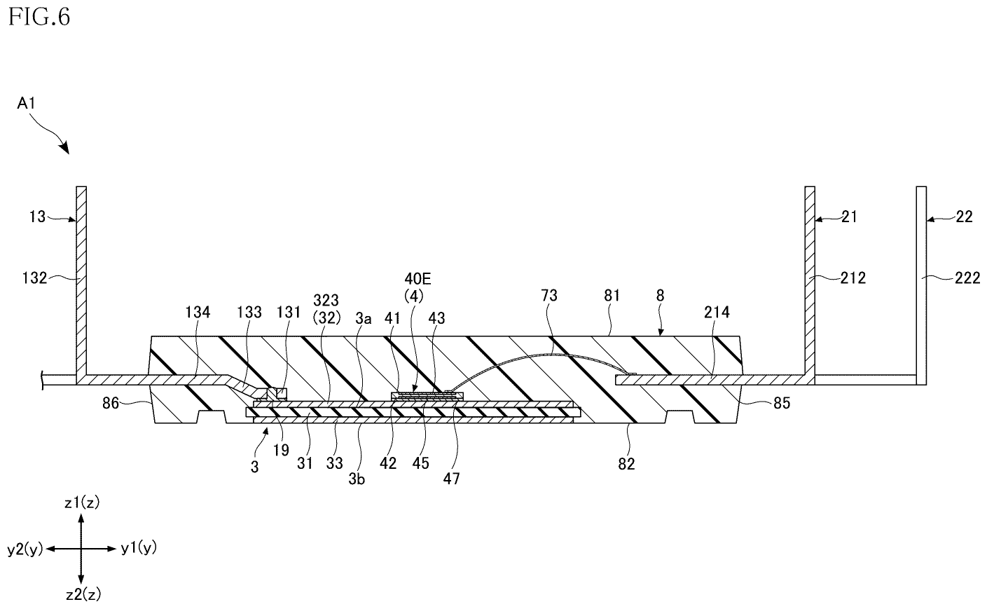

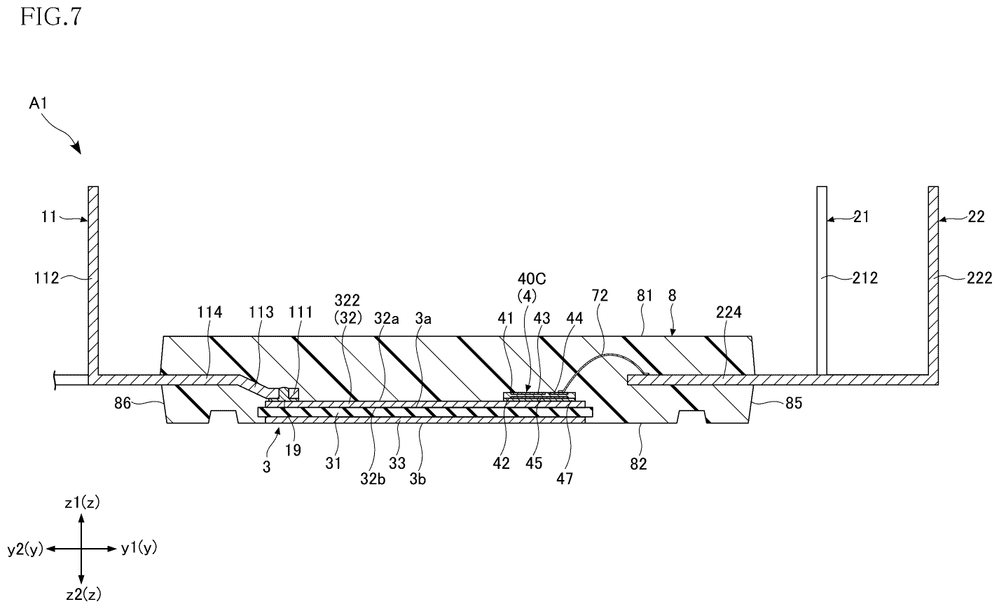

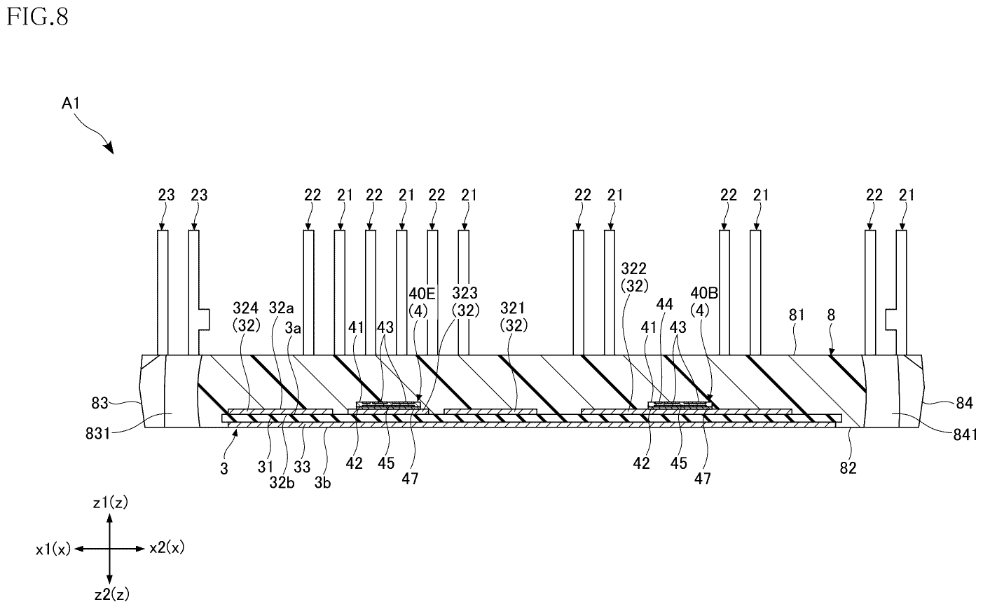

FIG. 1 is a perspective view showing the semiconductor device A1. FIG. 2 is a plan view showing the semiconductor device A1. FIG. 3 is a plan view showing the semiconductor device A1, as seen through the sealing resin 8. FIG. 4 is a bottom view showing the semiconductor device A1. FIG. 5 is a cross-sectional view taken along line V-V in FIG. 3. FIG. 6 is a cross-sectional view taken along line VI-VI in FIG. 3. FIG. 7 is a cross-sectional view taken along line VII-VII in FIG. 3. FIG. 8 is a cross-sectional view taken along line VIII-VIII in FIG. 3. In FIG.

3, the outline of the sealing resin 8 is indicated by an imaginary line (two-dot chain line). FIGS. 5 to 8 omit the wires 71.

In the description of the semiconductor device A1, the thickness direction (plan-view direction) of the support 3 is an example of a “thickness direction” in the present disclosure, and is referred to as a “thickness direction z”. A direction perpendicular to the thickness direction z is an example of a “first direction” in the present disclosure, and is referred to as a “first direction x”. The direction perpendicular to the thickness direction z and the first direction x is an example of a “second direction” in the present disclosure, and is referred to as a “second direction y”. The left side in FIGS. 2 and 3 is an example of a “first side in the first direction” in the present disclosure, and is referred to as an “x1 side in the first direction x”. The right side in FIGS. 2 and 3 is an example of a “second side in the first direction”, and is referred to as an “x2 side in the first direction x”. The upper side in FIGS. 2 and 3 is an example of a “first side in the second direction” in the present disclosure, and is referred to as a “y1 side in the second direction y”. The lower side in FIGS. 2 and 3 is an example of a “second side in the second direction” in the present disclosure, and is referred to as a “y2 side in the second direction y”. The upper side in FIGS. 5 to 8 is an example of a “first side in the thickness direction” in the present disclosure, and is referred to as a “z1 side in the thickness direction z”. The lower side in FIGS. 5 to 8 is an example of a “second side in the thickness direction”, and is referred to as a “z2 side in the thickness direction z”.

As shown in FIG. 3, and FIGS. 5 to 8, the support 3 and the supporting conductor 32 support the semiconductor elements 4. The support 3 is not particularly limited to a specific configuration, and may be an active metal brazing (AMB) substrate or a direct bonded copper (DBC) substrate. In the present embodiment, the support 3 is made of an insulating substrate 31 and a metal layer 33. The support 3 has a second obverse surface 3a and a second reverse surface 3b. The second obverse surface 3a faces the z1 side in the thickness direction z. The second reverse surface 3b faces the opposite side (the z2 side in the thickness direction z) from the second obverse surface 3a. The AMB substrate or the DBC substrate that serves as the support 3 includes the insulating substrate 31, the supporting conductor 32, and the metal layer 33. The overall thickness (the dimension in the thickness direction z) of the insulating substrate 31, the supporting conductor 32, and the metal layer 33 in the support 3 is not particularly limited, and may be approximately 0.4 mm to 3.0 mm.

The insulating substrate 31 is made of a ceramic material with excellent thermal conductivity, for example. Examples of such a ceramic material include silicon nitride (SiN) and alumina (Al₂O3). The material of the insulating substrate 31 is not limited to ceramics, and may be an insulating resin sheet, for example. The shape of the insulating substrate 31 is not particularly limited, and may be a rectangle in plan view. In the present embodiment, the insulating substrate 31 has a rectangular shape elongated in the first direction x as viewed in the thickness direction z. The insulating substrate 31 has the second obverse surface 3a. The second obverse surface 3a is a plane facing the z1 side in the thickness direction z. The thickness of the insulating substrate 31 is not particularly limited, and may be approximately 0.05 mm to 1.0 mm.

The supporting conductor 32 is formed on the second obverse surface 3a of the insulating substrate 31. The constituent material of the supporting conductor 32 contains copper (Cu), for example. The constituent material may contain aluminum (Al) instead of copper. Using the DBC substrate or the like and patterning a copper foil bonded to the second obverse surface 3a, for example, can facilitate forming of the supporting conductor 32 including a first conductor 321 to an eighth conductor 328 described below. The supporting conductor 32 has a first obverse surface 32a and a first reverse surface 32b. The first obverse surface 32a faces the z1 side in the thickness direction z. The first reverse surface 32b faces the opposite side (the z2 side in the thickness direction z) from the first obverse surface 32a, and faces the second obverse surface 3a. The thickness of the supporting conductor 32 is not particularly limited, and may be approximately 0.1 mm to 1.5 mm.

The supporting conductor 32 includes a first conductor 321, a second conductor 322, a third conductor 323, a fourth conductor 324, a fifth conductor 325, a sixth conductor 326, a seventh conductor 327, and an eighth conductor 328. The surfaces of the first conductor 321 to the eighth conductor 328 may be plated with silver (Ag).

The first conductor 321 is disposed near the center in the first direction x on the second obverse surface 3a of the insulating substrate 31. The first conductor 321 supports one of the semiconductor elements 4. The second conductor 322 is disposed on the x2 side in the first direction x relative to the first conductor 321, and is adjacent to the first conductor 321. The second conductor 322 supports one of the semiconductor elements 4. The third conductor 323 is disposed on the x1 side in the first direction x relative to the first conductor 321, and is adjacent to the first conductor 321. The third conductor 323 supports one of the semiconductor elements 4. The fourth conductor 324 is disposed on the x1 side in the first direction x relative to the third conductor 323, and is adjacent to the third conductor 323. The fourth conductor 324 supports one of the semiconductor elements 4.

The fifth conductor 325 and the sixth conductor 326 are disposed near the corner of the insulating substrate 31 on the x2 side in the first direction x and on the y1 side in the second direction y. A wire 73 is bonded to the fifth conductor 325. A wire 72 is bonded to the sixth conductor 326. The seventh conductor 327 and the eighth conductor 328 are disposed near the corner of the insulating substrate 31 on the x1 side in the first direction x and the y1 side in the second direction y. The seventh conductor 327 and the eighth conductor 328 are located on the x1 side in the first direction x relative to the third conductor 323 and on the y1 side in the second direction y relative to the fourth conductor 324. A wire 73 is bonded to the seventh conductor 327. A wire 72 is bonded to the eighth conductor 328. The supporting conductor 32 that supports the semiconductor elements 4 corresponds to an example of a “conductor” in the present disclosure.

The metal layer 33 is bonded to the lower surface (the surface facing the z2 side in the thickness direction z) of the insulating substrate 31. The metal layer 33 is made of the same material as the supporting conductor 32. The metal layer 33 has the second reverse surface 3b. The second reverse surface 3b is a plane facing the z2 side in the thickness direction z. In the present embodiment, the second reverse surface 3b is exposed from the sealing resin 8. A heat dissipating member (e.g., a heat sink), which is not shown in the figures, can be attached to the second reverse surface 3b. A structure (e.g., an AMB substrate or a DBC substrate) made up of the supporting conductor 32 and the support 3 (i.e., the insulating substrate 31 and the metal layer 33) has a thermal capacity of 0.01 to 15 J/K, for example. The structure (e.g., an AMB substrate or a DBC substrate) made up of the supporting conductor 32 and the support 3 has a thermal resistance of 0.0003 to 1.5 K/W, for example.

The wiring portion 5 is formed on the second obverse surface 3a of the insulating substrate 31. The wiring portion 5 is made of a conductive material. The conductive material of the wiring portion 5 is not particularly limited. The conductive material of the wiring portion 5 may contain silver (Ag), copper (Cu), or gold (Au). The following description is provided with an example where the wiring portion 5 contains silver. Note that the wiring portion 5 may contain copper instead of silver, or may contain gold instead of silver or copper. Alternatively, the wiring portion 5 may contain Ag—Pt or Ag—Pd. The method for forming the wiring portion 5 is not particularly limited. For example, the wiring portion 5 may be formed by sintering a paste containing these metals. The thickness of the wiring portion 5 is not particularly limited, and may be approximately 5 μm to 30 μm. The wiring portion 5 is thinner than the supporting conductor 32.

The shape, etc., of the wiring portion 5 is not particularly limited. In the present embodiment, the wiring portion 5 includes two wirings 501 as shown in FIG. 3. The two wirings 501 are disposed near the corner of the insulating substrate 31 on the x1 side in the first direction x and on the y1 side in the second direction y. The two wirings 501 are spaced apart from each other and aligned in the second direction y. Each of the wirings 501 has a pad portion 502. The pad portion 502 is located at the end of the wiring 501 on the x2 side in the first direction x. The two pad portions 502 are bonded to respective terminals of the thermistor 6.

Each of the leads 1 contain a metal, and has a thermal conductivity higher than that of the insulating substrate 31, for example. The metal in each lead 1 is not particularly limited, and may be copper, aluminum, iron (Fe), oxygen-free copper, or any of the alloys thereof (e.g., Cu—Sn alloy, Cu—Zr alloy, Cu—Fe alloy, etc.). The leads 1 may be plated with nickel (Ni). The leads 1 may be formed by pressing a die onto a metal plate, or may be formed by patterning a metal plate by etching. The method for forming the leads 1 is not particularly limited. The thickness of each lead 1 is not particularly limited, and may be approximately 0.4 mm to 0.8 mm. The leads 1 are spaced apart from each other.

In the present embodiment, the leads 1 include a lead 11, a lead 12, a lead 13, a lead 14, and a lead 15. The leads 11, 12, 13, 14, and 15 form the conductive paths to the semiconductor elements 4, and protrude from the side surface (a resin side surface 86 described below) of the sealing resin 8 that faces the y2 side in the second direction y (the lower side in FIG. 2).

The lead 11 is disposed on the supporting conductor 32. In the present embodiment, the lead 11 is disposed on the second conductor 322. As shown in FIG. 7, the lead 11 is bonded to the second conductor 322 via a conductive bonding material 19. The conductive bonding material 19 may be any material capable of bonding the lead 11 to the second conductor 322 and electrically connecting the lead 11 and the second conductor 322. The conductive bonding material 19 may be silver paste, copper paste, or solder, for example.

The configuration of the lead 11 is not particularly limited. In the present embodiment, the lead 11 is divided into a connecting end portion 111, a protruding portion 112, an inclined portion 113, and a parallel portion 114 for description, as shown in FIGS. 3 and 7.

The connecting end portion 111 is rectangular in plan view and bonded to the second conductor 322. The connecting end portion 111 is electrically bonded to the end of the second conductor 322 on the y2 side in the second direction y via the conductive bonding material 19. The inclined portion 113 and the parallel portion 114 are covered with the sealing resin 8. The inclined portion 113 is connected to the connecting end portion 111 and the parallel portion 114, and is inclined relative to the connecting end portion 111 and the parallel portion 114. The parallel portion 114 is connected to the inclined portion 113 and the protruding portion 112, and is parallel to the connecting end portion 111. The protruding portion 112 is the portion of the lead 11 that protrudes from the sealing resin 8, and is connected to an end of the parallel portion 114. In the illustrated example, two protruding portions 112 are provided with a space therebetween in the first direction x. The protruding portions 112 protrude to the side opposite from the connecting end portion 111 in the second direction y. The protruding portions 112 may be used to electrically connect the semiconductor device A1 to an external circuit. In the illustrated example, the protruding portions 112 are bent toward the side that the second obverse surface 3a of the insulating substrate 31 faces in the thickness direction z.

The lead 12 is disposed on the supporting conductor 32. In the present embodiment, the lead 12 is disposed on the first conductor 321. The lead 12 is bonded to the first conductor 321 via a conductive bonding material. The configuration of the lead 12 is not particularly limited. In the present embodiment, the lead 12 is divided into a connecting end portion 121, a protruding portion 122, an inclined portion 123, and a parallel portion 124 for description, as shown in FIG. 3. The connecting end portion 121 is rectangular in plan view and bonded to the first conductor 321. The connecting end portion 121 is electrically bonded to the end of the first conductor 321 on the y2 side in the second direction y via the conductive bonding material. The inclined portion 123 and the parallel portion 124 are covered with the sealing resin 8. The inclined portion 123 is connected to the connecting end portion 121 and the parallel portion 124, and is inclined relative to the connecting end portion 121 and the parallel portion 124. The parallel portion 124 is connected to the inclined portion 123 and the protruding portion 122, and is parallel to the connecting end portion 121. A wire 71 is bonded to the parallel portion 124. The protruding portion 122 is the portion of the lead 12 that protrudes from the sealing resin 8, and is connected to an end of the parallel portion 124. The protruding portion 122 protrudes to the side opposite from the connecting end portion 121 in the second direction y. The protruding portion 122 may be used to electrically connect the semiconductor device A1 to an external circuit. In the illustrated example, the protruding portion 122 is bent toward the side that the second obverse surface 3a of the insulating substrate 31 faces in the thickness direction z.

The lead 13 is disposed on the supporting conductor 32. In the present embodiment, the lead 13 is disposed on the third conductor 323. As shown in FIG. 6, the lead 13 is bonded to the third conductor 323 via a conductive bonding material 19. The configuration of the lead 13 is not particularly limited. In the present embodiment, the lead 13 is divided into a connecting end portion 131, a protruding portion 132, an inclined portion 133, and a parallel portion 134 for description, as shown in FIGS. 3 and 6.

The connecting end portion 131 is rectangular in plan view and bonded to the third conductor 323. The connecting end portion 131 is electrically bonded to the end of the third conductor 323 on the y2 side in the second direction y via the conductive bonding material 19. The inclined portion 133 and the parallel portion 134 are covered with the sealing resin 8. The inclined portion 133 is connected to the connecting end portion 131 and the parallel portion 134, and is inclined relative to the connecting end portion 131 and the parallel portion 134. The parallel portion 134 is connected to the inclined portion 133 and the protruding portion 132, and is parallel to the connecting end portion 131. A wire 71 is bonded to the parallel portion 134. The protruding portion 132 is the portion of the lead 13 that protrudes from the sealing resin 8, and is connected to an end of the parallel portion 134. The protruding portion 132 protrudes to the side opposite from the connecting end portion 131 in the second direction y. The protruding portion 132 may be used to electrically connect the semiconductor device A1 to an external circuit. In the illustrated example, the protruding portion 132 is bent toward the side that the second obverse surface 3a of the insulating substrate 31 faces in the thickness direction z.

The lead 14 is disposed on the supporting conductor 32. In the present embodiment, the lead 14 is disposed on the fourth conductor 324. The lead 14 is bonded to the fourth conductor 324 via a conductive bonding material. The configuration of the lead 14 is not particularly limited. In the present embodiment, the lead 14 is divided into a connecting end portion 141, a protruding portion 142, an inclined portion 143, and a parallel portion 144 for description, as shown in FIG. 3.

The connecting end portion 141 is rectangular in plan view and bonded to the fourth conductor 324. The connecting end portion 141 is electrically bonded to the end of the fourth conductor 324 on the y2 side in the second direction y via the conductive bonding material. The inclined portion 143 and the parallel portion 144 are covered with the sealing resin 8. The inclined portion 143 is connected to the connecting end portion 141 and the parallel portion 144, and is inclined relative to the connecting end portion 141 and the parallel portion 144. The parallel portion 144 is connected to the inclined portion 143 and the protruding portion 142, and is parallel to the connecting end portion 141. A wire 71 is bonded to the parallel portion 144. The protruding portion 142 is the portion of the lead 14 that protrudes from the sealing resin 8, and is connected to an end of the parallel portion 144. The protruding portion 142 protrudes to the side opposite from the connecting end portion 141 in the second direction y. The protruding portion 142 may be used to electrically connect the semiconductor device A1 to an external circuit. In the illustrated example, the protruding portion 142 is bent toward the side that the second obverse surface 3a of the insulating substrate 31 faces in the thickness direction z.

In the present embodiment, the lead 15 is not disposed on the supporting conductor 32, and is supported by the sealing resin 8. The lead 15 does not include any portions corresponding to the connecting end portion 131 and the inclined portion 133 of the lead 13. Note that the lead 15 is not limited to this configuration. In the present embodiment, the lead 15 is divided into a protruding portion 152 and a parallel portion 154 for description, as shown in FIG. 3.

The parallel portion 154 is covered with the sealing resin 8. The parallel portion 154 is parallel to the supporting conductor 32. A wire 71 is bonded to the parallel portion 154. The protruding portion 152 is the portion of the lead 15 that protrudes from the sealing resin 8, and is connected to an end of the parallel portion 154. The protruding portion 152 protrudes from the sealing resin 8 to the y2 side in the second direction y. The protruding portion 152 may be used to electrically connect the semiconductor device A1 to an external circuit. In the illustrated example, the protruding portion 152 is bent toward the side that the second obverse surface 3a of the insulating substrate 31 faces in the thickness direction z.

Each of the leads 2 contain a metal, and has a thermal conductivity higher than that of the insulating substrate 31, for example. The metal in each lead 2 is not particularly limited, and may be copper, aluminum, iron (Fe), oxygen-free copper, or any of the alloys thereof (e.g., Cu—Sn alloy, Cu—Zr alloy, Cu—Fe alloy, etc.). The leads 2 may be plated with nickel (Ni). The leads 2 may be formed by pressing a die onto a metal plate, or may be formed by patterning a metal plate by etching. The method for forming the leads 2 is not particularly limited. The thickness of each lead 2 is not particularly limited, and may be approximately 0.4 mm to 0.8 mm. The leads 2 are spaced apart from each other.

In the present embodiment, the leads 2 include a plurality of leads 21, a plurality of leads 22, and two leads 23. The leads 21 and the leads 22 form conductive paths to source electrodes 43 and gate electrodes 44 (which are described below) of the semiconductor elements 4, and protrude from the side surface of the sealing resin 8 (a resin side surface 85 described below) that faces the y1 side in the second direction y (the upper side in FIG. 2). The two leads 23 form a conductive path to the thermistor 6, and protrude from the side surface of the sealing resin 8 that faces the y1 side in the second direction y.

The leads 21 are not disposed on the supporting conductor 32, and are supported by the sealing resin 8. The leads 21 are disposed at intervals in the first direction x. The configuration of each lead 21 is not particularly limited. In the present embodiment, each of the leads 21 is divided into a protruding portion 212 and a parallel portion 214 for description, as shown in FIGS. 3 and 6.

The parallel portion 214 is covered with the sealing resin 8. The parallel portion 214 is parallel to the supporting conductor 32. A wire 73 is bonded to the parallel portion 214. The protruding portion 212 is the portion of the lead 21 that protrudes from the sealing resin 8, and is connected to an end of the parallel portion 214. The protruding portion 212 protrudes from the sealing resin 8 to the y1 side in the second direction y. The protruding portion 212 may be used to electrically connect the semiconductor device A1 to an external circuit. In the illustrated example, the protruding portion 212 is bent toward the side that the second obverse surface 3a of the insulating substrate 31 faces in the thickness direction z.

The leads 22 are not disposed on the supporting conductor 32, and are supported by the sealing resin 8. The leads 22 are disposed at intervals in the first direction x. Each of the leads 22 is disposed near one of the leads 21 to form a pair with the lead 21. The configuration of each lead 22 is not particularly limited. In the present embodiment, each of the leads 22 is divided into a protruding portion 222 and a parallel portion 224 for description, as shown in FIGS. 3 and 7.

The parallel portion 224 is covered with the sealing resin 8. The parallel portion 224 is parallel to the supporting conductor 32. A wire 72 is bonded to the parallel portion 224. The protruding portion 222 is the portion of the lead 22 that protrudes from the sealing resin 8, and is connected to an end of the parallel portion 224. The protruding portion 222 protrudes from the sealing resin 8 to the y1 side in the second direction y. The protruding portion 222 may be used to electrically connect the semiconductor device A1 to an external circuit. In the illustrated example, the protruding portion 222 is bent toward the side that the second obverse surface 3a of the insulating substrate 31 faces in the thickness direction z.

The two leads 23 are not disposed on the supporting conductor 32, and are supported by the sealing resin 8. The two leads 23 are aligned in the first direction x. The configuration of each lead 23 is not particularly limited. In the present embodiment, each of the leads 23 is divided into a protruding portion 232 and a parallel portion 234 for description, as shown in FIGS. 3 and 5.

The parallel portion 234 is covered with the sealing resin 8. The parallel portion 234 is parallel to the supporting conductor 32. A wire 74 is bonded to the parallel portion 234. The protruding portion 232 is the portion of the lead 23 that protrudes from the sealing resin 8, and is connected to an end of the parallel portion 234. The protruding portion 232 protrudes from the sealing resin 8 to the y1 side in the second direction y. The protruding portion 232 may be used to electrically connect the semiconductor device A1 to an external circuit. In the illustrated example, the protruding portion 232 is bent toward the side that the second obverse surface 3a of the insulating substrate 31 faces in the thickness direction z.

The semiconductor elements 4 are electronic components integral to the function of the semiconductor device A1. In the present embodiment, the semiconductor elements 4 are switching elements. The semiconductor elements 4 are disposed on the first obverse surface 32a of the supporting conductor 32. Specifically, four or more semiconductor elements 4 are disposed at intervals, and each of these semiconductor elements 4 is supported by one of the first conductor 321 to the fourth conductor 324 of the supporting conductor 32. In the present embodiment, the semiconductor elements 4 include semiconductor elements 40A to 40F. Although six semiconductor elements, namely the semiconductor elements 40A to 40F, are provided in the illustrated example, the number of semiconductor elements 4 is not limited as long the number is four or more.

Each of the semiconductor elements 4 (the semiconductor elements 40A to 40F) may include at least one of a wide bandgap semiconductor and an ultra-wide bandgap semiconductor. Examples of the wide bandgap semiconductor include silicon carbide (SiC) and gallium nitride (GaN). Examples of the ultra-wide bandgap semiconductor include gallium oxide (Ga₂O₃) and diamond (C). In the present embodiment, each of the semiconductor elements 4 (the semiconductor elements 40A to 40F) may be a SiC MOSFET (metal-oxide-semiconductor field-effect transistor), which is a MOSFET with a silicon carbide (SiC) substrate. Each of the semiconductor elements 4 may be a MOSFET with a silicon (Si) substrate instead of a SiC substrate, and may include an IGBT element. Alternatively, each of the semiconductor elements 4 may be a MOSFET containing gallium nitride (GaN). In addition, the semiconductor elements 4 may be diodes instead of the switching elements described above.

As shown in FIG. 3 and FIGS. 5 to 8, each of the semiconductor elements 4 has a rectangular plate shape in plan view, and includes an element obverse surface 41, an element reverse surface 42, a source electrode 43, a gate electrode 44, and a drain electrode 45. The element obverse surface 41 and the element reverse surface 42 face away from each other in the thickness direction z. The element obverse surface 41 faces the z1 side in the thickness direction z. The element reverse surface 42 faces the z2 side in the thickness direction z. As shown in FIG. 3, the source electrode 43 and the gate electrode 44 are disposed on the element obverse surface 41. As shown in FIGS. 5 to 7, the drain electrode 45 is disposed on the element reverse surface 42. The shape and arrangement of each of the source electrode 43, the gate electrode 44, and the drain electrode 45 are not particularly limited. In the illustrated example, the source electrode 43 is larger than the gate electrode 44 as viewed in the thickness direction z. The source electrode 43 consists of two separate regions as viewed in the thickness direction z. Each of the semiconductor elements 4 has a thermal capacity of 0.0001 to 0.5 J/K, for example. Each of the semiconductor elements 4 has a thermal resistance of 0.0003 to 1.5 K/W, for example.

As shown in FIGS. 3, 7, and 8, the semiconductor elements 40A, 40B, and 40C are disposed on the second conductor 322. As shown in FIGS. 7 and 8, each of the semiconductor elements 40A, 40B, and 40C is bonded to the second conductor 322 via a conductive bonding material 47 with the element reverse surface 42 facing the second conductor 322. As a result, the drain electrode 45 of each of the semiconductor elements 40A, 40B, and 40C is electrically connected to the second conductor 322 via a conductive bonding material 47. The conductive bonding material 47 may be silver paste, copper paste, or solder, for example. As shown in FIG. 3, the source electrode 43 of the semiconductor element 40A is electrically connected to the lead 12 via a wire 71. The source electrode 43 of the semiconductor element 40B is electrically connected to the lead 13 via a wire 71. The source electrode 43 of the semiconductor element 40C is electrically connected to the lead 14 via a wire 71. The wires 71 are made of aluminum (Al) or copper (Cu), for example. The material, diameter, and number of wires 71 are not limited.

As shown in FIGS. 3, the semiconductor element 40D is disposed on the first conductor 321. The semiconductor element 40D is bonded to the second conductor 321 via a non-illustrated conductive bonding material with the element reverse surface 42 facing the first conductor 321. As a result, the drain electrode 45 of the semiconductor element 40D is electrically connected to the first conductor 321 via the conductive bonding material. The source electrode 43 of the semiconductor element 40D is electrically connected to the lead 15 via a wire 71.

As shown in FIGS. 3, 6, and 8, the semiconductor element 40E is disposed on the third conductor 323. As shown in FIGS. 6 and 8, the semiconductor element 40E is bonded to the third conductor 323 via a conductive bonding material 47 with the element reverse surface 42 facing the third conductor 323. As a result, the drain electrode 45 of the semiconductor element 40E is electrically connected to the third conductor 323 via the conductive bonding material 47. As shown in FIG. 3, the source electrode 43 of the semiconductor element 40E is electrically connected the lead 15 via a wire 71.

As shown in FIGS. 3 and 5, the semiconductor element 40F is disposed on the fourth conductor 324. As shown in FIG. 5, the semiconductor element 40F is bonded to the fourth conductor 324 via a conductive bonding material 47 with the element reverse surface 42 facing the fourth conductor 324. As a result, the drain electrode 45 of the semiconductor element 40F is electrically connected to the fourth conductor 324 via the conductive bonding material 47. As shown in FIG. 3, the source electrode 43 of the semiconductor element 40F is electrically connected the lead 15 via a wire 71.

The gate electrode 44 of the semiconductor element 40A is connected to the sixth conductor 326 via a wire 72, and the sixth conductor 326 is connected to a lead 22 via a wire 72. The gate electrode 44 of the semiconductor element 40A is electrically connected to the lead 22 via the wires 72 and the sixth conductor 326. The lead 22 electrically connected to the gate electrode 44 of the semiconductor element 40A is a terminal (gate terminal) used to input a drive signal for the semiconductor element 40A. The source electrode 43 of the semiconductor element 40A is connected to the fifth conductor 325 via a wire 73, and the fifth conductor 325 is connected to a lead 21 via a wire 73. The source electrode 43 of the semiconductor element 40A is electrically connected to the lead 21 via the wires 73 and the fifth conductor 325. The lead 21 electrically connected to the source electrode 43 of the semiconductor element 40A is a terminal (source sense terminal) used to detect a source signal for the semiconductor element 40A. The wires 72 and 73 are made of gold (Au), silver (Ag), copper (Cu), or aluminum (Al), for example. The material, diameter, and number of wires 72 and 73 are not limited.

The gate electrode 44 of the semiconductor element 40B is electrically connected to a lead 22 via a wire 72. The lead 22 electrically connected to the gate electrode 44 of the semiconductor element 40B is the gate terminal of the semiconductor element 40B. The source electrode 43 of the semiconductor element 40B is electrically connected to the lead 21 via a wire 73. The lead 21 electrically connected to the source electrode 43 of the semiconductor element 40B is the source sense terminal of the semiconductor element 40B.

The gate electrode 44 of the semiconductor element 40C is electrically connected to a lead 22 via a wire 72. The lead 22 electrically connected to the gate electrode 44 of the semiconductor element 40C is the gate terminal of the semiconductor element 40C. The source electrode 43 of the semiconductor element 40C is electrically connected to a lead 21 via a wire 73. The lead 21 electrically connected to the source electrode 43 of the semiconductor element 40C is the source sense terminal of the semiconductor element 40C.

The gate electrode 44 of the semiconductor element 40D is electrically connected to a lead 22 via a wire 72. The lead 22 electrically connected to the gate electrode 44 of the semiconductor element 40D is the gate terminal of the semiconductor element 40D. The source electrode 43 of the semiconductor element 40D is electrically connected to a lead 21 via a wire 73. The lead 21 electrically connected to the source electrode 43 of the semiconductor element 40D is the source sense terminal of the semiconductor element 40D.

The gate electrode 44 of the semiconductor element 40E is electrically connected to a lead 22 via a wire 72. The lead 22 electrically connected to the gate electrode 44 of the semiconductor element 40E is the gate terminal of the semiconductor element 40E. The source electrode 43 of the semiconductor element 40E is electrically connected to a lead 21 via a wire 73. The lead 21 electrically connected to the source electrode 43 of the semiconductor element 40E is the source sense terminal of the semiconductor element 40E.

The gate electrode 44 of the semiconductor element 40F is electrically connected to a lead 22 via a wire 72. In the present embodiment, the wire 72 has one end bonded to the gate electrode 44 of the semiconductor element 40F, a middle part bonded to the eighth conductor 328, and the other end bonded to the lead 22. The lead 22 electrically connected to the gate electrode 44 of the semiconductor element 40F is the gate terminal of the semiconductor element 40F. The source electrode 43 of the semiconductor element 40F is electrically connected to a lead 21 via a wire 73. In the present embodiment, the wire 73 has one end bonded to the source electrode 43 of the semiconductor element 40F, a middle part bonded to the seventh conductor 327, and the other end bonded to the lead 21. The lead 21 electrically connected to the source electrode 43 of the semiconductor element 40F is the source sense terminal of the semiconductor element 40F.

The semiconductor device A1 is configured as a half-bridge switching circuit, for example. In this case, the leads 12, 13, and 14 are electrically connected to each other via an external connection, so that the semiconductor elements 40A, 40B, and 40C form an upper arm circuit of the semiconductor device A1, and the semiconductor elements 40D, 40E, and 40F form a lower arm circuit. In the upper arm circuit, the semiconductor elements 40A, 40B, and 40C are connected to each other in parallel. In the lower arm circuit, the semiconductor elements 40D, 40E, and 40F are also connected to each other in parallel. The semiconductor elements 40A, 40B, and 40C are connected in series to the semiconductor elements 40D, 40E, and 40F, respectively, so as to form bridge layers. In the semiconductor device A1, the lead 11 and the lead 15 are used to input DC voltage that is to be converted. The lead 11 is a positive electrode (P terminal), and the lead 15 is a negative electrode (N terminal). The lead 12, the lead 13, and the lead 14 are used to output AC voltage resulting from the power conversion by the semiconductor elements 40A to 40F.

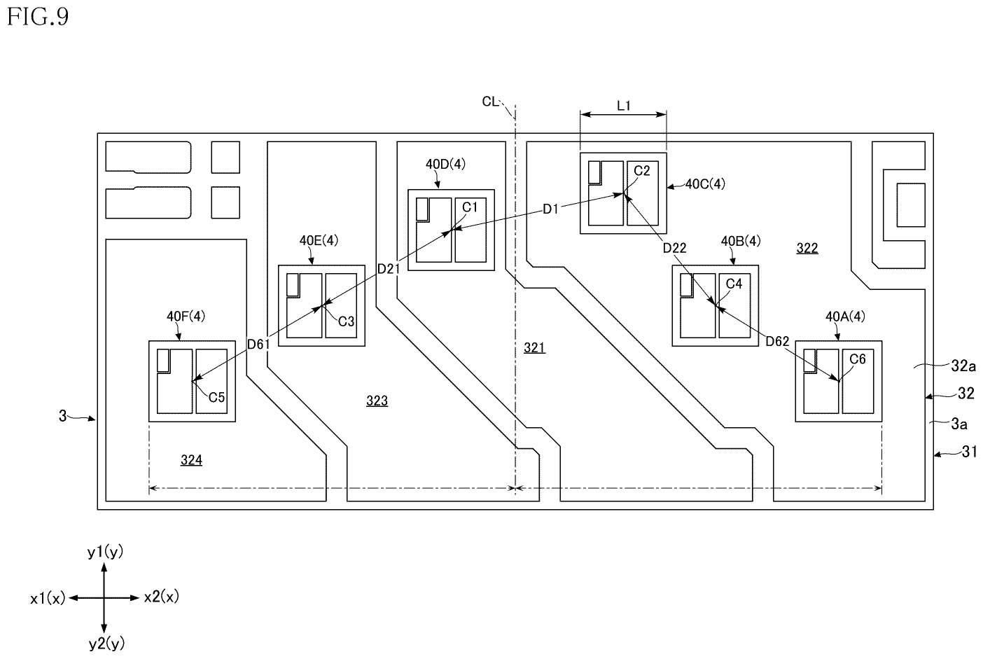

As shown in FIGS. 3 and 9, the semiconductor elements 4 (the semiconductor elements 40A to 40F) of the present embodiment are disposed side by side in the first direction x. The semiconductor element 40A is located at the end on the x2 side in the first direction x, the semiconductor element 40F is located at the end on the x1 side in the first direction x, and the semiconductor elements 40A to 40F are disposed in this order from the x2 side in the first direction x to the x1 side in the first direction x.

The semiconductor element 40C and the semiconductor element 40D are disposed near the center in the first direction x. Note that the “center in the first direction x” refers to a center line CL in the first direction x for the semiconductor elements 40A to 40F disposed side by side in the first direction x, and the same applies to variations, etc., described below. As can be seen in the present embodiment, when the number of semiconductor elements 4 (the semiconductor elements 40A to 40F) is even, two semiconductor elements, namely the semiconductor elements 40C and 40D, are disposed near the center in the first direction x among the semiconductor elements 4.

In the illustrated example, the semiconductor elements 40A to 40F include those that are not aligned along the first direction x and are located at different positions in the second direction y. The semiconductor element 40B is offset to the y1 side in the second direction y with respect to the semiconductor element 40A adjacent on the x2 side in the first direction x. The semiconductor element 40C is offset to the y1 side in the second direction y with respect to the semiconductor element 40B adjacent on the x2 side in the first direction x. In addition, the semiconductor element 40C is offset to the y1 side in the second direction y with respect to the semiconductor element 40D adjacent on the x1 side in the first direction x. The semiconductor element 40D is offset to the y1 side in the second direction y with respect to the semiconductor element 40E adjacent on the x1 side in the first direction x. The semiconductor element 40E is offset to the y1 side in the second direction y with respect to the semiconductor element 40F adjacent on the x1 side in the first direction x. The semiconductor element 40E is located at the same (or substantially the same) position as the semiconductor element 40B in the second direction y. The semiconductor element 40F is located at the same (or substantially the same) position as the semiconductor element 40A in the second direction y. Among the semiconductor elements 4 (the semiconductor elements 40A to 40F) disposed as described above, the semiconductor element 40D corresponds to an example of a “first semiconductor element” in the present disclosure, and the semiconductor element 40C corresponds to an example of a “second semiconductor element” in the present disclosure. The first conductor 321 on which the semiconductor element 40D (the first semiconductor element) is disposed corresponds to an example of a “first portion” in the present disclosure, and the second conductor 322 on which the semiconductor element 40C (the second semiconductor element) is disposed corresponds to an example of a “second portion” in the present disclosure.

As shown in FIG. 9, the semiconductor elements 4 (the semiconductor elements 40A to 40F) have the following relationships regarding the distance between the centers of adjacent semiconductor elements 4 in the first direction x. A first distance D1, which is the distance between a center C1 of the semiconductor element 40D and a center C2 of the semiconductor element 40C that are located near the center in the first direction x, is greater than a second distance D21, which is the distance between the center C1 of the semiconductor element 40D and a center C3 of the semiconductor element 40E that is adjacent to the semiconductor element 40D in the first direction x. The distance (the first distance D1) between the center C1 of the semiconductor element 40D and the center C2 of the semiconductor element 40C is also greater than a second distance D22, which is the distance between the center C2 of the semiconductor element 40C and a center C4 of the semiconductor element 40B that is adjacent to the semiconductor element 40C in the first direction x. In the present embodiment, the distance (the first distance D1) between the center C1 of the semiconductor element 40D and the center C2 of the semiconductor element 40C is at least twice the length (length L1) of a side of each semiconductor element 4 along the first direction x.

The distance (the first distance D1) between the center C1 of the semiconductor element 40D and the center C2 of the semiconductor element 40C is greater than a sixth distance D61, which is the distance between the center C3 of the semiconductor element 40E and a center C5 of the semiconductor element 40F that are adjacent to each other in the first direction x out of the plurality of semiconductor elements 4. The first distance D1 is also greater than a sixth distance D62, which is the distance between the center C4 of the semiconductor element 40B and a center C6 of the semiconductor element 40A that are adjacent to each other in the first direction x out of the plurality of semiconductor elements 4.

The distance (the second distance D21) between the center C1 of the semiconductor element 40D and the center C3 of the semiconductor element 40E is greater than the distance (the sixth distance D61) between the center C3 of the semiconductor element 40E and the center C5 of the semiconductor element 40F that are adjacent to each other in the first direction x. The distance (the second distance D22) between the center C2 of the semiconductor element 40C and the center C4 of the semiconductor element 40B is greater than the distance (the sixth distance D62) between the center C4 of the semiconductor element 40B and a center C6 of the semiconductor element 40A that are adjacent to each other in the first direction x.

The thermistor 6 is a temperature detection element mounted on the second obverse surface 3a of the insulating substrate 31. The thermistor 6 is a resistor that exhibits a large change in electric resistance in response to temperature changes, and a change in resistance value in response to the surrounding temperature causes a change in the voltage across terminals. The temperature around in the thermistor 6 is detected based on the voltage across the terminals of the thermistor 6. The characteristics of the thermistor 6 are not particularly limited. The thermistor 6 may be an NTC (negative temperature coefficient) thermistor, a PTC (positive temperature coefficient) thermistor, or a thermistor having other characteristics.

The thermistor 6 is provided to detect the temperature of the semiconductor device A1. As shown in FIGS. 3 and 5, the thermistor 6 is provided across the two pad portions 502 of the wiring portion 5 (the wirings 501). The thermistor 6 is bonded to the pad portions 502 via conductive bonding materials 63. Each conductive bonding material 63 may be any material capable of bonding the thermistor 6 to the pad portions 502 and electrically connecting the thermistor 6 and the pad portions 502. The conductive bonding materials 63 may be silver paste, copper paste, or solder, for example. One of the terminals of the thermistor 6 is electrically bonded to a pad portion 502 via a conductive bonding material 63, and the other terminal of the thermistor 6 is electrically bonded to the other pad portion 502 via a conductive bonding material 63.

Each of the two pad portions 502 (the wirings 501) is electrically connected to a lead 23 via a wire 74. The pad portions 502 (the wirings 501) and the wires 74 form conductive paths that electrically connect the thermistor 6 and the leads 23. The two leads 23 are terminals used to detect the temperature of the semiconductor device A1, and output the voltage across the terminals of the thermistor 6.

In the present embodiment, the semiconductor device A1 includes an insulating member 62 as shown in FIG. 5. The insulating member 62 is provided between the second obverse surface 3a of the insulating substrate 31 and the thermistor 6, and is electrically insulative. The insulating member 62 is an underfill filled between the second obverse surface 3a and the thermistor 6 in the thickness direction z. The constituent material of the insulating member 62 is not particularly limited, and may be a synthetic resin mainly containing black epoxy resin. As shown in FIG. 3, the thermistor 6 is disposed near the corner of the insulating substrate 31 on the x1 side in the first direction x and on the y1 side in the second direction y.

The semiconductor device A1 may include another temperature detection element instead of the thermistor 6. Example of another temperature detection element may be a semiconductor temperature sensor. The semiconductor temperature sensor may be a Si diode that exhibits a large change in forward voltage in response to temperature changes, and detects the surrounding temperature based on the voltage across terminals when a predetermined current is supplied. Unlike the present embodiment, the semiconductor device A1 may be configured without the thermistor 6 or other temperature detection elements.

The sealing resin 8 covers at least the semiconductor elements 40A to 40F, the wiring portion 5, the thermistor 6, the wires 71 to 74, parts of the leads 1 and 2, and a part of the support 3. The constituent material of the sealing resin 8 is not particularly limited, and may be black epoxy resin. The sealing resin 8 is formed by molding, for example.

The sealing resin 8 has a resin obverse surface 81, a resin reverse surface 82, and a plurality of resin side surfaces 83 to 86. As shown in FIGS. 5 to 8, the resin obverse surface 81 and the resin reverse surface 82 are flat surfaces perpendicular to the thickness direction z and face away from each other in the thickness direction z. The resin obverse surface 81 faces the z1 side in the thickness direction z, and the resin reverse surface 82 faces the z2 side in the thickness direction z. As shown in FIG. 4, the resin reverse surface 82 has a frame shape surrounding the second reverse surface 3b of the support 3 (the metal layer 33) in plan view. The second reverse surface 3b of the support 3 is exposed from the resin reverse surface 82 of the sealing resin 8, and is flush with the resin reverse surface 82, for example. Note that the second reverse surface 3b of the support 3 may protrude from the resin reverse surface 82 of the sealing resin 8 toward the z2 side in the thickness direction z.

The resin side surfaces 83 to 86 are connected to the resin obverse surface 81 and the resin reverse surface 82, and are flanked by these surfaces in the thickness direction z. As shown in FIG. 2, the resin side surface 83 and the resin side surface 84 are spaced apart from each other in the first direction x. The resin side surface 83 faces the x1 side in the first direction x, and the resin side surface 84 faces the x2 side in the first direction x. As shown in FIG. 2, the resin side surface 85 and the resin side surface 86 are spaced apart from each other in the second direction y. The resin side surface 85 faces the y1 side in the second direction y, and the resin side surface 86 faces the y2 side in the second direction y. A part of each lead 2 protrudes from the resin side surface 85. A part of each lead 1 protrudes from the resin side surface 86. As shown in FIGS. 2 to 4, the resin side surface 83 is formed with a recess 831 that is recessed in the first direction x. The resin side surface 84 is formed with a recess 841 that is recessed in the first direction x. The recess 831 and the recess 841 may be used for fixing when mounting the semiconductor device A1. Although detailed descriptions are omitted, each of the resin side surfaces 85 and 86 is formed with a plurality of recesses that are recessed in the second direction y.

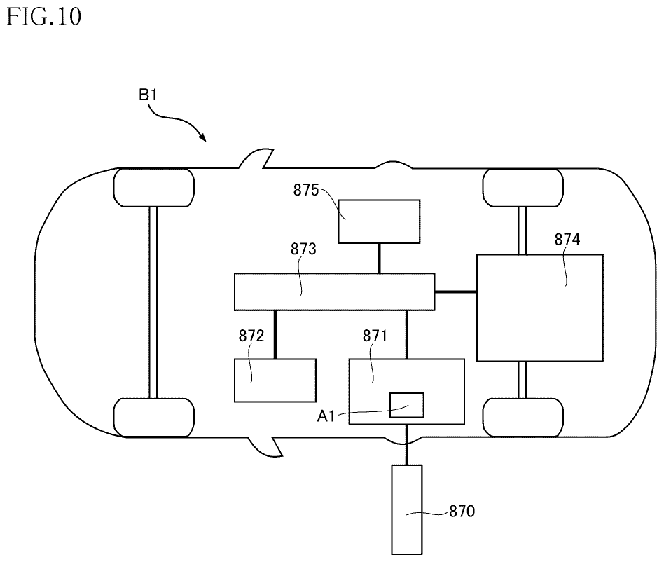

Next, a use example of the semiconductor device A1 will be described with reference to FIG. 10. FIG. 10 is a schematic view showing a vehicle B1 that includes the semiconductor device A1. The vehicle B1 includes an AC-DC conversion device 871, a power receiving device 872, a storage battery 873, a drive system 874, and a DC-DC conversion device 875. The semiconductor device A1 constitutes a part (PFC circuit) of the AC-DC conversion device 871. When the vehicle B1 receives AC power from a charging facility 870, which is an AC power source installed outdoors, for example, the AC-DC conversion device 871 converts the AC power into high-voltage DC power. The AC-DC conversion device 871 supplies the high-voltage DC power to the storage battery 873. The power receiving device 872 supplies power to the storage battery 873 via a non-contact charging system, and receives power from a non-contact charger (not illustrated) placed in a parking lot or the like by an electromagnetic induction method. The power stored in the storage battery 873 is supplied to the drive system 874 that includes an inverter, an AC motor, and a transmission. The drive system 874 drives the vehicle B1. The DC-DC conversion device 875 may be a step-down DC-DC converter, and supplies power to electrical components other than those used for driving the vehicle B1. The AC-DC conversion device 871 is an example of a “power conversion device” of the present disclosure.

Next, advantages of the semiconductor device A1 according to the present embodiment will be described.

The semiconductor device A1 includes the supporting conductor 32, four or more semiconductor elements 4 (the semiconductor elements 40A to 40F), and the sealing resin 8. The semiconductor elements 40A to 40F include the semiconductor element 40D (the first semiconductor element) and the semiconductor element 40C (the second semiconductor element) that are located near the center in the first direction x. The distance (the first distance D1) between the center C1 of the semiconductor element 40D and the center C2 of the semiconductor element 40C is greater than the distance (the second distance D21) between the center C1 of the semiconductor element 40D and the center C3 of the semiconductor element 40E that is adjacent to the semiconductor element 40D in the first direction x, and is also greater than the distance (the second distance D22) between the center C2 of the semiconductor element 40C and the center C4 of the semiconductor element 40B that is adjacent to the semiconductor element 40C in the first direction x. This configuration can suppress the thermal interference between the semiconductor element 40D and the semiconductor element 40C that are located near the center among the semiconductor elements 40A to 40F. This makes it possible to prevent the concentration of heat generated by the semiconductor elements 40A to 40F and reduce the thermal resistance. As a result, the semiconductor device A1 can easily handle large currents and improve durability.

The center C1 of the semiconductor element 40D and the center C2 of the semiconductor element 40C are located at different positions in the second direction y perpendicular to the first direction x in which the semiconductor elements 40A to 40F are disposed side by side. According to this configuration, heat generated by the semiconductor element 40D and the semiconductor element 40C that are located near the center among the semiconductor elements 40A to 40F can be efficiently released to the surrounding environment, whereby thermal interference is further suppressed. In addition, the above configuration can increase the distance (the first distance D1) between the center C1 of the semiconductor element 40D and the center C2 of the semiconductor element 40C while preventing an increase in the dimension of the semiconductor device A1 in the first direction x.

As shown in FIG. 9, the centers of semiconductor elements 4 adjacent in the first direction x out of the semiconductor elements 4 (the semiconductor elements 40A to 40F) are located at different positions in the second direction y. According to this configuration, heat generated by the semiconductor elements 40A to 40F can be efficiently released to the surrounding environment.

The distance (the first distance D1) between the center C1 of the semiconductor element 40D and the center C2 of the semiconductor element 40C is at least twice the length (length L1) of a side of each semiconductor element 4 along the first direction x. This configuration can appropriately suppress the thermal interference between the semiconductor element 40D and the semiconductor element 40C that are located near the center among the semiconductor elements 40A to 40F. The above configuration is more preferable for reducing the thermal resistance of the semiconductor device A1.

The distance (the second distance D21) between the center C1 of the semiconductor element 40D and the center C3 of the semiconductor element 40E is greater than the distance (the sixth distance D61) between the center C3 of the semiconductor element 40E and the center C5 of the semiconductor element 40F. The distance (the second distance D22) between the center C2 of the semiconductor element 40C and the center C4 of the semiconductor element 40B is greater than the distance (the sixth distance D62) between the center C4 of the semiconductor element 40B and the center C6 of the semiconductor element 40A. According to this configuration, the semiconductor elements 4 (the semiconductor elements 40A to 40F) are disposed such that the distance between adjacent semiconductor elements 4 in the first direction x decreases with increasing distance from the center in the first direction x. This makes it possible to suppress the thermal interference between the semiconductor elements 4 (the semiconductor elements 40A to 40F) and reduce the dimension of the semiconductor device A1 in the first direction x.

The supporting conductor 32 includes the first conductor 321 (the first portion) and the second conductor 322 (the second portion) that are spaced apart from each other. Of the semiconductor elements 40A to 40F, only the semiconductor element 40D (the first semiconductor element) is disposed on the first conductor 321. Of the semiconductor elements 40A to 40F, the semiconductor element 40C (the second semiconductor element) and the semiconductor element 40B that is adjacent to the semiconductor element 40C are disposed on the second conductor 322. The center C1 of the semiconductor element 40D (the first semiconductor element) is offset to the y1 side in the second direction y from the center of any of the semiconductor elements 40A, 40B, 40E, and 40F in the second direction y. The center C2 of the semiconductor element 40C (the second semiconductor element) is offset to the y1 side in the second direction y from the center C1 of the semiconductor element 40D. Heat generated by the semiconductor element 40C and the semiconductor element 40B that are disposed on the common second conductor 322 tends to be trapped on the second conductor 322, and the interference of heat generated by the semiconductor element 40C and the semiconductor element 40B tends to cause a rise in the temperature of the second conductor 322. As described above, the semiconductor element 40C is disposed farthest to the y1 side in the second direction y among all the semiconductor elements 40A to 40F. According to this layout, the second conductor 322 on which the semiconductor element 40C is mounted can efficiently release heat generated by the semiconductor element 40C to the surroundings of the semiconductor element 40C. This makes it possible to suppress the thermal interference between the semiconductor elements 40D, 40C, and 40B, thereby reducing the thermal resistance of the semiconductor device A1.

The semiconductor device A1 includes the support 3. The first reverse surface 32b of the supporting conductor 32 on which the semiconductor elements 4 (the semiconductor elements 40A to 40F) are mounted is bonded to the second obverse surface 3a of the support 3 (the insulating substrate 31). The second reverse surface 3b of the support 3 (the metal layer 33) is exposed from the sealing resin 8. According to this configuration, heat transferred from the semiconductor elements 4 to the support 3 (the insulating substrate 31) can be efficiently released from the second reverse surface 3b to the outside, and the heat dissipation of the semiconductor device A1 is thereby improved.

### First Example of Semiconductor Device Assembly Including Semiconductor Device of First Embodiment

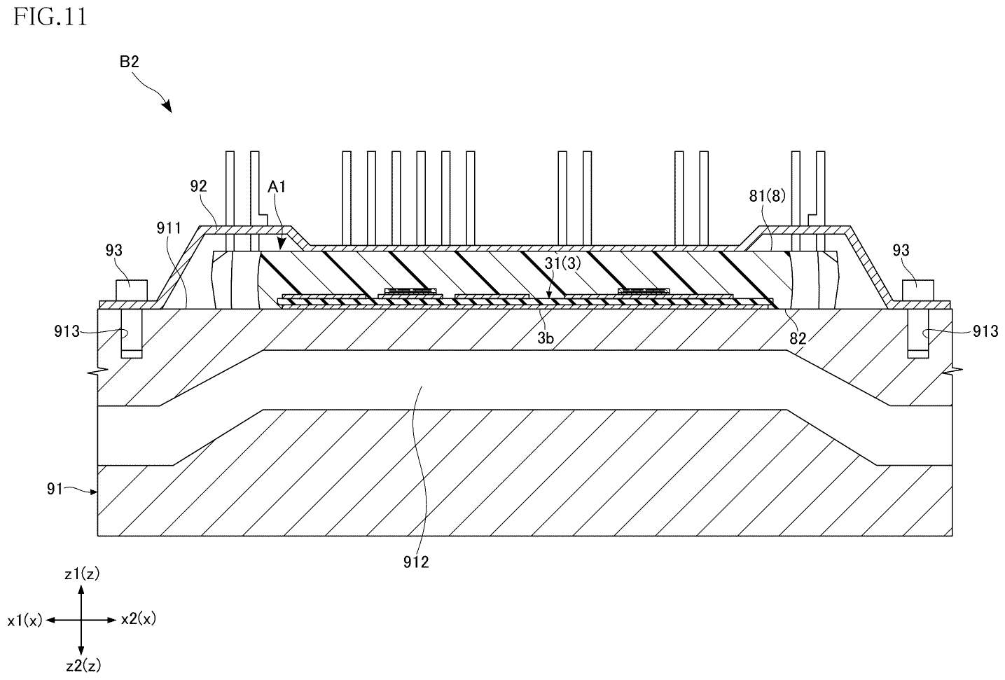

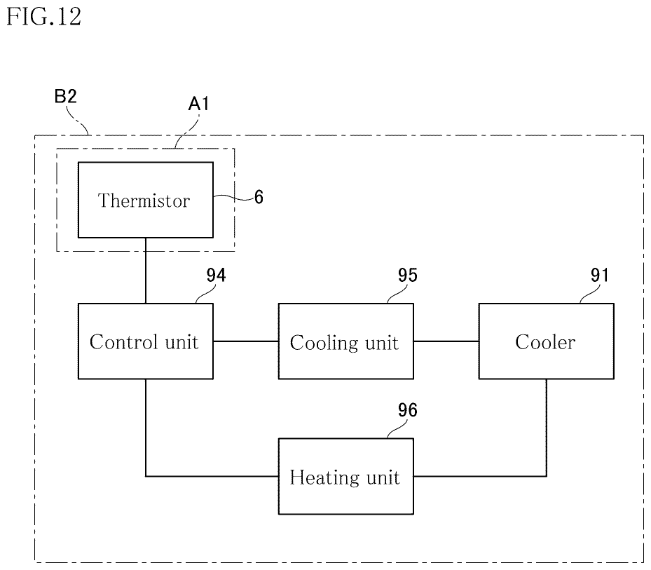

FIGS. 11 and 12 show a first example of a semiconductor device assembly configured to include the semiconductor device A1. FIG. 11 is a partial cross-sectional view showing a semiconductor device assembly B2 of the present example. FIG. 12 is a block diagram showing a configuration of the semiconductor device assembly B2. The semiconductor device assembly B2 includes the semiconductor device A1, a cooler 91, a mounting member 92, a fastener 93, a control unit 94, a cooling unit 95, and a heating unit 96.

The cooler 91 is a heat dissipating member for cooling the semiconductor device A1. The cooler 91 is made of a metal material having high thermal conductivity. The constituent material of the cooler 91 is not particularly limited, and may be aluminum (Al), copper (Cu), or any of the alloys thereof. The cooler 91 has a mounting surface 911 and a flow passage 912. The mounting surface 911 is a flat surface facing the z1 side in the thickness direction z. The flow passage 912 is a hollow portion formed inside the cooler 91. The flow passage 912 allows cooling water to flow through as a coolant. The semiconductor device A1 is disposed on the mounting surface 911 of the cooler 91. The mounting surface 911 faces the second reverse surface 3b of the support 3 of the semiconductor device A1 and the resin reverse surface 82 of the sealing resin 8, and is in surface contact with the second reverse surface 3b and the resin reverse surface 82.

The mounting member 92 is provided to hold the semiconductor device A1 on the cooler 91. The mounting member 92 is disposed across the semiconductor device A1 in the second direction y. The mounting member 92 is a plate spring, for example. The mounting member 92 is attached to the cooler 91 by inserting two fasteners 93 into two mounting holes 913 located at the respective sides of the semiconductor device A1 in the second direction y. The two fasteners 93 are bolts, for example. In a pressure-contact state, the semiconductor device A1 is pressed against the cooler 91 by the spring elastic force of the mounting member 92, and the mounting surface 911 of the cooler 91 and the second reverse surface 3b of the support 3 of the semiconductor device A1 are in close contact with each other. If the contact between the mounting surface 911 and the second reverse surface 3b is insufficient, the cooler 91 may be provided with a thermal interface material (TIM), which is not illustrated. The TIM is made of a thermal grease or a thermal interface sheet, for example, and is provided between the mounting surface 911 and the second reverse surface 3b. The TIM bonds the mounting surface 911 and the second reverse surface 3b so that the mounting surface 911 and the second reverse surface 3b are in close contact with each other.

The cooling unit 95 is provided to cool the cooler 91. The cooling unit 95 may be configured to include a cooling water supply source and an open/close switchable valve which are not illustrated. When the cooler 91 is cooled by the cooling unit 95, for example, the valve is open so as to allow the cooling water supplied from the cooling water supply source to flow through the flow passage 912. When cooling of the cooler 91 is stopped, the valve is closed so as to stop the flow of the cooling water through the flow passage 912. It is sufficient for the cooling unit 95 to cool the cooler 91, and the specific configuration of the cooling unit 95 is not limited at all.

The heating unit 96 is provided to heat the cooler 91. The heating unit 96 may be configured to include a non-illustrated heater attached to the cooler 91. The heater is activated when, for example, the cooler 91 is heated by the heating unit 96. It is sufficient for the heating unit 96 to heat the cooler 91, and the specific configuration of the heating unit 96 is not limited at all.

The control unit 94 controls the cooling unit 95 and the heating unit 96 based on the temperature detected by the thermistor 6 of the semiconductor device A1. For example, when the temperature detected by the thermistor 6 exceeds a predetermined first temperature, the control unit 94 activates the cooling unit 95 to cool the cooler 91. When the temperature detected by the thermistor 6 falls below a predetermined second temperature (the second temperature being lower than the first temperature), the control unit 94 activates the heating unit 96 to heat the cooler 91. The specific control method used by the control unit 94 to control the cooling unit 95 and the heating unit 96 is not particularly limited.

Next, advantages of the semiconductor device assembly B2 according to the present example will be described.

The semiconductor device assembly B2 of the present example includes the semiconductor device A1, the cooler 91, the cooling unit 95 for cooling the cooler 91, and the control unit 94. The second reverse surface 3b of the support 3 in the semiconductor device A1 is exposed from the sealing resin 8, and the cooler 91 has a portion (the mounting surface 911 or the TIM) that is in contact with the second reverse surface 3b of the support 3. Such a configuration can suppress a temperature rise of the semiconductor device A1.

The semiconductor device assembly B2 includes the control unit 94. The control unit 94 controls the cooling unit 95 based on the temperature detected by the thermistor 6 of the semiconductor device A1. According to the configuration, it is possible to prevent excessive temperature rise of the semiconductor device A1 while monitoring the temperature of the semiconductor device A1, thereby driving the semiconductor device A1 appropriately.

The semiconductor device assembly B2 includes the heating unit 96 that heats the cooler 91, and the control unit 94 controls the heating unit 96 based on the temperature detected by the thermistor 6. According to the configuration, when, for example, the semiconductor device A1 is mounted in a vehicle-mount device and used in a cold area or the like, it is possible to prevent excessive temperature drop of the semiconductor device A1 while monitoring the temperature of the semiconductor device A1, thereby driving the semiconductor device A1 appropriately.

### Second Example of Semiconductor Device Assembly Including Semiconductor Device of

### First Embodiment

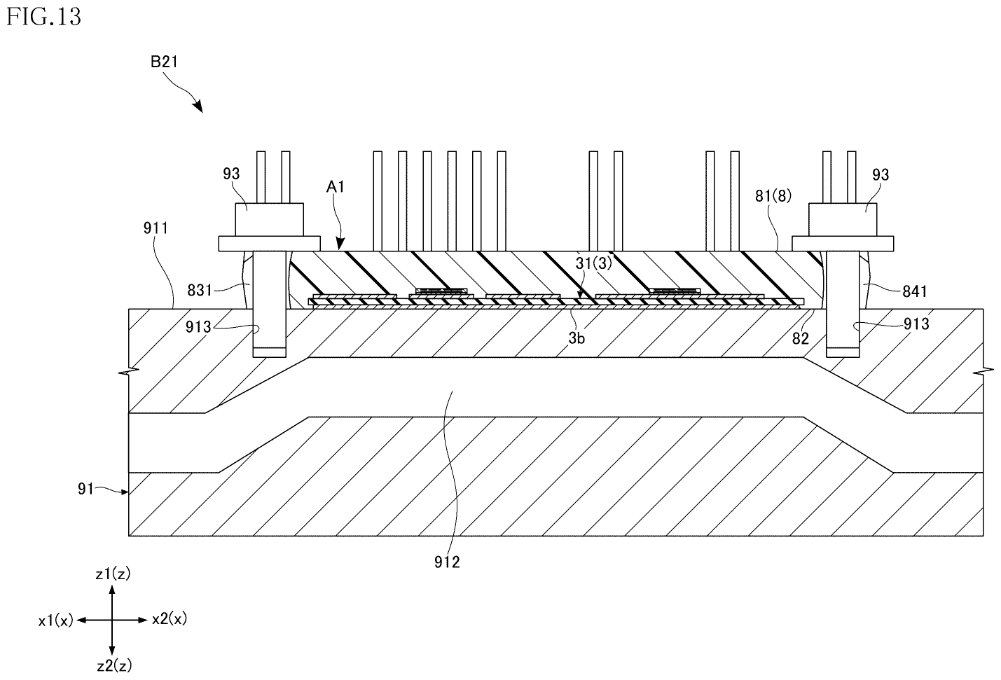

FIG. 13 shows a second example of a semiconductor device assembly configured to include the semiconductor device A1. FIG. 13 is a partial cross-sectional view showing a semiconductor device assembly B21 of the present example. The semiconductor device assembly B21 has the same configuration as the semiconductor device assembly B2 of the first example in FIG. 12. As shown in FIGS. 12 and 13, the semiconductor device assembly B21 includes the semiconductor device A1, a cooler 91, a fastener 93, a control unit 94, a cooling unit 95, and a heating unit 96. The cooler 91, the control unit 94, the cooling unit 95, and the heating unit 96 are the same as those of the semiconductor device assembly B2 described above, and detailed descriptions thereof are thus omitted.

In the semiconductor device assembly B21, the semiconductor device A1 is disposed on a mounting surface 911 of the cooler 91. The mounting surface 911 faces the second reverse surface 3b of the support 3 of the semiconductor device A1 and the resin reverse surface 82 of the sealing resin 8, and is in surface contact with at least the second reverse surface 3b.

The cooler 91 in the semiconductor device assembly B21 has two mounting holes 913. The two mounting holes 913 are formed in the positions corresponding to the recess 831 and the recess 841 of the semiconductor device A1. The semiconductor device A1 is fixed to the cooler 91 by passing two fasteners 93 through the recess 831 and the recess 841 and inserting the two fasteners 93 into the two mounting holes 913. The two fasteners 93 are bolts, for example. In a state where the semiconductor device A1 is fixed to the cooler 91, the semiconductor device A1 is pressed against the cooler 91, and the mounting surface 911 of the cooler 91 and the second reverse surface 3b of the support 3 of the semiconductor device A1 are in close contact with each other. If the contact between the mounting surface 911 and the second reverse surface 3b is insufficient, the cooler 91 may be provided with a TIM, which is not illustrated. The TIM is the same as that described above in connection with the semiconductor device assembly B2 of the first example. Thus, descriptions of the TIM are omitted here.

The semiconductor device assembly B2 of the present example includes the semiconductor device A1, the cooler 91, the cooling unit 95 for cooling the cooler 91, and the control unit 94. The second reverse surface 3b of the support 3 in the semiconductor device A1 is exposed from the sealing resin 8, and the cooler 91 has a portion (the mounting surface 911 or the TIM) that is in contact with the second reverse surface 3b of the support 3. Such a configuration can suppress a temperature rise of the semiconductor device A1.

Next, advantages of the semiconductor device assembly B21 according to the present example will be described.

The semiconductor device assembly B21 of the present example includes the semiconductor device A1, the cooler 91, the cooling unit 95 for cooling the cooler 91, and the control unit 94. The second reverse surface 3b of the support 3 in the semiconductor device A1 is exposed from the sealing resin 8, and the cooler 91 has a portion (the mounting surface 911 or the TIM) that is in contact with the second reverse surface 3b of the support 3. Such a configuration can suppress a temperature rise of the semiconductor device A1. The semiconductor device assembly B21 also has advantages similar to those of the semiconductor device assembly B2 described above.

### Variations of Arrangement of Semiconductor Elements

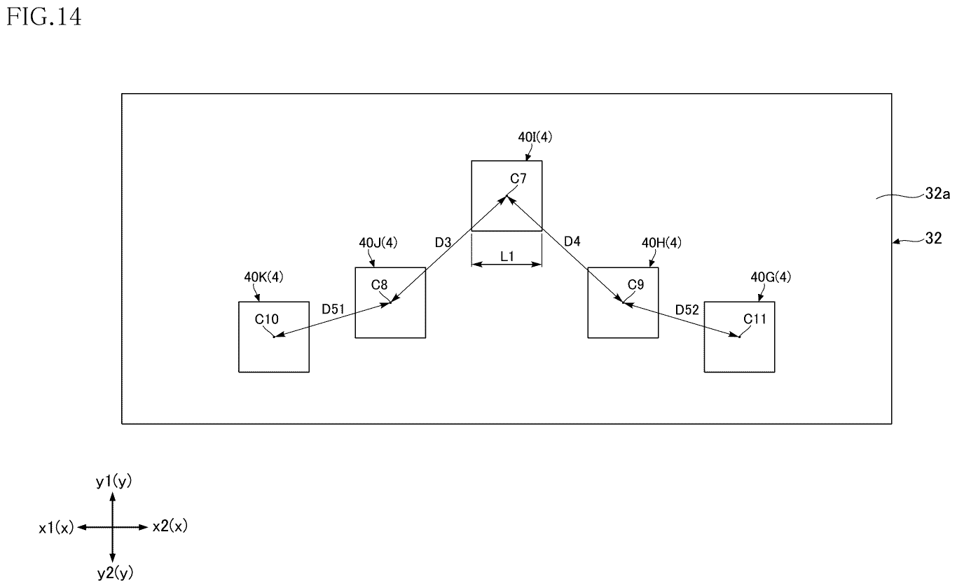

FIGS. 14 to 17 show variations of the arrangement of the semiconductor elements 4. Each of FIGS. 14 to 17 is a schematic plan view showing the arrangement of the semiconductor elements 4. The constituent elements (i.e., the leads 1, the leads 2, the support 3, the wiring portion 5, the thermistor 6, the wires 71, 72, 73, 74, and the sealing resin 8) other than the semiconductor elements 4 and the supporting conductor 32 that supports the semiconductor elements 4 are the same as those in the semiconductor device A1 of the above embodiment, and descriptions of these elements will be omitted. In FIG. 14 and the subsequent figures, elements that are the same as or similar to the elements in the semiconductor device A1 in the above embodiment are provided with the same reference numerals, and descriptions thereof are omitted. The configurations of the elements in each of the variations and examples in FIG. 14 and the subsequent figures can be combined as appropriate to the extent that no technical contradictions arise.

In the arrangement example of the semiconductor elements 4 shown in FIG. 14, the semiconductor elements 4 include five semiconductor elements 40G to 40K. The semiconductor elements 4 (the semiconductor elements 40G to 40K) are disposed side by side in the first direction x. The semiconductor element 40G is located at the end on the x2 side in the first direction x, the semiconductor element 40K is located at the end on the x1 side in the first direction x, and the semiconductor elements 40G to 40K are disposed in this order from the x2 side in the first direction x to the x1 side in the first direction x. As shown in FIG. 14, when the number of semiconductor elements 4 (the semiconductor elements 40G to 40K) is odd, the semiconductor element 40I is disposed near the center in the first direction x among the semiconductor elements 4.

In the illustrated example, the semiconductor elements 40G to 40K include those that are not aligned along the first direction x and are located at different positions in the second direction y. The semiconductor element 40H is offset to the y1 side in the second direction y with respect to the semiconductor element 40G adjacent on the x2 side in the first direction x. The semiconductor element 40I is offset to the y1 side in the second direction y with respect to the semiconductor element 40H adjacent on the x2 side in the first direction x. In addition, the semiconductor element 40I is offset to the y1 side in the second direction y with respect to the semiconductor element 40J adjacent on the x1 side in the first direction x. The semiconductor element 40J is offset to the y1 side in the second direction y with respect to the semiconductor element 40K adjacent on the x1 side in the first direction x. The semiconductor element 40J is located at the same (or substantially the same) position as the semiconductor element 40H in the second direction y. The semiconductor element 40K is located at the same (or substantially the same) position as the semiconductor element 40G in the second direction y. Among the semiconductor elements 4 (the semiconductor elements 40G to 40K) disposed as described above, the semiconductor element 40I corresponds to an example of a “third semiconductor element” in the present disclosure, the semiconductor element 40J corresponds to an example of a “fourth semiconductor element” in the present disclosure, and the semiconductor element 40H corresponds to an example of a “fifth semiconductor element” in the present disclosure.

The semiconductor elements 4 (the semiconductor elements 40G to 40K) shown in FIG. 14 have the following relationships regarding the distance between the centers of adjacent semiconductor elements 4 in the first direction x. A third distance D3, which is the distance between a center C7 of the semiconductor element 40I located near the center in the first direction x and a center C8 of the semiconductor element 40J that is adjacent to the semiconductor element 40I on the x1 side in the first direction x, and a fourth distance D4, which is the distance between the center C7 of the semiconductor element 401 and a center C9 of the semiconductor element 40H that is adjacent to the semiconductor element 40I on the x2 side in the first direction x, are each greater than a fifth distance D51, which is the distance between the center C8 of the semiconductor element 40J and a center C10 of the semiconductor element 40K that is adjacent to the semiconductor element 40J in the first direction x. Each of the third distance D3 and the fourth distance D4 is greater than a fifth distance D52, which is the distance between the center C9 of the semiconductor element 40H and a center C11 of the semiconductor element 40G that is adjacent to the semiconductor element 40H in the first direction x. In the illustrated example, each of the distance (the third distance D3) between the center C7 of the semiconductor element 401 and the center C8 of the semiconductor element 40J and the distance (the fourth distance D4) between the center C7 of the semiconductor element 401 and the center C9 of the semiconductor element 40H is at least twice the length (length L1) of a side of each semiconductor element 4 along the first direction x.

The semiconductor elements 40G to 40K shown in FIG. 14 include the semiconductor element 40I (the third semiconductor element) near the center in the first direction x, the semiconductor element 40J (the fourth semiconductor element) adjacent to the semiconductor element 40I on the x1 side in the first direction x, and the semiconductor element 40H (the fifth semiconductor element) adjacent to the semiconductor element 401 on the x2 side in the first direction x. Each of the distance (the third distance D3) between the center C7 of the semiconductor element 40I and the center C8 of the semiconductor element 40J and the distance (the fourth distance D4) between the center C7 of the semiconductor element 40I and the center C9 of the semiconductor element 40H is greater than the distance (fifth distance D51) between the center C8 of the semiconductor element 40J and the center C10 of the semiconductor element 40K adjacent to the semiconductor element 40J in the first direction x, and is greater than the distance (the fifth distance D52) between the center C9 of the semiconductor element 40H and the center C11 of the semiconductor element 40G. This configuration can suppress the thermal interference between the semiconductor element 40I located near the center among the semiconductor elements 40G to 40K and each of the semiconductor elements 40J and 40H that are adjacent to the semiconductor element 40I. This makes it possible to prevent the concentration of heat generated by the semiconductor elements 40G to 40K and reduce the thermal resistance. As a result, the semiconductor device can easily handle large currents and improve durability.

The center C7 of the semiconductor element 401 and each of the center C8 of the semiconductor element 40J and the center C9 of the semiconductor element 40H are located at different positions in the second direction y perpendicular to the first direction x in which the semiconductor elements 40G to 40K are disposed side by side. According to this configuration, heat generated by the semiconductor element 40I disposed near the center among the semiconductor elements 40G to 40K and by the semiconductor elements 40J and 40H that are adjacent to the semiconductor element 40I can be efficiently released to the surrounding environment, whereby thermal interference is further suppressed. In addition, the above configuration can increase the distance (the third distance D3) between the center C7 of the semiconductor element 40I and the center C8 of the semiconductor element 40J and the distance (the fourth distance D4) between the center C7 of the semiconductor element 401 and the center C9 of the semiconductor element 40H, while preventing an increase in the dimension of the semiconductor device in the first direction x.

The centers of semiconductor elements 4 adjacent in the first direction x out of the semiconductor elements 4 (the semiconductor elements 40G to 40K) are located at different positions in the second direction y. According to this configuration, heat generated by the semiconductor elements 40G to 40K can be efficiently released to the surrounding environment.

Each of the distance (the third distance D3) between the center C7 of the semiconductor element 40I and the center C8 of the semiconductor element 40J and the distance (the fourth distance D4) between the center C7 of the semiconductor element 401 and the center C9 of the semiconductor element 40H is at least twice the length (length L1) of a side of each semiconductor element 4 along the first direction x. This configuration can appropriately suppress the thermal interference between the semiconductor element 401 located near the center among the semiconductor elements 40G to 40K and each of the semiconductor elements 40J and 40H that are adjacent to the semiconductor element 40I. The above configuration is more preferable for reducing the thermal resistance of the semiconductor device.

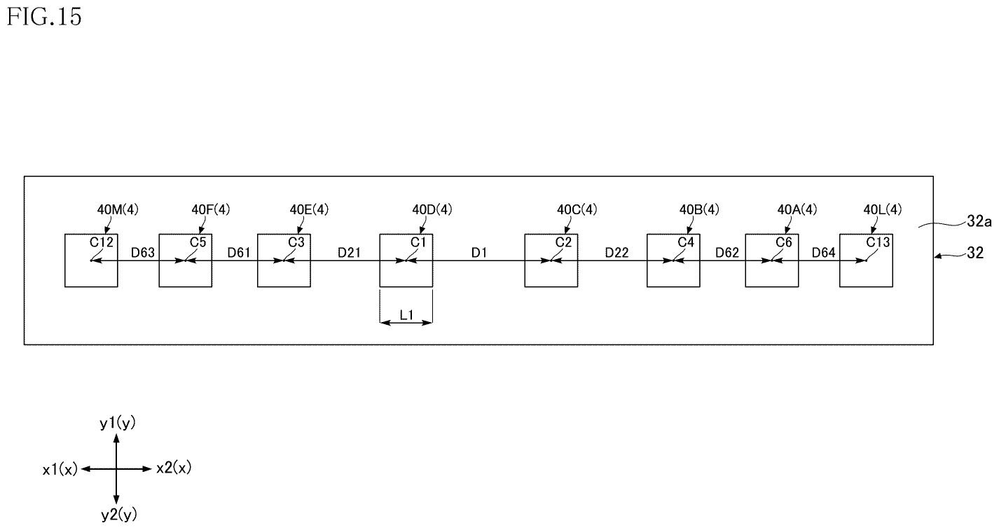

In the arrangement example of the semiconductor elements 4 shown in FIG. 15, the semiconductor elements 4 include eight semiconductor elements 40A to 40F, 40L, and 40M. The semiconductor elements 4 (the semiconductor elements 40L, 40A to 40F, and 40M) are disposed side by side in the first direction x. The semiconductor element 40L is located at the end on the x2 side in the first direction x, the semiconductor element 40M is located at the end on the x1 side in the first direction x, and the semiconductor elements 40L, 40A to 40F, and 40M are disposed in this order from the x2 side in the first direction x to the x1 side in the first direction x. As shown in FIG. 15, when the number of semiconductor elements 4 (the semiconductor elements 40L, 40A to 40F, and 40M) is even, two semiconductor elements, namely the semiconductor element 40D (the first semiconductor element) and the semiconductor element 40C (the second semiconductor element), are disposed near the center in the first direction x. In the illustrated example, the semiconductor elements 40L, 40A to 40F, and 40M are aligned in the first direction x and located at the same (or substantially the same) position in the second direction y.

The semiconductor elements 4 (the semiconductor elements 40L, 40A to 40F, and 40M) shown in FIG. 15 have the following relationships regarding the distance between the centers of adjacent semiconductor elements 4 in the first direction x. The first distance D1 between the center C1 of the semiconductor element 40D and the center C2 of the semiconductor element 40C that are located near the center in the first direction x, is greater than the second distance D21 between the center C1 of the semiconductor element 40D and the center C3 of the semiconductor element 40E that is adjacent to the semiconductor element 40D in the first direction x. The distance (the first distance D1) between the center C1 of the semiconductor element 40D and the center C2 of the semiconductor element 40C is also greater than the second distance D22 between the center C2 of the semiconductor element 40C and the center C4 of the semiconductor element 40B that is adjacent to the semiconductor element 40C in the first direction x. In the illustrated example, the distance (the first distance D1) between the center C1 of the semiconductor element 40D and the center C2 of the semiconductor element 40C is at least twice the length (length L1) of a side of each semiconductor element 4 along the first direction x.

The distance (the second distance D21) between the center C1 of the semiconductor element 40D and the center C3 of the semiconductor element 40E is greater than the distance (the sixth distance D61) between the center C3 of the semiconductor element 40E and the center C5 of the semiconductor element 40F that are adjacent to each other in the first direction x. The distance (the second distance D22) between the center C2 of the semiconductor element 40C and the center C4 of the semiconductor element 40B is greater than the distance (the sixth distance D62) between the center C4 of the semiconductor element 40B and the center C6 of the semiconductor element 40A that are adjacent to each other in the first direction x.

As shown in FIG. 15, the distance (the sixth distance D61) between the center C3 of the semiconductor element 40E and the center C5 of the semiconductor element 40F that are adjacent to each other in the first direction x is greater than the distance (a sixth distance D63) between the center C5 of the semiconductor element 40F and a center C12 of the semiconductor element 40M that are adjacent to each other in the first direction x. The semiconductor element 40M is located farther away from the center in the first direction x than the semiconductor element 40F. The distance (the sixth distance D62) between the center C4 of the semiconductor element 40B and the center C6 of the semiconductor element 40A that are adjacent to each other in the first direction x is greater than the distance (a sixth distance D64) between the center C6 of the semiconductor element 40A and a center C13 of the semiconductor element 40L that are adjacent to each other in the first direction x. The semiconductor element 40L is located farther away from the center in the first direction x than the semiconductor element 40A.

The semiconductor elements 40L, 40A to 40F, and 40M shown in FIG. 15 include the semiconductor element 40D (the first semiconductor element) and the semiconductor element 40C (the second semiconductor element) that are located near the center in the first direction x. The distance (the first distance D1) between the center C1 of the semiconductor element 40D and the center C2 of the semiconductor element 40C is greater than the distance (the second distance D21) between the center C1 of the semiconductor element 40D and the center C3 of the semiconductor element 40E that is adjacent to the semiconductor element 40D in the first direction x, and is also greater than the distance (the second distance D22) between the center C2 of the semiconductor element 40C and the center C4 of the semiconductor element 40B that is adjacent to the semiconductor element 40C in the first direction x. This configuration can suppress the thermal interference between the semiconductor element 40D and the semiconductor element 40C that are located near the center among the semiconductor elements 40L, 40A to 40F, and 40M. This makes it possible to prevent the concentration of heat generated by the semiconductor elements 40L, 40A to 40F, and 40M and reduce the thermal resistance. As a result, the semiconductor device can easily handle large currents and improve durability.

The distance (the first distance D1) between the center C1 of the semiconductor element 40D and the center C2 of the semiconductor element 40C is at least twice the length (length L1) of a side of each semiconductor element 4 along the first direction x. This configuration can appropriately suppress the thermal interference between the semiconductor element 40D and the semiconductor element 40C that are located near the center among the semiconductor elements 40L, 40A to 40F, and 40M. The above configuration is more preferable for reducing the thermal resistance of the semiconductor device.

The distance (the second distance D21) between the center C1 of the semiconductor element 40D and the center C3 of the semiconductor element 40E is greater than the distance (the sixth distance D61) between the center C3 of the semiconductor element 40E and the center C5 of the semiconductor element 40F. The distance (the sixth distance D61) between the center C3 of the semiconductor element 40E and the center C5 of the semiconductor element 40F is greater than the distance (the sixth distance D63) between the center C5 of the semiconductor element 40F and the center C12 of the semiconductor element 40M. The distance (the second distance D22) between the center C2 of the semiconductor element 40C and the center C4 of the semiconductor element 40B is greater than the distance (the sixth distance D62) between the center C4 of the semiconductor element 40B and the center C6 of the semiconductor element 40A. The distance (the sixth distance D62) between the center C4 of the semiconductor element 40B and the center C6 of the semiconductor element 40A is greater than the distance (the sixth distance D64) between the center C6 of the semiconductor element 40A and the center C13 of the semiconductor element 40L. According to this configuration, the semiconductor elements 4 (the semiconductor elements 40L, 40A to 40F, and 40M) are disposed such that the distance between adjacent semiconductor elements 4 in the first direction x decreases with increasing distance from the center in the first direction x. This makes it possible to suppress the thermal interference between the semiconductor elements 4 (the semiconductor elements 40L, 40A to 40F, and 40M) and reduce the dimension of the semiconductor device in the first direction x.

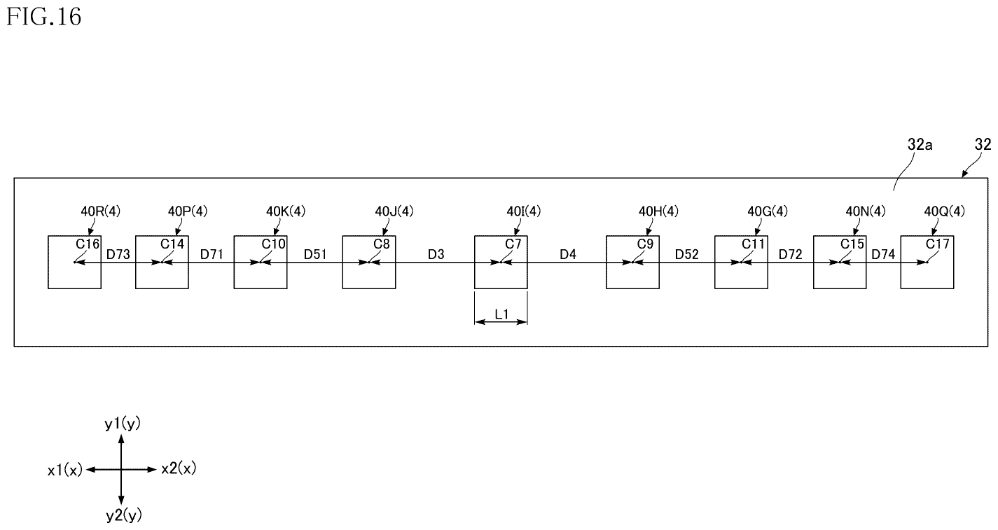

In the arrangement example of the semiconductor elements 4 shown in FIG. 16, the semiconductor elements 4 include nine semiconductor elements 40G to 40K, 40N, 40P, 40Q, and 40R. The semiconductor elements 4 (the semiconductor elements 40Q, 40N, 40G to 40K, 40P, and 40R) are disposed side by side in the first direction x. The semiconductor element 40Q is located at the end on the x2 side in the first direction x, the semiconductor element 40R is located at the end on the x1 side in the first direction x, and the semiconductor elements 40Q, 40N, 40G to 40K, 40P, and 40R are disposed in this order from the x2 side in the first direction x to the x1 side in the first direction x. As shown in FIG. 16, when the number of semiconductor elements 4 (the semiconductor elements 40Q, 40N, 40G to 40K, 40P, and 40R) is odd, the semiconductor element 40I is disposed near the center in the first direction x. In the illustrated example, the semiconductor elements 40Q, 40N, 40G to 40K, 40P, and 40R are aligned in the first direction x and located at the same (or substantially the same) position in the second direction y.

The semiconductor elements 4 (the semiconductor elements 40Q, 40N, 40G to 40K, 40P, and 40R) shown in FIG. 16 have the following relationships regarding the distance between the centers of adjacent semiconductor elements 4 in the first direction x. The third distance D3 between the center C7 of the semiconductor element 40I located near the center in the first direction x and the center C8 of the semiconductor element 40J that is adjacent to the semiconductor element 40I on the x1 side in the first direction x, and the fourth distance D4 between the center C7 of the semiconductor element 401 and the center C9 of the semiconductor element 40H that is adjacent to the semiconductor element 401 on the x2 side in the first direction x, are each greater than the fifth distance D51 between the center C8 of the semiconductor element 40J and the center C10 of the semiconductor element 40K that is adjacent to the semiconductor element 40J in the first direction x. Each of the third distance D3 and the fourth distance D4 is also greater than the fifth distance D52 between the center C9 of the semiconductor element 40H and the center C11 of the semiconductor element 40G that is adjacent to the semiconductor element 40H in the first direction x. In the illustrated example, each of the distance (the third distance D3) between the center C7 of the semiconductor element 401 and the center C8 of the semiconductor element 40J and the distance (the fourth distance D4) between the center C7 of the semiconductor element 40I and the center C9 of the semiconductor element 40H is at least twice the length (length L1) of a side of each semiconductor element 4 along the first direction x.

The distance (the fifth distance D51) between the center C8 of the semiconductor element 40J and the center C10 of the semiconductor element 40K is greater than the distance (a seventh distance D71) between the center C10 of the semiconductor element 40K and a center C14 of the semiconductor element 40P that are adjacent to each other in the first direction x. The distance (the fifth distance D52) between the center C9 of the semiconductor element 40H and the center C11 of the semiconductor element 40G is greater than the distance (a seventh distance D72) between the center C11 of the semiconductor element 40G and a center C15 of the semiconductor element 40N that are adjacent to each other in the first direction x.

As shown in FIG. 16, the distance (the seventh distance D71) between the center C10 of the semiconductor element 40K and the center C14 of the semiconductor element 40P that are adjacent to each other in the first direction x is greater than the distance (a seventh distance D73) between the center C14 of the semiconductor element 40P and the center C16 of the semiconductor element 40R that are adjacent to each other in the first direction x. The semiconductor element 40R is located farther away from the center in the first direction x than the semiconductor element 40P. The distance (the seventh distance D72) between the center C11 of the semiconductor element 40G and the center C15 of the semiconductor element 40N that are adjacent to each other in the first direction x is greater than the distance (a seventh distance D74) between the center C15 of the semiconductor element 40N and a center C17 of the semiconductor element 40Q that are adjacent to each other in the first direction x. The semiconductor element 40Q is located farther away from the center in the first direction x than the semiconductor element 40N.

The semiconductor elements 40Q, 40N, 40G to 40K, 40P, and 40R include the semiconductor element 40I (the third semiconductor element) near the center in the first direction x, the semiconductor element 40J (the fourth semiconductor element) adjacent to the semiconductor element 40I on the x1 side in the first direction x, and the semiconductor element 40H (the fifth semiconductor element) adjacent to the semiconductor element 401 on the x2 side in the first direction x. Each of the distance (the third distance D3) between the center C7 of the semiconductor element 401 and the center C8 of the semiconductor element 40J and the distance (the fourth distance D4) between the center C7 of the semiconductor element 40I and the center C9 of the semiconductor element 40H is greater than the distance (the fifth distance D51) between the center C8 of the semiconductor element 40J and the center C10 of the semiconductor element 40K adjacent to the semiconductor element 40J in the first direction x, and is also greater than the distance (the fifth distance D52) between the center C9 of the semiconductor element 40H and the center C11 of the semiconductor element 40G. This configuration can suppress the thermal interference between the semiconductor element 40I near the center among the semiconductor elements 40Q, 40N, 40G to 40K, 40P, and 40R and each of the semiconductor elements 40J and 40H that are adjacent to the semiconductor element 40I. This makes it possible to prevent the concentration of heat generated by the semiconductor elements 40G to 40K and reduce the thermal resistance. As a result, the semiconductor device can easily handle large currents and improve durability.

Each of the distance (the third distance D3) between the center C7 of the semiconductor element 40I and the center C8 of the semiconductor element 40J and the distance (the fourth distance D4) between the center C7 of the semiconductor element 401 and the center C9 of the semiconductor element 40H is at least twice the length (length L1) of a side of each semiconductor element 4 along the first direction x. This configuration can appropriately suppress the thermal interference between the semiconductor element 40I located near the center among the semiconductor elements 40Q, 40N, 40G to 40K, 40P, and 40R and each of the semiconductor elements 40J and 40H that are adjacent to the semiconductor element 40I. The above configuration is more preferable for reducing the thermal resistance of the semiconductor device.

The distance (the fifth distance D51) between the center C8 of the semiconductor element 40J and the center C10 of the semiconductor element 40K is greater than the distance (the seventh distance D71) between the center C10 of the semiconductor element 40K and the center C14 of the semiconductor element 40P. The distance (the seventh distance D71) between the center C10 of the semiconductor element 40K and the center C14 of the semiconductor element 40P is greater than the distance (the seventh distance D73) between the center C14 of the semiconductor element 40P and the center C16 of the semiconductor element 40R. The distance (the fifth distance D52) between the center C9 of the semiconductor element 40H and the center C11 of the semiconductor element 40G is greater than the distance (the seventh distance D72) between the center C11 of the semiconductor element 40G and the center C15 of the semiconductor element 40N. The distance (the seventh distance D72) between the center C11 of the semiconductor element 40G and the center C15 of the semiconductor element 40N is greater than the distance (the seventh distance D74) between the center C15 of the semiconductor element 40N and the center C17 of the semiconductor element 40Q. According to this configuration, the semiconductor elements 4 (the semiconductor elements 40Q, 40N, 40G to 40K, 40P, and 40R) are disposed such that the distance between adjacent semiconductor elements 4 in the first direction x decreases with increasing distance from the center in the first direction x. This makes it possible to suppress the thermal interference between the semiconductor elements 4 (the semiconductor elements 40Q, 40N, 40G to 40K, 40P, and 40R) and reduce the dimension of the semiconductor device in the first direction x.

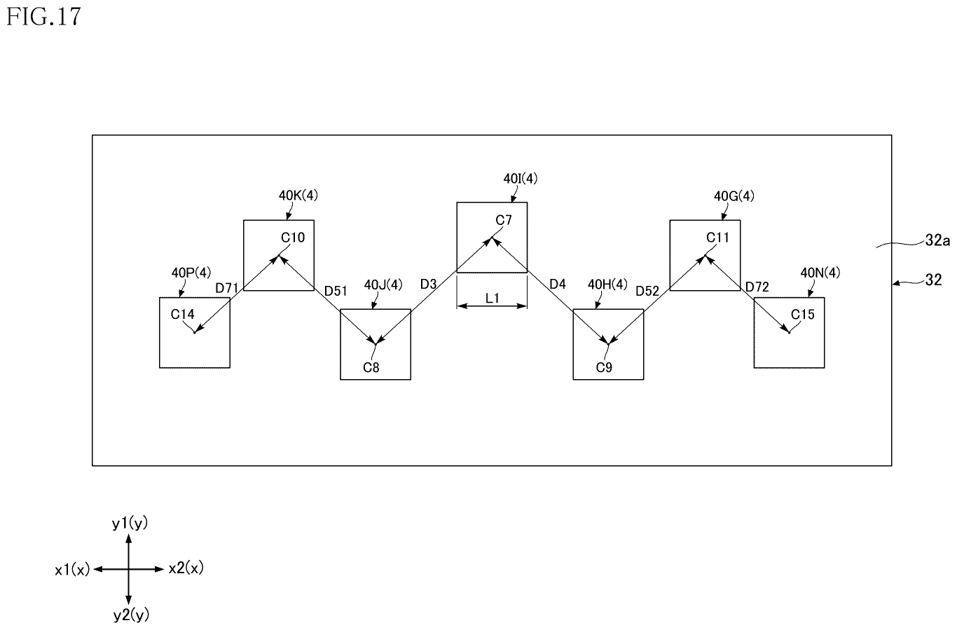

In the arrangement example of the semiconductor elements 4 shown in FIG. 17, the semiconductor elements 4 include seven semiconductor elements 40G to 40K, 40N, and 40P. The semiconductor elements 4 (the semiconductor elements 40N, 40G to 40K, and 40P) are disposed side by side in the first direction x. The semiconductor element 40N is located at the end on the x2 side in the first direction x, the semiconductor element 40P is located at the end on the x1 side in the first direction x, and the semiconductor elements 40N, 40G to 40K, and 40P are disposed in this order from the x2 side in the first direction x to the x1 side in the first direction x. As shown in FIG. 17, when the number of semiconductor elements 4 (the semiconductor elements 40N, 40G to 40K, and 40P) is odd, the semiconductor element 40I is disposed near the center in the first direction x.

In the illustrated example, the semiconductor elements 40N, 40G to 40K, and 40P include those that are not aligned along the first direction x and are located at different positions in the second direction y. The semiconductor element 40G is offset to the y1 side in the second direction y with respect to the semiconductor element 40N adjacent on the x2 side in the first direction x. The semiconductor element 40H is offset to the y2 side in the second direction y with respect to the semiconductor element 40G adjacent on the x2 side in the first direction x. The semiconductor element 40I is offset to the y1 side in the second direction y with respect to the semiconductor element 40H adjacent on the x2 side in the first direction x. The semiconductor element 40J is offset to the y2 side in the second direction y with respect to the semiconductor element 40I adjacent on the x2 side in the first direction x. The semiconductor element 40K is offset to the y1 side in the second direction y with respect to the semiconductor element 40J adjacent on the x2 side in the first direction x. The semiconductor element 40P is offset to the y2 side in the second direction y with respect to the semiconductor element 40K adjacent on the x2 side in the first direction x. As shown in FIG. 17, the semiconductor elements 40N, 40G to 40K, and 40P are disposed in zigzags in the second direction y.

The semiconductor elements 4 (the semiconductor elements 40N, 40G to 40K, and 40P) shown in FIG. 17 have the following relationships regarding the distance between the centers of adjacent semiconductor elements 4 in the first direction x. The third distance D3 between the center C7 of the semiconductor element 401 located near the center in the first direction x and the center C8 of the semiconductor element 40J that is adjacent to the semiconductor element 401 on the x1 side in the first direction x, and the fourth distance D4 between the center C7 of the semiconductor element 40I and the center C9 of the semiconductor element 40H that is adjacent to the semiconductor element 401 on the x2 side in the first direction x, are each greater than the fifth distance D51 between the center C8 of the semiconductor element 40J and the center C10 of the semiconductor element 40K that is adjacent to the semiconductor element 40J in the first direction x. Each of the third distance D3 and the fourth distance D4 is also greater than the fifth distance D52 between the center C9 of the semiconductor element 40H and the center C11 of the semiconductor element 40G that is adjacent to the semiconductor element 40H in the first direction x. In the illustrated example, each of the distance (the third distance D3) between the center C7 of the semiconductor element 40I and the center C8 of the semiconductor element 40J and the distance (the fourth distance D4) between the center C7 of the semiconductor element 40I and the center C9 of the semiconductor element 40H is at least twice the length (length L1) of a side of each semiconductor element 4 along the first direction x.

The distance (the fifth distance D51) between the center C8 of the semiconductor element 40J and the center C10 of the semiconductor element 40K is greater than the distance (the seventh distance D71) between the center C10 of the semiconductor element 40K and the center C14 of the semiconductor element 40P that are adjacent to each other in the first direction x. The distance (the fifth distance D52) between the center C9 of the semiconductor element 40H and the center C11 of the semiconductor element 40G is greater than the distance (the seventh distance D72) between the center C11 of the semiconductor element 40G and the center C15 of the semiconductor element 40N that are adjacent to each other in the first direction x.

The semiconductor elements 40N, 40G to 40K, and 40P shown in FIG. 17 include the semiconductor element 40I (the third semiconductor element) near the center in the first direction x, the semiconductor element 40J (the fourth semiconductor element) adjacent to the semiconductor element 40I on the x1 side in the first direction x, and the semiconductor element 40H (the fifth semiconductor element) adjacent to the semiconductor element 40I on the x2 side in the first direction x. Each of the distance (the third distance D3) between the center C7 of the semiconductor element 40I and the center C8 of the semiconductor element 40J and the distance (the fourth distance D4) between the center C7 of the semiconductor element 40I and the center C9 of the semiconductor element 40H is greater than the distance (the fifth distance D51) between the center C8 of the semiconductor element 40J and the center C10 of the semiconductor element 40K adjacent to the semiconductor element 40J in the first direction x, and is also greater than the distance (the fifth distance D52) between the center C9 of the semiconductor element 40H and the center C11 of the semiconductor element 40G. This configuration can suppress the thermal interference between the semiconductor element 401 located near the center among the semiconductor elements 40N, 40G to 40K, and 40P and each of the semiconductor elements 40J and 40H that are adjacent to the semiconductor element 40I. This makes it possible to prevent the concentration of heat generated by the semiconductor elements 40G to 40K and reduce the thermal resistance. As a result, the semiconductor device can easily handle large currents and improve durability.

Each of the distance (the third distance D3) between the center C7 of the semiconductor element 40I and the center C8 of the semiconductor element 40J and the distance (the fourth distance D4) between the center C7 of the semiconductor element 401 and the center C9 of the semiconductor element 40H is at least twice the length (length L1) of a side of each semiconductor element 4 along the first direction x. This configuration can appropriately suppress the thermal interference between the semiconductor element 401 located near the center among the semiconductor elements 40N, 40G to 40K, and 40P and each of the semiconductor elements 40J and 40H that are adjacent to the semiconductor element 40I. The above configuration is more preferable for reducing the thermal resistance of the semiconductor device.

The center C7 of the semiconductor element 401 and each of the center C8 of the semiconductor element 40J and the center C9 of the semiconductor element 40H are located at different positions in the second direction y perpendicular to the first direction x in which the semiconductor elements 40N, 40G to 40K, and 40P are disposed side by side. According to this configuration, heat generated by the semiconductor element 40I disposed near the center among the semiconductor elements 40N, 40G to 40K, and 40P and by the semiconductor elements 40J and 40H that are adjacent to the semiconductor element 40I can be efficiently released to the surrounding environment, whereby thermal interference is further suppressed. In addition, the above configuration can increase the distance (the third distance D3) between the center C7 of the semiconductor element 40I and the center C8 of the semiconductor element 40J and the distance (the fourth distance D4) between the center C7 of the semiconductor element 40I and the center C9 of the semiconductor element 40H, while preventing an increase in the dimension of the semiconductor device in the first direction x.

The centers of semiconductor elements 4 adjacent in the first direction x out of the semiconductor elements 4 (the semiconductor elements 40N, 40G to 40K, and 40P) are located at different positions in the second direction y. According to this configuration, heat generated by the semiconductor elements 40N, 40G to 40K, and 40P can be efficiently released to the surrounding environment. As shown in FIG. 17, the semiconductor elements 40N, 40G to 40K, and 40P are disposed in zigzags in the second direction y. The above configuration can prevent an increase in the dimensions of the semiconductor device in the first direction x and the second direction y while maintaining a desirable distance between the centers of semiconductor elements 4 adjacent in the first direction x out of the semiconductor elements 4 (the semiconductor elements 40N, 40G to 40K, and 40P).

The distance (the fifth distance D51) between the center C8 of the semiconductor element 40J and the center C10 of the semiconductor element 40K is greater than the distance (the seventh distance D71) between the center C10 of the semiconductor element 40K and the center C14 of the semiconductor element 40P. The distance (the fifth distance D52) between the center C9 of the semiconductor element 40H and the center C11 of the semiconductor element 40G is greater than the distance (the seventh distance D72) between the center C11 of the semiconductor element 40G and the center C15 of the semiconductor element 40N. According to this configuration, the semiconductor elements 4 (the semiconductor elements semiconductor elements 40N, 40G to 40K, and 40P) are disposed such that the distance between adjacent semiconductor elements 4 in the first direction x decreases with increasing distance from the center in the first direction x. This makes it possible to suppress the thermal interference between the semiconductor elements 4 (the semiconductor elements 40N, 40G to 40K, and 40P) and reduce the dimension of the semiconductor device in the first direction x.

### Second Embodiment

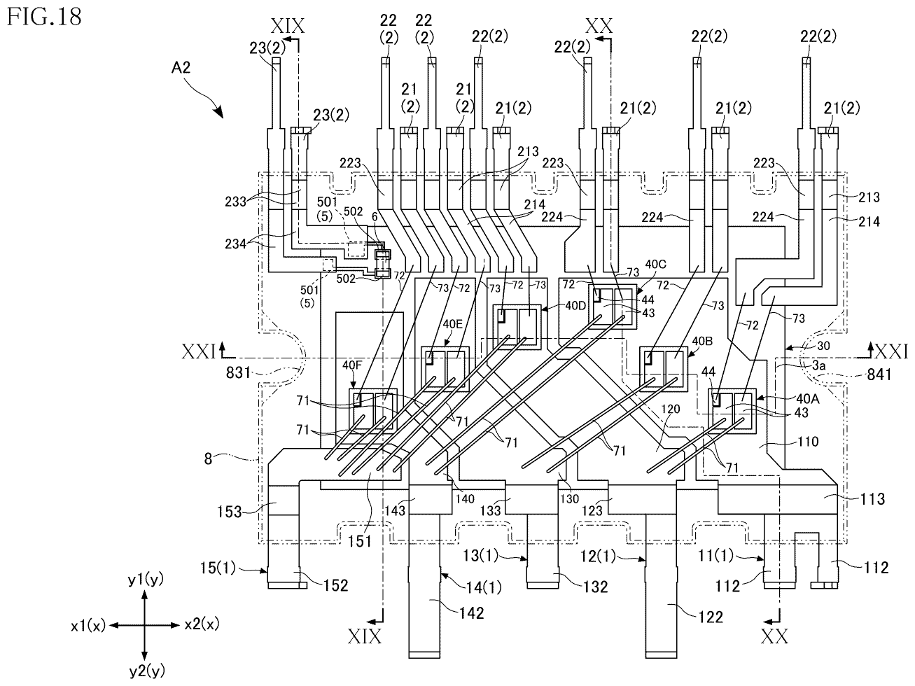

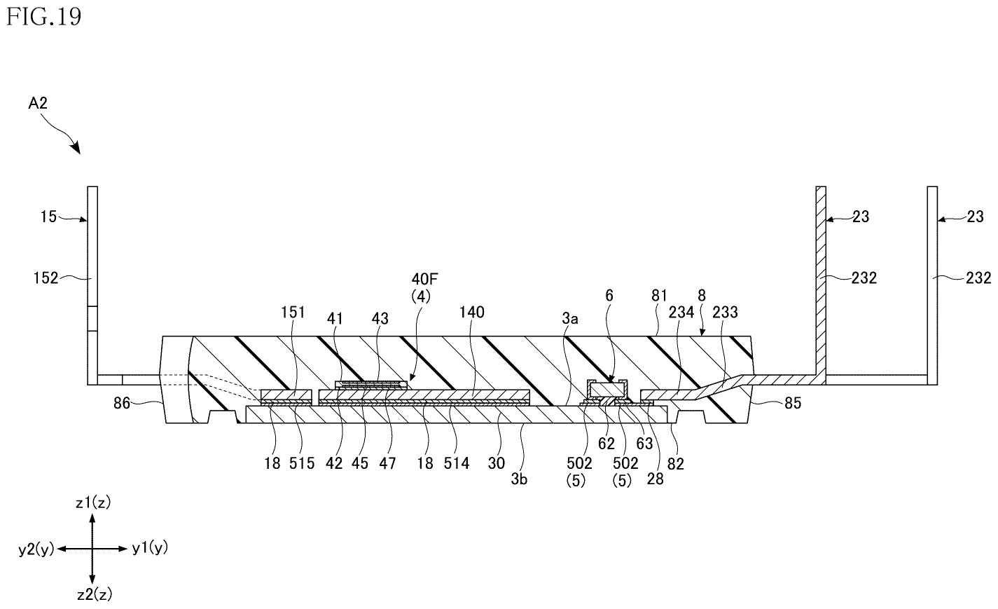

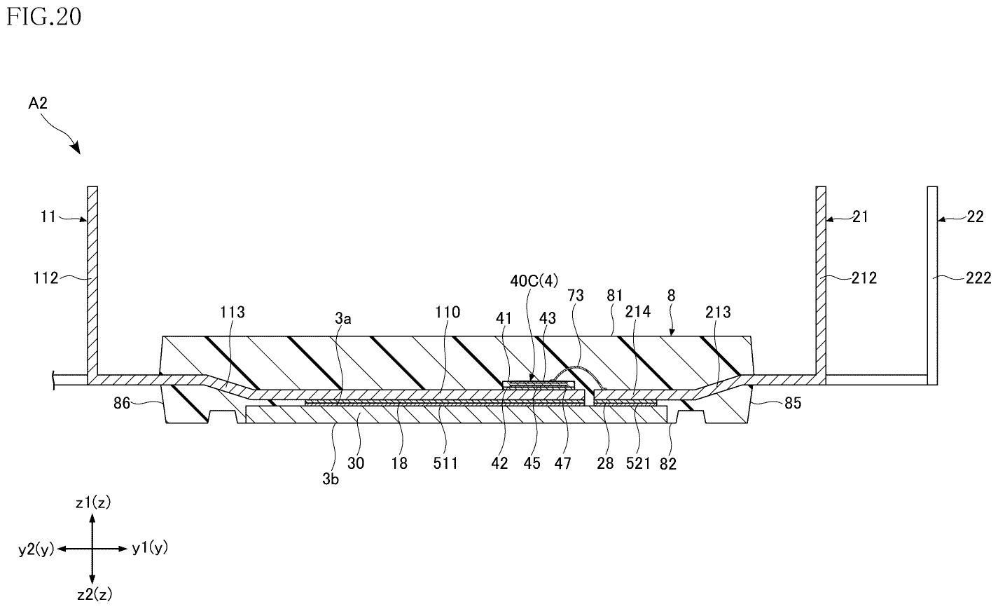

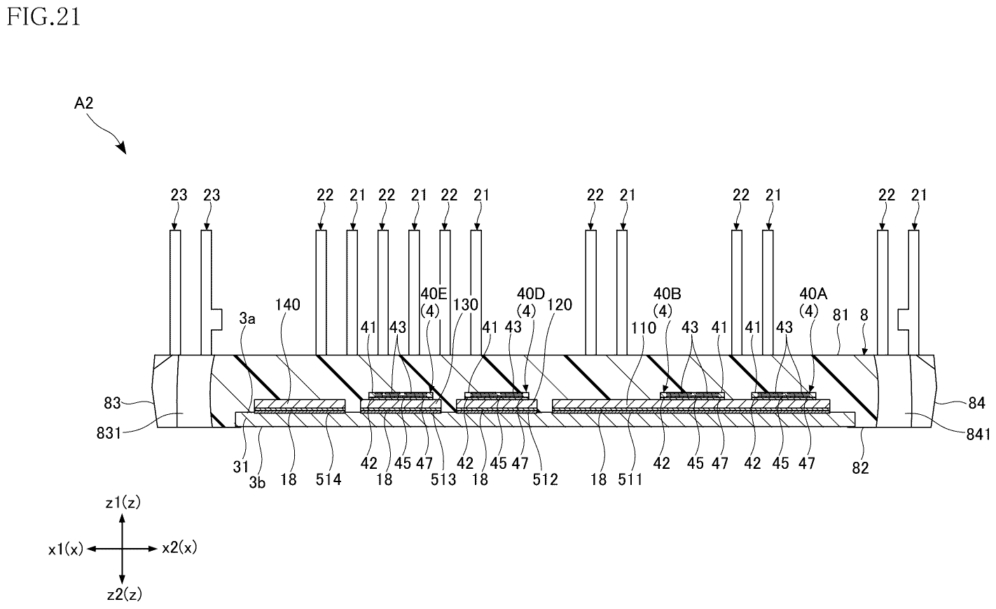

FIGS. 18 to 21 show a semiconductor device according to a second embodiment of the present disclosure. A semiconductor device A2 of the present embodiment includes a plurality of leads 1 (leads 11 to 15), a plurality of leads 2 (a plurality of leads 21, a plurality of leads 22, and two leads 23), an insulating substrate 30, a plurality of semiconductor elements 4 (semiconductor elements 40A to 40F), a wiring portion 5, a plurality of bonding portions 511 to 515, a bonding portion 521, a thermistor 6, a plurality of wires 71, a plurality of wires 72, a plurality of wires 73, and a sealing resin 8. FIG. 18 is a plan view showing the semiconductor device A2, as seen through the sealing resin 8. FIG. 19 is a cross-sectional view taken along line XIX-XIX in FIG. 18. FIG. 20 is a cross-sectional view taken along line XX-XX in FIG. 18. FIG. 21 is a cross-sectional view taken along line XXI-XXI in FIG. 18. In FIG. 18, the outline of the sealing resin 8 is indicated by an imaginary line (two-dot chain line). FIGS. 19 to 21 omit the wires 71. FIGS. 19 and 21 omit the wires 72 and 73.

The semiconductor device A2 of the present embodiment is different from the semiconductor device in the above embodiment mainly in that the semiconductor device A2 includes the insulating substrate 30 instead of the support 3 in the above embodiment, and in the configurations of the leads 1 (the leads 11 to 15) and the leads 2 (the leads 21, the leads 22, and the two leads 23), and the configuration of the wiring portion 5.

The insulating substrate 30 supports the semiconductor elements 40A to 40F. The material of the insulating substrate 30 is not particularly limited. It is preferable that the material of the insulating substrate 30 have a thermal conductivity higher than that of the sealing resin 8, for example. Examples of the material of the insulating substrate 30 include ceramics such as alumina (Al₂O₃), silicon nitride (SiN), aluminum nitride (AlN), and zirconia-containing alumina. The thickness of the insulating substrate 30 is not particularly limited, and may be approximately 0.1 mm to 1.0 mm.

The shape of the insulating substrate 30 is not particularly limited. As shown in FIGS. 18 to 21, the insulating substrate 30 of the present embodiment has a second obverse surface 3a and a second reverse surface 3b. The second obverse surface 3a faces the z1 side in the thickness direction z. The second reverse surface 3b faces the opposite side (the z2 side in the thickness direction z) from the second obverse surface 3a. In the present embodiment, the second reverse surface 3b is exposed from the sealing resin 8. A heat dissipating member (e.g., a heat sink), which is not shown in the figures, can be attached to the second reverse surface 3b. In the illustrated example, the insulating substrate 30 is rectangular in plan view. The insulating substrate 30 has a rectangular shape elongated in the first direction x as viewed in the thickness direction z. The insulating substrate 30 is an example of a “support” in the present disclosure, and the support is formed from the insulating substrate 30. The wiring portion 5 is formed on the insulating substrate 30. In the present embodiment, the wiring portion 5 is formed on the second obverse surface 3a of the insulating substrate 30. The wiring portion 5 is made of a conductive material. The conductive material of the wiring portion 5 is not particularly limited. The conductive material of the wiring portion 5 may contain silver (Ag), copper (Cu), or gold (Au). The following description is provided with an example where the wiring portion 5 contains silver. Note that the wiring portion 5 may contain copper instead of silver, or may contain gold instead of silver or copper. Alternatively, the wiring portion 5 may contain Ag-Pt or Ag-Pd. The method for forming the wiring portion 5 is not particularly limited. For example, the wiring portion 5 may be formed by sintering a paste containing these metals. The thickness of the wiring portion 5 is not particularly limited, and may be approximately 5 μm to 30 μm.

The shape, etc., of the wiring portion 5 is not particularly limited. In the present embodiment, the wiring portion 5 includes two wirings 501 as shown in FIGS. 18 and 19. The two wirings 501 are disposed near the corner of the insulating substrate 30 on the x1 side in the first direction x and on the y1 side in the second direction y. The two wirings 501 are spaced apart from each other and aligned in the second direction y. Each of the wirings 501 has a pad portion 502. The pad portion 502 is located at the end of the wiring 501 on the x2 side in the first direction x. The two pad portions 502 are bonded to respective terminals of the thermistor 6.

As shown in FIGS. 19 to 21, the bonding portions 511 to 515 and the bonding portion 521 are formed on the insulating substrate 30. In the present embodiment, the bonding portions 511 to 515 and the bonding portion 521 are formed on the second obverse surface 3a of the insulating substrate 30. The material of the bonding portions 511 to 515 and the bonding portion 521 is not particularly limited. For example, the bonding portions 511 to 515 and the bonding portion 521 may be made of a material capable of bonding the insulating substrate 30 and the leads 1. The bonding portions 511 to 515 and the bonding portion 521 may be made of a conductive material, for example. The conductive material of the bonding portions 511 to 515 and the bonding portion 521 is not particularly limited. The conductive material of the bonding portions 511 to 515 and the bonding portion 521 may contain silver (Ag), copper (Cu), or gold (Au). The following description is provided with an example where the bonding portions 511 to 515 and the bonding portion 521 contain silver. The bonding portions 511 to 515 and the bonding portion 521 in this example contain the same conductive material as that of the wiring portion 5. Note that the bonding portions 511 to 515 and the bonding portion 521 may contain copper instead of silver, or may contain gold instead of silver or copper. Alternatively, the bonding portions 511 to 515 and the bonding portion 521 may contain Ag—Pt or Ag—Pd. The method for forming the bonding portions 511 to 515 and the bonding portion 521 is not particularly limited. For example, as with the wiring portion 5, the bonding portions 511 to 515 and the bonding portion 521 may be formed by sintering a paste containing the metals mentioned above. The thickness of each of the bonding portions 511 to 515 and the bonding portion 521 is not particularly limited, and may be approximately 5 μm to 30 μm.

Each of the leads 1 contain a metal, and has a heat dissipation property better than that of the insulating substrate 30, for example. The metal in each lead 1 is not particularly limited, and may be copper, aluminum, iron (Fe), oxygen-free copper, or any of the alloys thereof (e.g., Cu—Sn alloy, Cu—Zr alloy, Cu—Fe alloy, etc.). The leads 1 may be plated with nickel (Ni). The leads 1 may be formed by pressing a die onto a metal plate, or may be formed by patterning a metal plate by etching. However, the method for forming the leads 1 is not limited to this. The thickness of each lead 1 is not particularly limited, and may be approximately 0.4 mm to 0.8 mm. The leads 1 are spaced apart from each other.

In the present embodiment, the leads 1 include a lead 11, a lead 12, a lead 13, a lead 14, and a lead 15. The lead 11, the lead 12, the lead 13, the lead 14, and the lead 15 form the conductive paths to the semiconductor elements 4, for example.

The lead 11 is disposed on the insulating substrate 30. In the present embodiment, the lead 11 is disposed on the second obverse surface 3a. The lead 11 is bonded to the bonding portion 511 via a bonding material 18. The bonding material 18 may be any material capable of bonding the lead 11 to the bonding portion 511. In terms of efficiently transmitting heat from the lead 11 to the insulating substrate 30, the bonding material 18 preferably has a relatively high thermal conductivity, such as silver paste, copper paste, or solder. Alternatively, the bonding material 18 may be an insulating material such as an epoxy resin or a silicone resin. If the bonding portion 511 is not formed on the insulating substrate 30, the lead 11 may be bonded to the insulating substrate 30.

The configuration of the lead 11 is not particularly limited. In the present embodiment, the lead 11 is divided into a mounting portion 110, a protruding portion 112, and an inclined portion 113 for description, as shown in FIGS. 18, 20, and 21.

The mounting portion 110 is offset to the x2 side in the first direction x on the second obverse surface 3a of the insulating substrate 30. The semiconductor elements 40A, 40B, and 40C are disposed on the upper surface (a first obverse surface facing the z1 side in the thickness direction z) of the mounting portion 110. The mounting portion 110 forms a part of the “conductor” of the present disclosure. Unlike the illustrated example, the mounting portion 110 may have a plurality of recesses that are recessed from the upper surface of the mounting portion 110 to the z2 side in the thickness direction z. The lower surface (a first reverse surface facing the z2 side in the thickness direction z) of the mounting portion 110 is bonded to the bonding portion 511 via the bonding material 18. The inclined portion 113 is connected to the mounting portion 110, and is inclined relative to the mounting portion 110. The protruding portion 112 is connected to the inclined portion 113, and a large part of the protruding portion 112 protrudes from the sealing resin 8. In the illustrated example, two protruding portions 112 are provided with a space therebetween in the first direction x. The protruding portions 112 protrude to the side opposite from the mounting portion 110 in the second direction y. The protruding portions 112 may be used to electrically connect the semiconductor device A2 to an external circuit. In the illustrated example, the protruding portions 112 are bent toward the side that the second obverse surface 3a of the insulating substrate 30 faces in the thickness direction z.

The lead 12 is disposed on the insulating substrate 30. In the present embodiment, the lead 12 is disposed on the second obverse surface 3a. The lead 12 is bonded to the bonding portion 512 via a bonding material 18. The configuration of the lead 12 is not particularly limited.

In the present embodiment, the lead 12 is divided into a mounting portion 120, a protruding portion 122, and an inclined portion 123 for description, as shown in FIGS. 18 and 21.

The mounting portion 120 is offset to the x1 side in the first direction x relative to the mounting portion 110, and is adjacent to the mounting portion 110. The semiconductor element 40D is disposed on the upper surface (a first obverse surface facing the z1 side in the thickness direction z) of the mounting portion 120. The mounting portion 120 forms a part of the “conductor” of the present disclosure. Unlike the illustrated example, the mounting portion 120 may have a plurality of recesses that are recessed from the upper surface of the mounting portion 120 to the z2 side in the thickness direction z. The lower surface (a first reverse surface facing the z2 side in the thickness direction z) of the mounting portion 120 is bonded to the bonding portion 512 via a bonding material 18. The inclined portion 123 is connected to the mounting portion 120, and is inclined relative to the mounting portion 120. The protruding portion 122 is connected to the inclined portion 123, and a large part of the protruding portion 122 protrudes from the sealing resin 8. The protruding portion 122 protrudes to the side opposite from the mounting portion 120 in the second direction y. The protruding portion 122 may be used to electrically connect the semiconductor device A2 to an external circuit. In the illustrated example, the protruding portion 122 is bent toward the side that the second obverse surface 3a of the insulating substrate 30 faces in the thickness direction z.

The lead 13 is disposed on the insulating substrate 30. In the present embodiment, the lead 13 is disposed on the second obverse surface 3a. The lead 13 is bonded to the bonding portion 513 via a bonding material 18. The configuration of the lead 13 is not particularly limited. In the present embodiment, the lead 13 is divided into a mounting portion 130, a protruding portion 132, and an inclined portion 133 for description, as shown in FIGS. 18 and 21.

The mounting portion 130 is offset to the x1 side in the first direction x relative to the mounting portion 120, and is adjacent to the mounting portion 120. The semiconductor element 40E is disposed on the upper surface (a first obverse surface facing the z1 side in the thickness direction z) of the mounting portion 130. The mounting portion 130 forms a part of the “conductor” of the present disclosure. Unlike the illustrated example, the mounting portion 130 may have a plurality of recesses that are recessed from the upper surface of the mounting portion 130 to the z2 side in the thickness direction z. The lower surface (a first reverse surface facing the z2 side in the thickness direction z) of the mounting portion 130 is bonded to the bonding portion 513 via the bonding material 18. The inclined portion 133 is connected to the mounting portion 130, and is inclined relative to the mounting portion 130. The protruding portion 132 is connected to the inclined portion 133, and a large part of the protruding portion 132 protrudes from the sealing resin 8. The protruding portion 132 protrudes to the side opposite from the mounting portion 130 in the second direction y. The protruding portion 132 may be used to electrically connect the semiconductor device A2 to an external circuit. In the illustrated example, the protruding portion 132 is bent toward the side that the second obverse surface 3a of the insulating substrate 30 faces in the thickness direction z.

The lead 14 is disposed on the insulating substrate 30. In the present embodiment, the lead 14 is disposed on the second obverse surface 3a. The lead 14 is bonded to the bonding portion 514 via a bonding material 18. The configuration of the lead 14 is not particularly limited. In the present embodiment, the lead 14 is divided into a mounting portion 140, a protruding portion 142, and an inclined portion 143 for description, as shown in FIGS. 18, 19, and 21.

The mounting portion 140 is offset to the x1 side in the first direction x relative to the mounting portion 130, and is adjacent to the mounting portion 130. The semiconductor element 40F is disposed on the upper surface (a first obverse surface facing the z1 side in the thickness direction z) of the mounting portion 140. The mounting portion 140 forms a part of the “conductor” of the present disclosure. Unlike the illustrated example, the mounting portion 140 may have a plurality of recesses that are recessed from the upper surface of the mounting portion 140 to the z2 side in the thickness direction z. The lower surface (a first reverse surface facing the z2 side in the thickness direction z) of the mounting portion 140 is bonded to the bonding portion 514 via the bonding material 18. The inclined portion 143 is connected to the mounting portion 140, and is inclined relative to the mounting portion 140. The protruding portion 142 is connected to the inclined portion 143, and a large part of the protruding portion 142 protrudes from the sealing resin 8. The protruding portion 142 protrudes to the side opposite from the mounting portion 140 in the second direction y. The protruding portion 142 may be used to electrically connect the semiconductor device A2 to an external circuit. In the illustrated example, the protruding portion 142 is bent toward the side that the second obverse surface 3a of the insulating substrate 30 faces in the thickness direction z.

The lead 15 is disposed on the insulating substrate 30. In the present embodiment, the lead 15 is disposed on the second obverse surface 3a. As shown in FIGS. 18 and 19, the lead 15 is bonded to the bonding portion 515 via a bonding material 18. The configuration of the lead 15 is not particularly limited. In the present embodiment, the lead 15 is divided into a pad portion 151, a protruding portion 152, and an inclined portion 153 for description, as shown in FIGS. 18 and 19.

The pad portion 151 is covered with the sealing resin 8. The pad portion 151 is parallel to the insulating substrate 30. A wire 71 is bonded to the upper surface (the surface facing the z1 side in the thickness direction z) of the pad portion 151. The lower surface (the surface facing the z2 side in the thickness direction z) of the pad portion 151 is bonded to the bonding portion 515 via the bonding material 18. The inclined portion 153 is connected to the pad portion 151, and is inclined relative to the pad portion 151. The protruding portion 152 is connected to the inclined portion 153, and a large part of the protruding portion 152 protrudes from the sealing resin 8. The protruding portion 152 may be used to electrically connect the semiconductor device A2 to an external circuit. In the illustrated example, the protruding portion 152 is bent toward the side that the second obverse surface 3a of the insulating substrate 30 faces in the thickness direction Z.

Each of the leads 2 contain a metal, and has a thermal conductivity higher than that of the insulating substrate 30, for example. The metal in each lead 2 is not particularly limited, and may be copper, aluminum, iron (Fe), oxygen-free copper, or any of the alloys thereof (e.g., Cu—Sn alloy, Cu—Zr alloy, Cu—Fe alloy, etc.). The leads 2 may be plated with nickel (Ni). The leads 2 may be formed by pressing a die onto a metal plate, or may be formed by patterning a metal plate by etching. The method for forming the leads 2 is not particularly limited. The thickness of each lead 2 is not particularly limited, and may be approximately 0.4 mm to 0.8 mm. The leads 2 are spaced apart from each other.

Each of the leads 2 contain a metal, and has a thermal conductivity higher than that of the insulating substrate 30, for example. The metal in each lead 2 is not particularly limited, and may be copper, aluminum, iron (Fe), oxygen-free copper, or any of the alloys thereof (e.g., Cu—Sn alloy, Cu—Zr alloy, Cu—Fe alloy, etc.). The leads 2 may be plated with nickel (Ni). The leads 2 may be formed by pressing a die onto a metal plate, or may be formed by patterning a metal plate by etching. The method for forming the leads 2 is not particularly limited. The thickness of each lead 2 is not particularly limited, and may be approximately 0.4 mm to 0.8 mm. The leads 2 are spaced apart from each other.

In the present embodiment, the leads 2 include a plurality of leads 21, a plurality of leads 22, and two leads 23. The leads 21 and the leads 22 form conductive paths to source electrodes 43 and gate electrodes 44 of the semiconductor elements 4 (the semiconductor elements 40A to 40F). The two leads 23 form a conductive path to the thermistor 6.

The leads 21 are disposed on the insulating substrate 30. In the present embodiment, the leads 21 are disposed on the second obverse surface 3a. The leads 21 are provided at intervals in the first direction x. The configuration of each lead 21 is not particularly limited. In the present embodiment, each of the leads 21 is divided into a protruding portion 212, an inclined portion 213, and a parallel portion 214 for description, as shown in FIGS. 18 and 20.

The parallel portion 214 is covered with the sealing resin 8. The parallel portion 214 is parallel to the insulating substrate 30. The lower surface (the surface facing the z2 side in the thickness direction z) of the parallel portion 214 is bonded to the bonding portion 521 via a conductive bonding material 28. The inclined portion 213 is connected to an end of the parallel portion 214, and is inclined relative to the parallel portion 214. The protruding portion 212 is a portion of the lead 21 that protrudes from the sealing resin 8, and is connected to an end of the inclined portion 213. The protruding portion 212 protrudes from the sealing resin 8 to the y1 side in the second direction y. The protruding portion 212 may be used to electrically connect the semiconductor device A2 to an external circuit. In the illustrated example, the protruding portion 212 is bent toward the side that the second obverse surface 3a of the insulating substrate 30 faces in the thickness direction z.

The leads 22 are disposed on the insulating substrate 30. In the present embodiment, the leads 22 are disposed on the second obverse surface 3a. The leads 22 are provided at intervals in the first direction x. Each of the leads 22 is provided near one of the leads 21 to form a pair with the lead 21. The configuration of each lead 22 is not particularly limited. In the present embodiment, each of the leads 22 is divided into a protruding portion 222, an inclined portion 223, and a parallel portion 224 for description, as shown in FIG. 18.

The parallel portion 224 is covered with the sealing resin 8. The parallel portion 224 is parallel to the insulating substrate 30. The lower surface (the surface facing the z2 side in the thickness direction z) of the parallel portion 224 is bonded to the bonding portion 521 via a conductive bonding material 28. The inclined portion 223 is connected to an end of the parallel portion 224, and is inclined relative to the parallel portion 224. The protruding portion 222 is a portion of the lead 22 that protrudes from the sealing resin 8, and is connected to an end of the inclined portion 223. The protruding portion 222 protrudes from the sealing resin 8 to the y1 side in the second direction y. The protruding portion 222 may be used to electrically connect the semiconductor device A2 to an external circuit. In the illustrated example, the protruding portion 222 is bent toward the side that the second obverse surface 3a of the insulating substrate 30 faces in the thickness direction z.

The leads 23 are disposed on the insulating substrate 30. In the present embodiment, the leads 23 are disposed on the second obverse surface 3a. The two leads 23 are disposed side by side in the first direction x. The configuration of each lead 23 is not particularly limited. In the present embodiment, each of the leads 23 is divided into a protruding portion 232, an inclined portion 233, and a parallel portion 234 for description, as shown in FIGS. 18 and 19.

The parallel portion 234 is covered with the sealing resin 8. The parallel portion 234 is parallel to the insulating substrate 30. The lower surface (the surface facing the z2 side in the thickness direction z) of the parallel portion 234 is bonded to a wiring 501 via a conductive bonding material 28. The inclined portion 233 is connected to an end of the parallel portion 234, and is inclined relative to the parallel portion 234. The protruding portion 232 is a portion of the lead 23 that protrudes from the sealing resin 8, and is connected to an end of the inclined portion 233. The protruding portion 232 protrudes from the sealing resin 8 to the y1 side in the second direction y. The protruding portion 232 may be used to electrically connect the semiconductor device A2 to an external circuit. In the illustrated example, the protruding portion 232 is bent toward the side that the second obverse surface 3a of the insulating substrate 30 faces in the thickness direction Z.

As shown in FIGS. 20 and 21, each of the semiconductor elements 40A, 40B, and 40C is bonded to the mounting portion 110 via a conductive bonding material 47 with an element reverse surface 42 facing the mounting portion 110. As a result, a drain electrode 45 of each of the semiconductor elements 40A, 40B, and 40C is electrically connected to the mounting portion 110 via a conductive bonding material 47. The mounting portion 110 is an example of the “second portion” of the present disclosure.

As shown in FIG. 21, the semiconductor element 40D is bonded to the mounting portion 120 via a conductive bonding material 47 with an element reverse surface 42 facing the mounting portion 120. As a result, a drain electrode 45 of the semiconductor element 40D is electrically connected to the mounting portion 120 via the conductive bonding material 47. The mounting portion 120 is an example of the “first portion” of the present disclosure. As shown in FIG. 21, the semiconductor element 40E is bonded to the mounting portion 130 via a conductive bonding material 47 with an element reverse surface 42 facing the mounting portion 130. As a result, a drain electrode 45 of the semiconductor element 40E is electrically connected to the mounting portion 130 via the conductive bonding material 47. As shown in FIG. 19, the semiconductor element 40F is bonded to the mounting portion 140 via a conductive bonding material 47 with an element reverse surface 42 facing the mounting portion 140. As a result, a drain electrode 45 of the semiconductor element 40F is electrically connected to the mounting portion 140 via the conductive bonding material 47.

As shown in FIG. 18, in the present embodiment, the gate electrode 44 of each of the semiconductor elements 4 (the semiconductor elements 40A to 40F) is electrically connected to one of the leads 22 via a wire 72. The leads 22 are gate terminals of the semiconductor elements 4. The source electrode 43 of each of the semiconductor elements 4 (the semiconductor elements 40A to 40F) is electrically connected to one of the leads 21 via a wire 73. The leads 21 are source sense terminals of the semiconductor elements 4.

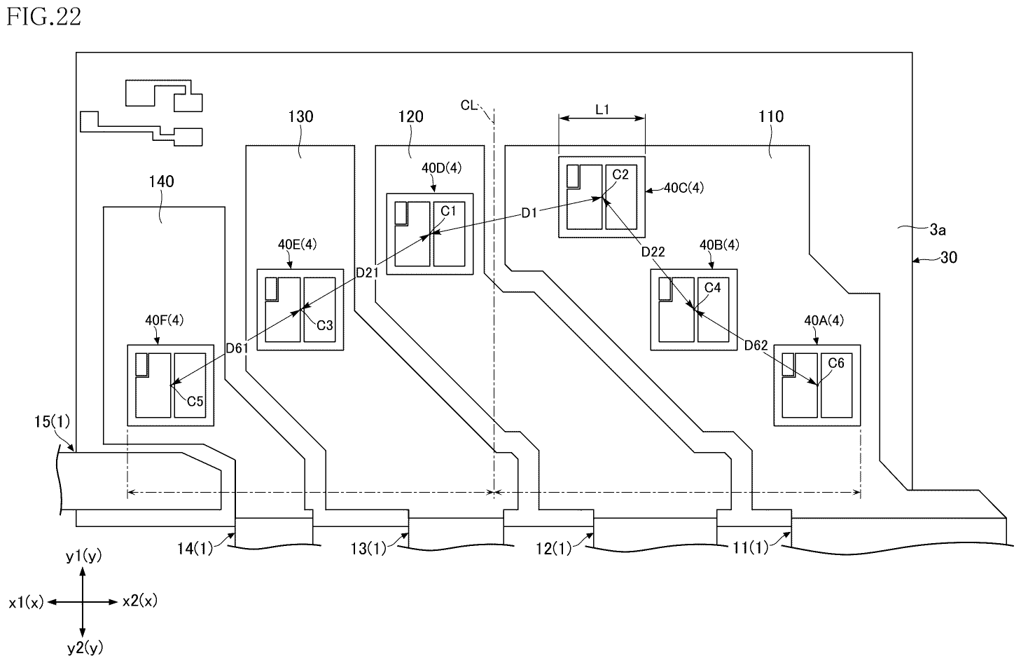

As shown in FIGS. 18 and 22, the semiconductor elements 4 (the semiconductor elements 40A to 40F) of the present embodiment are disposed side by side in the first direction x. The arrangement of the semiconductor elements 4 (the semiconductor elements 40A to 40F) is the same (or substantially the same) as that of the semiconductor device A1 of the above embodiment. The relationship between the center positions of the semiconductor elements 4 (the semiconductor elements 40A to 40F) and the distance between the centers of adjacent semiconductor elements 4, etc., are the same (or substantially the same) as those described in the above embodiment with reference to FIG. 9. Thus, the same reference numerals as in FIG. 9 associated with the above embodiment are provided in FIG. 22, and descriptions thereof are omitted.

As shown in FIG. 18, the thermistor 6 is disposed near the corner of the insulating substrate 30 on the x1 side in the first direction x and on the y1 side in the second direction y.

Next, advantages of the semiconductor device A2 according to the present embodiment will be described.

The semiconductor device A2 includes the insulating substrate 30, four or more semiconductor elements 4 (the semiconductor elements 40A to 40F), and the sealing resin 8. The semiconductor elements 40A to 40F include the semiconductor element 40D (the first semiconductor element) and the semiconductor element 40C (the second semiconductor element) that are located near the center in the first direction x. The distance (the first distance D1) between the center C1 of the semiconductor element 40D and the center C2 of the semiconductor element 40C is greater than the distance (the second distance D21) between the center C1 of the semiconductor element 40D and the center C3 of the semiconductor element 40E that is adjacent to the semiconductor element 40D in the first direction x, and is also greater than the distance (the second distance D22) between the center C2 of the semiconductor element 40C and the center C4 of the semiconductor element 40B that is adjacent to the semiconductor element 40C in the first direction x. This configuration can suppress the thermal interference between the semiconductor element 40D and the semiconductor element 40C that are located near the center among the semiconductor elements 40A to 40F. This makes it possible to prevent the concentration of heat generated by the semiconductor elements 40A to 40F and reduce the thermal resistance. As a result, the semiconductor device A2 can easily handle large currents and improve durability.

The center C1 of the semiconductor element 40D and the center C2 of the semiconductor element 40C are located at different positions in the second direction y perpendicular to the first direction x in which the semiconductor elements 40A to 40F are disposed side by side. According to this configuration, heat generated by the semiconductor element 40D and the semiconductor element 40C that are located near the center among the semiconductor elements 40A to 40F can be efficiently released to the surrounding environment, whereby thermal interference is further suppressed. In addition, the above configuration can increase the distance (the first distance D1) between the center C1 of the semiconductor element 40D and the center C2 of the semiconductor element 40C while preventing an increase in the dimension of the semiconductor device A2 in the first direction x. The semiconductor device A2 also has advantages similar to those of the semiconductor device A1 in the above embodiment.

As with the semiconductor device A1 in the semiconductor device assembly B2 described above, the semiconductor device A2 of the present embodiment can be provided for a semiconductor device assembly that includes a cooler 91, a mounting member 92, a control unit 94, a cooling unit 95, and a heating unit 96. As such, it is possible to achieve the same advantages as those described in connection with the semiconductor device assembly B2.

### Third Embodiment

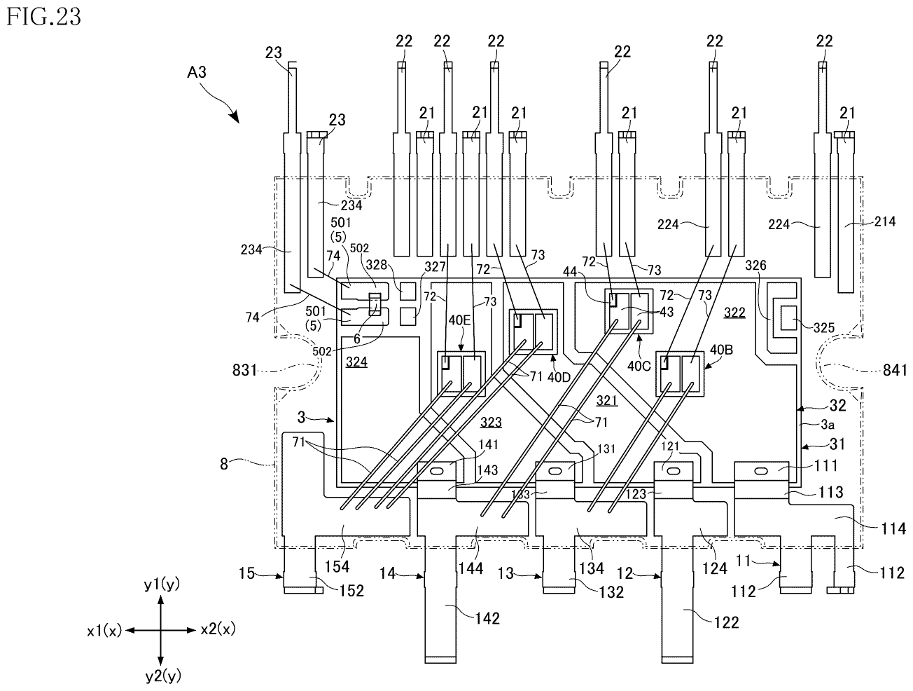

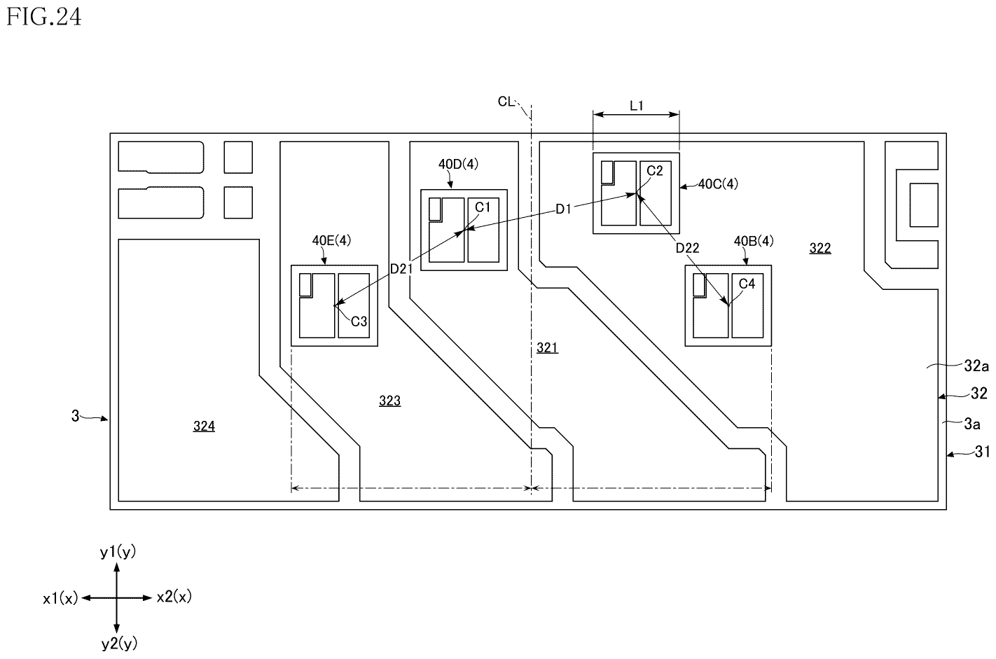

FIGS. 23 and 24 show a semiconductor device according to a third embodiment of the present disclosure. A semiconductor device A3 of the present embodiment includes a plurality of leads 1 (leads 11 to 15), a plurality of leads 2 (a plurality of leads 21, a plurality of leads 22, and two leads 23), a supporting conductor 32, a plurality of semiconductor elements 4 (semiconductor elements 40B, 40C, 40D, and 40E), a wiring portion 5, a thermistor 6, a plurality of wires 71, a plurality of wires 72, a plurality of wires 73, and a plurality of wires 74, and a sealing resin 8. FIG. 23 is a plan view showing the semiconductor device A3, as seen through the sealing resin 8. FIG. 24 is a schematic plan view showing the arrangement of the semiconductor elements 4 in the semiconductor device A3. In FIG. 23, the outline of the sealing resin 8 is indicated by an imaginary line (two-dot chain line).

The semiconductor device A3 of the present embodiment is different from the semiconductor device A1 of the above embodiment mainly in the arrangement of the semiconductor elements 4. The semiconductor device A3 of the present embodiment includes four semiconductor elements 4 (the semiconductor elements 40B, 40C, 40D, and 40E). The arrangement of the semiconductor elements 40B to 40E is the same (or substantially the same) as that of the semiconductor elements 40B to 40E in the semiconductor device A1. The semiconductor device A3 is configured as a full-bridge switching circuit, for example.

In the semiconductor device A3 including four (even number) semiconductor elements 4, the semiconductor element 40C and the semiconductor element 40D are disposed near the center in the first direction x. As can be seen in the present embodiment, when the number of semiconductor elements 4 (the semiconductor elements 40B to 40E) is even, two semiconductor elements, namely the semiconductor elements 40C and 40D, are disposed near the center in the first direction x among the semiconductor elements 4.

In the illustrated example, the semiconductor elements 40B to 40E include those that are not aligned along the first direction x and are located at different positions in the second direction y. The semiconductor element 40C is offset to the y1 side in the second direction y with respect to the semiconductor element 40B adjacent on the x2 side in the first direction x. In addition, the semiconductor element 40C is offset to the y1 side in the second direction y with respect to the semiconductor element 40D adjacent on the x1 side in the first direction x. The semiconductor element 40D is offset to the y1 side in the second direction y with respect to the semiconductor element 40E adjacent on the x1 side in the first direction x. The semiconductor element 40E is located at the same (or substantially the same) position as the semiconductor element 40B in the second direction y. Among the semiconductor elements 4 (the semiconductor elements 40B to 40E) disposed as described above, the semiconductor element 40D corresponds to an example of the “first semiconductor element” in the present disclosure, and the semiconductor element 40C corresponds to an example of the “second semiconductor element” in the present disclosure. A first conductor 321 on which the semiconductor element 40D (the first semiconductor element) is disposed corresponds to an example of the “first portion” in the present disclosure, and a second conductor 322 on which the semiconductor element 40C (the second semiconductor element) is disposed corresponds to an example of the “second portion” in the present disclosure.

The semiconductor elements 4 (the semiconductor elements 40B to 40E) shown in FIG. 24 have the following relationships regarding the distance between the centers of adjacent semiconductor elements 4 in the first direction x. The first distance D1 between the center C1 of the semiconductor element 40D and the center C2 of the semiconductor element 40C that are located near the center in the first direction x, is greater than the second distance D21 between the center C1 of the semiconductor element 40D and the center C3 of the semiconductor element 40E that is adjacent to the semiconductor element 40D in the first direction x. The distance (the first distance D1) between the center C1 of the semiconductor element 40D and the center C2 of the semiconductor element 40C is also greater than the second distance D22 between the center C2 of the semiconductor element 40C and the center C4 of the semiconductor element 40B that is adjacent to the semiconductor element 40C in the first direction x. In the present embodiment, the distance (the first distance D1) between the center C1 of the semiconductor element 40D and the center C2 of the semiconductor element 40C is at least twice the length (length L1) of a side of each semiconductor element 4 along the first direction x.

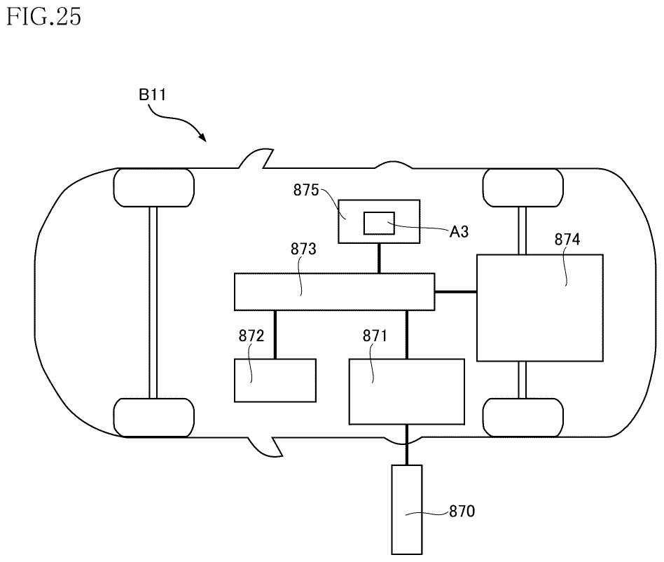

Next, a use example of the semiconductor device A3 will be described with reference to FIG. 25. FIG. 25 is a schematic view showing a vehicle B11 that includes the semiconductor device A3. The vehicle B11 includes an AC-DC conversion device 871, a power receiving device 872, a storage battery 873, a drive system 874, and a DC-DC conversion device 875. When the vehicle B11 receives AC power from a charging facility 870, which is an AC power source installed outdoors, for example, the AC-DC conversion device 871 converts the AC power into high-voltage DC power. The AC-DC conversion device 871 supplies the high-voltage DC power to the storage battery 873. The power receiving device 872 supplies power to the storage battery 873 via a non-contact charging system, and receives power from a non-contact charger (not illustrated) placed in a parking lot or the like by an electromagnetic induction method. The power stored in the storage battery 873 is supplied to the drive system 874 that includes an inverter, an AC motor, and a transmission. The drive system 874 drives the vehicle B11. The DC-DC conversion device 875 may be a step-down DC-DC converter, and supplies power to electrical components other than those used for driving the vehicle B11. The semiconductor device A3 forms a part of the “DC-DC conversion device 875”. The DC-DC conversion device 875 is an example of the “power conversion device” of the present disclosure.

Next, advantages of the semiconductor device A3 according to the present embodiment will be described.

The semiconductor device A3 includes a supporting conductor 32, four or more semiconductor elements 4 (the semiconductor elements 40B to 40E), and the sealing resin 8. The semiconductor elements 40B to 40E include the semiconductor element 40D (the first semiconductor element) and the semiconductor element 40C (the second semiconductor element) that are located near the center in the first direction x. The distance (the first distance D1) between the center C1 of the semiconductor element 40D and the center C2 of the semiconductor element 40C is greater than the distance (the second distance D21) between the center C1 of the semiconductor element 40D and the center C3 of the semiconductor element 40E that is adjacent to the semiconductor element 40D in the first direction x, and is also greater than the distance (the second distance D22) between the center C2 of the semiconductor element 40C and the center C4 of the semiconductor element 40B that is adjacent to the semiconductor element 40C in the first direction x. This configuration can suppress the thermal interference between the semiconductor element 40D and the semiconductor element 40C that are located near the center among the semiconductor elements 40B to 40E. This makes it possible to prevent the concentration of heat generated by the semiconductor elements 40B to 40E and reduce the thermal resistance. As a result, the semiconductor device A3 can easily handle large currents and improve durability.

The center C1 of the semiconductor element 40D and the center C2 of the semiconductor element 40C are located at different positions in the second direction y perpendicular to the first direction x in which the semiconductor elements 40B to 40E are disposed side by side. According to this configuration, heat generated by the semiconductor element 40D and the semiconductor element 40C that are located near the center among the semiconductor elements 40B to 40E can be efficiently released to the surrounding environment, whereby thermal interference is further suppressed. In addition, the above configuration can increase the distance (the first distance D1) between the center C1 of the semiconductor element 40D and the center C2 of the semiconductor element 40C while preventing an increase in the dimension of the semiconductor device A3 in the first direction x.

As shown in FIG. 24, the centers of semiconductor elements 4 adjacent in the first direction x out of the semiconductor elements 4 (the semiconductor elements 40B to 40E) are located at different positions in the second direction y. According to this configuration, heat generated by the semiconductor elements 40B to 40E can be efficiently released to the surrounding environment.

The distance (the first distance D1) between the center C1 of the semiconductor element 40D and the center C2 of the semiconductor element 40C is at least twice the length (length L1) of a side of each semiconductor element 4 along the first direction x. This configuration can appropriately suppress the thermal interference between the semiconductor element 40D and the semiconductor element 40C that are located near the center among the semiconductor elements 40B to 40E. The above configuration is more preferable for reducing the thermal resistance of the semiconductor device A3.

The supporting conductor 32 includes the first conductor 321 (the first portion) and the second conductor 322 (the second portion) that are spaced apart from each other. Of the semiconductor elements 40B to 40E, only the semiconductor element 40D (the first semiconductor element) is disposed on the first conductor 321. Of the semiconductor elements 40B to 40E, the semiconductor element 40C (the second semiconductor element) and the semiconductor element 40B that is adjacent to the semiconductor element 40C are disposed on the second conductor 322. The center C1 of the semiconductor element 40D (the first semiconductor element) is offset to the y1 side in the second direction y from the center of either of the semiconductor elements 40B and 40E in the second direction y. The center C2 of the semiconductor element 40C (the second semiconductor element) is offset to the y1 side in the second direction y from the center C1 of the semiconductor element 40D. Heat generated by the semiconductor element 40C and the semiconductor element 40B that are disposed on the common second conductor 322 tends to be trapped on the second conductor 322, and the interference of heat generated by the semiconductor element 40C and the semiconductor element 40B tends to cause a rise in the temperature of the second conductor 322. As described above, the semiconductor element 40C is disposed farthest to the y1 side in the second direction y among all the semiconductor elements 40B to 40E. According to this layout, the second conductor 322 on which the semiconductor element 40C is mounted can efficiently release heat generated by the semiconductor element 40C to the surroundings of the semiconductor element 40C. This makes it possible to suppress the thermal interference between the semiconductor elements 40D, 40C, and 40B, thereby reducing the thermal resistance of the semiconductor device A3.

### First Variation of Third Embodiment

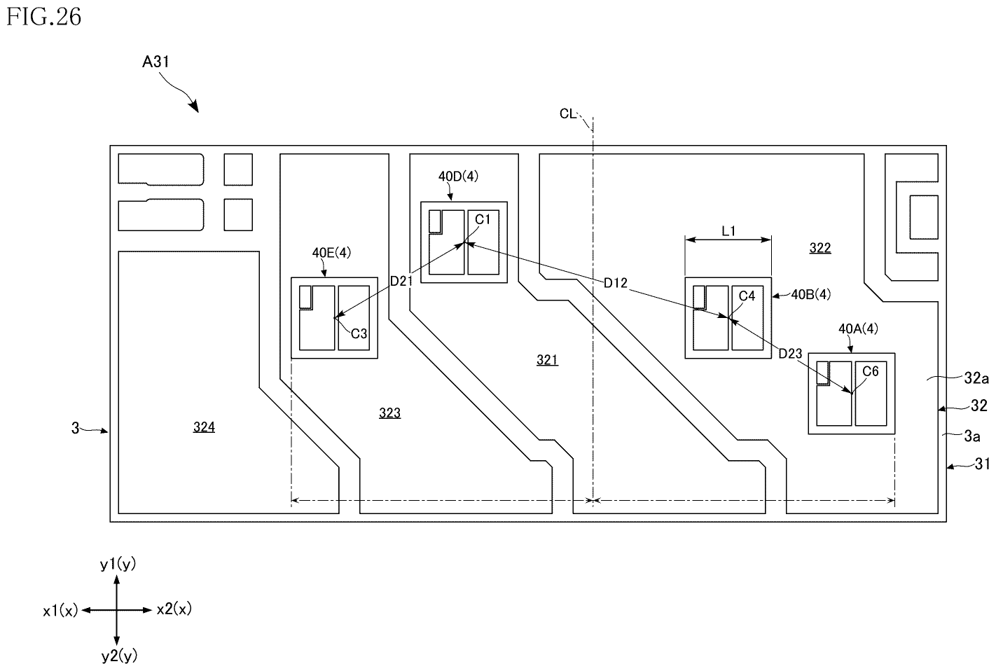

FIG. 26 shows a semiconductor device according to a first variation of the third embodiment. FIG. 26 is a schematic plan view showing the arrangement of the semiconductor elements 4 in a semiconductor device A31 of the present variation.

The semiconductor device A31 of the present variation is different from the semiconductor devices A1 and A3 of the above embodiments mainly in the arrangement of the semiconductor elements 4. The semiconductor device A31 includes four semiconductor elements 4 (the semiconductor elements 40A, 40B, 40D, and 40E). The arrangement of the semiconductor elements 40A, 40B, 40D, and 40E is the same (or substantially the same) as that of the semiconductor elements 40A, 40B, 40D, and 40E in the semiconductor device A1.

In the semiconductor device A31 including four (even number) semiconductor elements 4, the semiconductor element 40B and the semiconductor element 40D are disposed near the center in the first direction x. As can be seen in the present variation, when the number of semiconductor elements 4 (the semiconductor elements 40A, 40B, 40D, and 40E) is even, two semiconductor elements, namely the semiconductor elements 40B and 40D, are disposed near the center in the first direction x among the semiconductor elements 4.

In the illustrated example, the semiconductor elements 40A, 40B, 40D, and 40E include those that are not aligned along the first direction x and are located at different positions in the second direction y. The semiconductor element 40B is offset to the y1 side in the second direction y with respect to the semiconductor element 40A adjacent on the x2 side in the first direction x. The semiconductor element 40D is offset to the y1 side in the second direction y with respect to the semiconductor element 40B adjacent on the x2 side in the first direction x. In addition, the semiconductor element 40D is offset to the y1 side in the second direction y with respect to the semiconductor element 40E adjacent on the x1 side in the first direction x. The semiconductor element 40E is located at the same (or substantially the same) position as the semiconductor element 40B in the second direction y. Among the semiconductor elements 4 (the semiconductor elements 40A, 40B, 40D, and 40E) disposed as described above, the semiconductor element 40D corresponds to an example of the “first semiconductor element” in the present disclosure, and the semiconductor element 40B corresponds to an example of the “second semiconductor element” in the present disclosure.

The semiconductor elements 4 (the semiconductor elements 40A, 40B, 40D, and 40E) shown in FIG. 26 have the following relationships regarding the distance between the centers of adjacent semiconductor elements 4 in the first direction x. A first distance D12, which is the distance between the center C1 of the semiconductor element 40D and the center C4 of the semiconductor element 40B that are located near the center in the first direction x, is greater than the second distance D21 between the center C1 of the semiconductor element 40D and the center C3 of the semiconductor element 40E that is adjacent to the semiconductor element 40D in the first direction x. The distance (the first distance D12) between the center C1 of the semiconductor element 40D and the center C4 of the semiconductor element 40B is also greater than a second distance D23, which is the distance between the center C4 of the semiconductor element 40B and the center C6 of the semiconductor element 40A that is adjacent to the semiconductor element 40B in the first direction x. In the present variation, the distance (the first distance D12) between the center C1 of the semiconductor element 40D and the center C4 of the semiconductor element 40B is at least twice the length (length L1) of a side of each semiconductor element 4 along the first direction x.

In the semiconductor device A31, the semiconductor elements 40A, 40B, 40D, and 40E include the semiconductor element 40D (the first semiconductor element) and the semiconductor element 40B (the second semiconductor element) that are located near the center in the first direction x. The distance (the first distance D12) between the center C1 of the semiconductor element 40D and the center C4 of the semiconductor element 40B is greater than the distance (the second distance D21) between the center C1 of the semiconductor element 40D and the center C3 of the semiconductor element 40E that is adjacent to the semiconductor element 40D in the first direction x, and is also greater than the distance (the second distance D23) between the center C4 of the semiconductor element 40B and the center C6 of the semiconductor element 40A that is adjacent to the semiconductor element 40B in the first direction x. This configuration can suppress the thermal interference between the semiconductor element 40D and the semiconductor element 40B that are located near the center among the semiconductor elements 40A, 40B, 40D, and 40E. This makes it possible to prevent the concentration of heat generated by the semiconductor elements 40A, 40B, 40D, and 40E and reduce the thermal resistance. As a result, the semiconductor device A31 can easily handle large currents and improve durability.

The center C1 of the semiconductor element 40D and the center C4 of the semiconductor element 40B are located at different positions in the second direction y perpendicular to the first direction x in which the semiconductor elements 40A, 40B, 40D, and 40E are disposed side by side. According to this configuration, heat generated by the semiconductor element 40D and the semiconductor element 40B that are located near the center among the semiconductor elements 40A, 40B, 40D, and 40E can be efficiently released to the surrounding environment, whereby thermal interference is further suppressed. In addition, the above configuration can increase the distance (the first distance D12) between the center C1 of the semiconductor element 40D and the center C4 of the semiconductor element 40B while preventing an increase in the dimension of the semiconductor device A31 in the first direction x.

The centers of semiconductor elements 4 adjacent in the first direction x out of the semiconductor elements 4 (the semiconductor elements 40A, 40B, 40D, and 40E) are located at different positions in the second direction y. According to this configuration, heat generated by the semiconductor elements 40A, 40B, 40D, and 40E can be efficiently released to the surrounding environment.

The distance (the first distance D12) between the center C1 of the semiconductor element 40D and the center C4 of the semiconductor element 40B is at least twice the length (length L1) of a side of each semiconductor element 4 along the first direction x. This configuration can appropriately suppress the thermal interference between the semiconductor element 40D and the semiconductor element 40B that are located near the center among the semiconductor elements 40A, 40B, 40D, and 40E. The above configuration is more preferable for reducing the thermal resistance of the semiconductor device A31.

### Second Variation of Third Embodiment

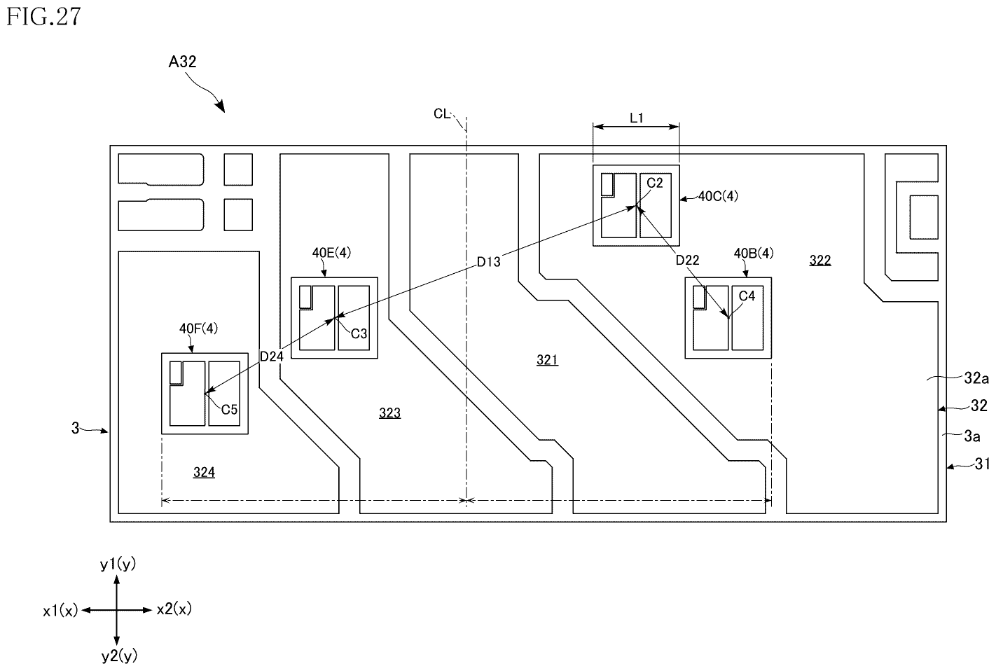

FIG. 27 shows a semiconductor device according to a second variation of the third embodiment. FIG. 27 is a schematic plan view showing the arrangement of the semiconductor elements 4 in a semiconductor device A32 of the present variation.

The semiconductor device A32 of the present variation is different from the semiconductor devices Al and A3 of the above embodiments mainly in the arrangement of the semiconductor elements 4. The semiconductor device A32 includes four semiconductor elements 4 (the semiconductor elements 40B, 40C, 40E, and 40F). The arrangement of the semiconductor elements 40B, 40C, 40E, and 40F is the same (or substantially the same) as that of the semiconductor elements 40B, 40C, 40E, and 40F in the semiconductor device A1.

In the semiconductor device A32 including four (even number) semiconductor elements 4, the semiconductor element 40C and the semiconductor element 40E are disposed near the center in the first direction x. As can be seen in the present variation, when the number of semiconductor elements 4 (the semiconductor elements 40B, 40C, 40E, and 40F) is even, two semiconductor elements, namely the semiconductor elements 40C and 40E, are disposed near the center in the first direction x among the semiconductor elements 4.

In the illustrated example, the semiconductor elements 40B, 40C, 40E, and 40F include those that are not aligned along the first direction x and located at different positions in the second direction y. The semiconductor element 40C is offset to the y1 side in the second direction y with respect to the semiconductor element 40B adjacent on the x2 side in the first direction x. In addition, the semiconductor element 40C is offset to the y1 side in the second direction y with respect to the semiconductor element 40E adjacent on the x1 side in the first direction x. The semiconductor element 40E is offset to the y1 side in the second direction y with respect to the semiconductor element 40F adjacent on the x1 side in the first direction x. The semiconductor element 40E is located at the same (or substantially the same) position as the semiconductor element 40B in the second direction y. Among the semiconductor elements 4 (the semiconductor elements 40B, 40C, 40E, and 40F) disposed as described above, the semiconductor element 40E corresponds to an example of the “first semiconductor element” in the present disclosure, and the semiconductor element 40C corresponds to an example of the “second semiconductor element” in the present disclosure.

The semiconductor elements 4 (the semiconductor elements 40B, 40C, 40E, and 40F) shown in FIG. 27 have the following relationships regarding the distance between the centers of adjacent semiconductor elements 4 in the first direction x. A first distance D13, which is the distance between the center C3 of the semiconductor element 40E and the center C2 of the semiconductor element 40C that are located near the center in the first direction x, is greater than a second distance D24, which is the distance between the center C3 of the semiconductor element 40E and the center C5 of the semiconductor element 40F that is adjacent to the semiconductor element 40E in the first direction x. The distance (the first distance D13) between the center C3 of the semiconductor element 40E and the center C2 of the semiconductor element 40C is also greater than the second distance D22 between the center C2 of the semiconductor element 40C and the center C4 of the semiconductor element 40B that is adjacent to the semiconductor element 40C in the first direction x. In the present variation, the distance (the first distance D13) between the center C3 of the semiconductor element 40E and the center C2 of the semiconductor element 40C is at least twice the length (length L1) of a side of each semiconductor element 4 along the first direction x.

In the semiconductor device A32, the semiconductor elements 40B, 40C, 40E, and 40F include the semiconductor element 40E (the first semiconductor element) and the semiconductor element 40C (the second semiconductor element) that are located near the center in the first direction x. The distance (the first distance D13) between the center C3 of the semiconductor element 40E and the center C2 of the semiconductor element 40C is greater than the distance (the second distance D24) between the center C3 of the semiconductor element 40E and the center C5 of the semiconductor element 40F that is adjacent to the semiconductor element 40E in the first direction x, and is also greater than the distance (the second distance D22) between the center C2 of the semiconductor element 40C and the center C4 of the semiconductor element 40B that is adjacent to the semiconductor element 40C in the first direction x. This configuration can suppress the thermal interference between the semiconductor element 40E and the semiconductor element 40C that are located near the center among the semiconductor elements 40B, 40C, 40E, and 40F. This makes it possible to prevent the concentration of heat generated by the semiconductor elements 40B, 40C, 40E, and 40F and reduce the thermal resistance. As a result, the semiconductor device A32 can easily handle large currents and improve durability.

The center C3 of the semiconductor element 40E and the center C2 of the semiconductor element 40C are located at different positions in the second direction y perpendicular to the first direction x in which the semiconductor elements 40B, 40C, 40E, and 40F are disposed side by side. According to this configuration, heat generated by the semiconductor element 40E and the semiconductor element 40C that are located near the center among the semiconductor elements 40B, 40C, 40E, and 40F can be efficiently released to the surrounding environment, whereby thermal interference is further suppressed. In addition, the above configuration can increase the distance (the first distance D13) between the center C3 of the semiconductor element 40E and the center C2 of the semiconductor element 40C while preventing an increase in the dimension of the semiconductor device A32 in the first direction x.

The centers of semiconductor elements 4 adjacent in the first direction x out of the semiconductor elements 4 (the semiconductor elements 40B, 40C, 40E, and 40F) are located at different positions in the second direction y. According to this configuration, heat generated by the semiconductor elements 40B, 40C, 40E, and 40F can be efficiently released to the surrounding environment.

The distance (the first distance D13) between the center C3 of the semiconductor element 40E and the center C2 of the semiconductor element 40C is at least twice the length (length L1) of a side of each semiconductor element 4 along the first direction x. This configuration can appropriately suppress the thermal interference between the semiconductor element 40E and the semiconductor element 40C that are located near the center among the semiconductor elements 40B, 40C, 40E, and 40F. The above configuration is more preferable for reducing the thermal resistance of the semiconductor device A32.

### Third Variation of Third Embodiment

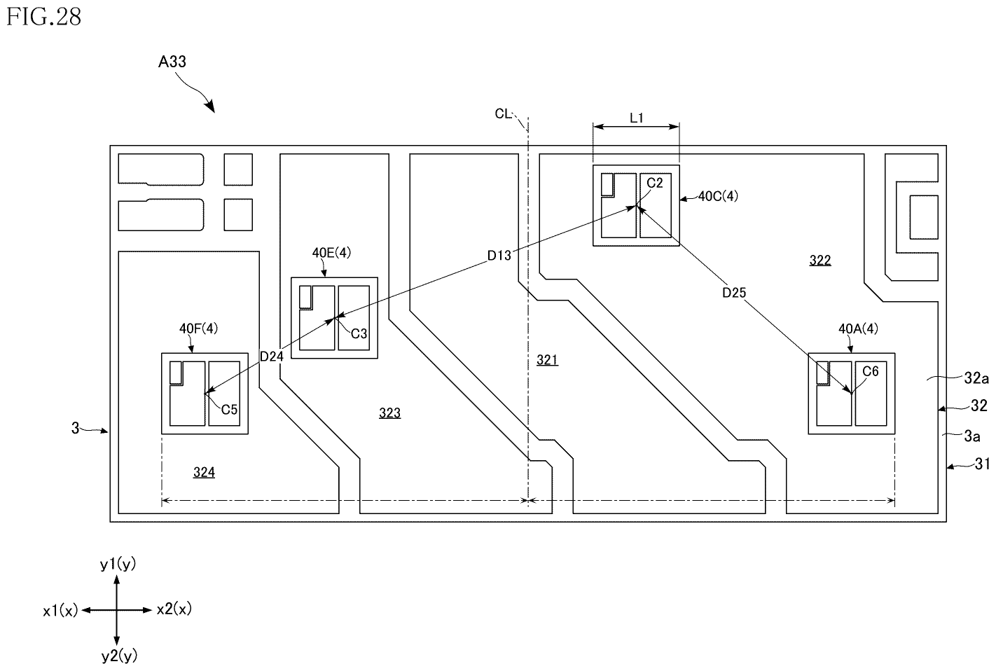

FIG. 28 shows a semiconductor device according to a third variation of the third embodiment. FIG. 28 is a schematic plan view showing the arrangement of the semiconductor elements 4 in a semiconductor device A33 of the present variation.

The semiconductor device A33 of the present variation is different from the semiconductor devices A1 and A3 of the above embodiments mainly in the arrangement of the semiconductor elements 4. The semiconductor device A33 includes four semiconductor elements 4 (the semiconductor elements 40A, 40C, 40E, and 40F). The arrangement of the semiconductor elements 40A, 40C, 40E, and 40F is the same (or substantially the same) as that of the semiconductor elements 40A, 40C, 40E, and 40F in the semiconductor device A1.

In the semiconductor device A33 including four (even number) semiconductor elements 4, the semiconductor element 40C and the semiconductor element 40E are disposed near the center in the first direction x. As can be seen in the present variation, when the number of semiconductor elements 4 (the semiconductor elements 40A, 40C, 40E, and 40F) is even, two semiconductor elements, namely the semiconductor elements 40C and 40E, are disposed near the center in the first direction x among the semiconductor elements 4.

In the illustrated example, the semiconductor elements 40A, 40C, 40E, and 40F include those that are not aligned along the first direction x and located at different positions in the second direction y. The semiconductor element 40C is offset to the y1 side in the second direction y with respect to the semiconductor element 40A adjacent on the x2 side in the first direction x. In addition, the semiconductor element 40C is offset to the y1 side in the second direction y with respect to the semiconductor element 40E adjacent on the x1 side in the first direction x. The semiconductor element 40E is offset to the y1 side in the second direction y with respect to the semiconductor element 40F adjacent on the x1 side in the first direction x. The semiconductor element 40F is located at the same (or substantially the same) position as the semiconductor element 40A in the second direction y. Among the semiconductor elements 4 (the semiconductor elements 40A, 40C, 40E, and 40F) disposed as described above, the semiconductor element 40E corresponds to an example of the “first semiconductor element” in the present disclosure, and the semiconductor element 40C corresponds to an example of the “second semiconductor element” in the present disclosure. A third conductor 323 on which the semiconductor element 40E (the first semiconductor element) is disposed corresponds to an example of the “first portion” in the present disclosure, and the second conductor 322 on which the semiconductor element 40C (the second semiconductor element) is disposed corresponds to an example of the “second portion” in the present disclosure.

The semiconductor elements 4 (the semiconductor elements 40A, 40C, 40E, and 40F) shown in FIG. 28 have the following relationships regarding the distance between the centers of adjacent semiconductor elements 4 in the first direction x. The first distance D13 between the center C3 of the semiconductor element 40E and the center C2 of the semiconductor element 40C that are located near the center in the first direction x is greater than the second distance D24 between the center C3 of the semiconductor element 40E and the center C5 of the semiconductor element 40F that is adjacent to the semiconductor element 40E in the first direction x. The distance (the first distance D13) between the center C3 of the semiconductor element 40E and the center C2 of the semiconductor element 40C is also greater than a second distance D25, which is the distance between the center C2 of the semiconductor element 40C and the center C6 of the semiconductor element 40A that is adjacent to the semiconductor element 40C in the first direction x. In the present variation, the distance (the first distance D13) between the center C3 of the semiconductor element 40E and the center C2 of the semiconductor element 40C is at least twice the length (length L1) of a side of each semiconductor element 4 along the first direction x.

In the semiconductor device A33, the semiconductor elements 40A, 40C, 40E, and 40F include the semiconductor element 40E (the first semiconductor element) and the semiconductor element 40C (the second semiconductor element) that are located near the center in the first direction x. The distance (the first distance D13) between the center C3 of the semiconductor element 40E and the center C2 of the semiconductor element 40C is greater than the distance (the second distance D24) between the center C3 of the semiconductor element 40E and the center C5 of the semiconductor element 40F that is adjacent to the semiconductor element 40E in the first direction x, and is also greater than the distance (the second distance D25) between the center C2 of the semiconductor element 40C and the center C6 of the semiconductor element 40A that is adjacent to the semiconductor element 40C in the first direction x. This configuration can suppress the thermal interference between the semiconductor element 40E and the semiconductor element 40C that are located near the center among the semiconductor elements 40A, 40C, 40E, and 40F. This makes it possible to prevent the concentration of heat generated by the semiconductor elements 40A, 40C, 40E, and 40F and reduce the thermal resistance. As a result, the semiconductor device A33 can easily handle large currents and improve durability.

The center C3 of the semiconductor element 40E and the center C2 of the semiconductor element 40C are located at different positions in the second direction y perpendicular to the first direction x in which the semiconductor elements 40A, 40C, 40E, and 40F are disposed side by side. According to this configuration, heat generated by the semiconductor element 40E and the semiconductor element 40C that are located near the center among the semiconductor elements 40A, 40C, 40E, and 40F can be efficiently released to the surrounding environment, whereby thermal interference is further suppressed. In addition, the above configuration can increase the distance (the first distance D13) between the center C3 of the semiconductor element 40E and the center C2 of the semiconductor element 40C while preventing an increase in the dimension of the semiconductor device A33 in the first direction x.

The centers of semiconductor elements 4 adjacent in the first direction x out of the semiconductor elements 4 (the semiconductor elements 40A, 40C, 40E, and 40F) are located at different positions in the second direction y. According to this configuration, heat generated by the semiconductor elements 40A, 40C, 40E, and 40F can be efficiently released to the surrounding environment.

The distance (the first distance D13) between the center C3 of the semiconductor element 40E and the center C2 of the semiconductor element 40C is at least twice the length (length L1) of a side of each semiconductor element 4 along the first direction x. This configuration can appropriately suppress the thermal interference between the semiconductor element 40E and the semiconductor element 40C that are located near the center among the semiconductor elements 40A, 40C, 40E, and 40F. The above configuration is more preferable for reducing the thermal resistance of the semiconductor device A33.

The supporting conductor 32 includes the third conductor 323 (the first portion) and the second conductor 322 (the second portion) that are spaced apart from each other. Of the semiconductor elements 40A, 40C, 40E, and 40F, only the semiconductor element 40E (the first semiconductor element) is disposed on the third conductor 323. Of the semiconductor elements 40A, 40C, 40E, and 40F, the semiconductor element 40C (the second semiconductor element) and the semiconductor element 40A adjacent to the semiconductor element 40C are disposed on the second conductor 322. The center C3 of the semiconductor element 40E (the first semiconductor element) is offset to the y1 side in the second direction y from the center of either of the semiconductor elements 40A and 40F in the second direction y. The center C2 of the semiconductor element 40C (the second semiconductor element) is offset to the y1 side in the second direction y from the center C3 of the semiconductor element 40E. Heat generated by the semiconductor element 40C and the semiconductor element 40A that are disposed on the common second conductor 322 tends to be trapped on the second conductor 322, and the interference of heat generated by the semiconductor element 40C and the semiconductor element 40A tends to cause a rise in the temperature of the second conductor 322. As described above, the semiconductor element 40C is disposed farthest to the y1 side in the second direction y among all the semiconductor elements 40A, 40C, 40E, and 40F. According to this layout, the second conductor 322 on which the semiconductor element 40C is mounted can efficiently release heat generated by the semiconductor element 40C to the surroundings of the semiconductor element 40C. This makes it possible to suppress the thermal interference between the semiconductor elements 40E, 40C, and 40A, thereby reducing the thermal resistance of the semiconductor device A33.

### Fourth Variation of Third Embodiment

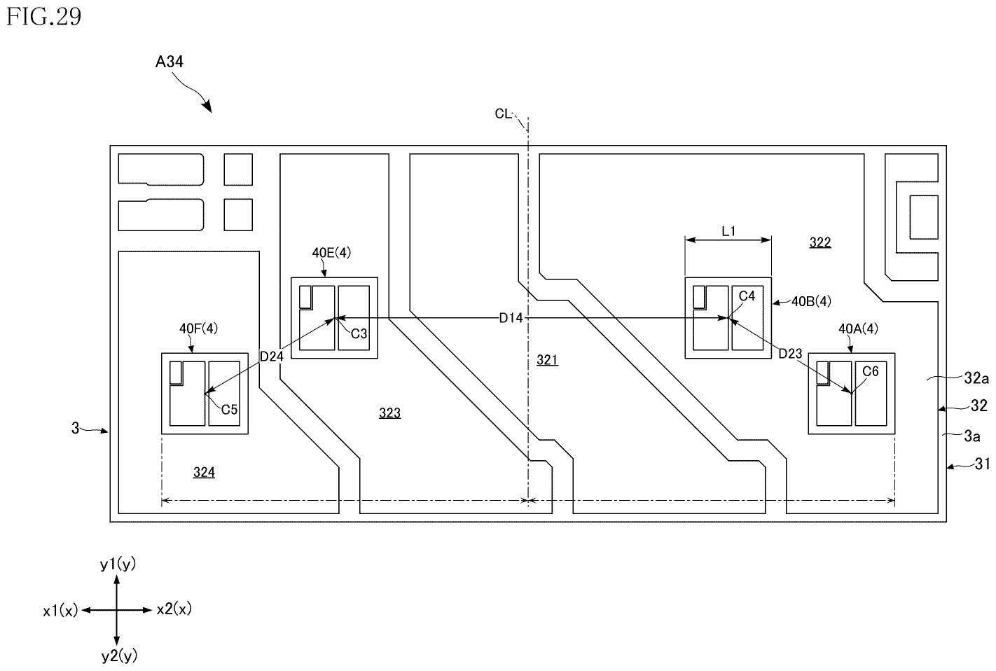

FIG. 29 shows a semiconductor device according to a fourth variation of the third embodiment. FIG. 29 is a schematic plan view showing the arrangement of the semiconductor elements 4 in a semiconductor device A34 of the present variation.

The semiconductor device A34 of the present variation is different from the semiconductor devices A1 and A3 of the above embodiments mainly in the arrangement of the semiconductor elements 4. The semiconductor device A34 includes four semiconductor elements 4 (the semiconductor elements 40A, 40B, 40E, and 40F). The arrangement of the semiconductor elements 40A, 40B, 40E, and 40F is the same (or substantially the same) as that of the semiconductor elements 40A, 40B, 40E, and 40F in the semiconductor device A1.

In the semiconductor device A34 including four (even number) semiconductor elements 4, the semiconductor element 40B and the semiconductor element 40E are disposed near the center in the first direction x. As can be seen in the present variation, when the number of semiconductor elements 4 (the semiconductor elements 40A, 40B, 40E, and 40F) is even, two semiconductor elements, namely the semiconductor elements 40B and 40E, are disposed near the center in the first direction x among the semiconductor elements 4.

In the illustrated example, the semiconductor elements 40A, 40B, 40E, and 40F include those that are not aligned along the first direction x and located at different positions in the second direction y. The semiconductor element 40B is offset to the y1 side in the second direction y with respect to the semiconductor element 40A adjacent on the x2 side in the first direction x. The semiconductor element 40B is adjacent to the semiconductor element 40E on the x1 side in the first direction x, and is located at the same (or substantially the same) position as the semiconductor element 40E in the second direction y. The semiconductor element 40E is offset to the y1 side in the second direction y with respect to the semiconductor element 40F adjacent on the x1 side in the first direction x. The semiconductor element 40F is located at the same (or substantially the same) position as the semiconductor element 40A in the second direction y. Among the semiconductor elements 4 (the semiconductor elements 40A, 40B, 40E, and 40F) disposed as described above, the semiconductor element 40E corresponds to an example of the “first semiconductor element” in the present disclosure, and the semiconductor element 40B corresponds to an example of the “second semiconductor element” in the present disclosure.

The semiconductor elements 4 (the semiconductor elements 40A, 40B, 40E, and 40F) shown in FIG. 29 have the following relationships regarding the distance between the centers of adjacent semiconductor elements 4 in the first direction x. A first distance D14 between the center C3 of the semiconductor element 40E and the center C4 of the semiconductor element 40B that are located near the center in the first direction x is greater than the second distance D24 between the center C3 of the semiconductor element 40E and the center C5 of the semiconductor element 40F that is adjacent to the semiconductor element 40E in the first direction x. The distance (the first distance D14) between the center C3 of the semiconductor element 40E and the center C4 of the semiconductor element 40B is also greater than the second distance D23 between the center C4 of the semiconductor element 40B and the center C6 of the semiconductor element 40A that is adjacent to the semiconductor element 40B in the first direction x. In the present variation, the distance (the first distance D14) between the center C3 of the semiconductor element 40E and the center C4 of the semiconductor element 40B is at least twice the length (length L1) of a side of each semiconductor element 4 along the first direction x.

In the semiconductor device A34, the semiconductor elements 40A, 40B, 40E, and 40F include the semiconductor element 40E (the first semiconductor element) and the semiconductor element 40B (the second semiconductor element) that are located near the center in the first direction x. The distance (the first distance D14) between the center C3 of the semiconductor element 40E and the center C4 of the semiconductor element 40B is greater than the distance (the second distance D24) between the center C3 of the semiconductor element 40E and the center C5 of the semiconductor element 40F that is adjacent to the semiconductor element 40E in the first direction x, and is also greater than the distance (the second distance D23) between the center C4 of the semiconductor element 40B and the center C6 of the semiconductor element 40A that is adjacent to the semiconductor element 40B in the first direction x. This configuration can suppress the thermal interference between the semiconductor element 40E and the semiconductor element 40B that are located near the center among the semiconductor elements 40A, 40B, 40E, and 40F. This makes it possible to prevent the concentration of heat generated by the semiconductor elements 40A, 40B, 40E, and 40F and reduce the thermal resistance. As a result, the semiconductor device A34 can easily handle large currents and improve durability.

The distance (the first distance D14) between the center C3 of the semiconductor element 40E and the center C4 of the semiconductor element 40B is at least twice the length (length L1) of a side of each semiconductor element 4 along the first direction x. This configuration can appropriately suppress the thermal interference between the semiconductor element 40E and the semiconductor element 40B that are located near the center among the semiconductor elements 40A, 40B, 40E, and 40F. The above configuration is more preferable for reducing the thermal resistance of the semiconductor device A34.

The semiconductor device according to the present disclosure is not limited to the embodiments described above. Various design changes can be made to the specific configurations of the elements of the semiconductor device according to the present disclosure.

Although the present embodiments have been described with an example where the semiconductor devices, such as the semiconductor device A1, are configured as molded modules in which the sealing resin 8 is formed by molding, the present disclosure is not limited to this. For example, the semiconductor device of the present disclosure may be configured as a case module. In this case, the inner space of the case may be filled with an insulating material, such as silicone gel, that functions as a sealing resin.

The present disclosure includes the embodiments described in the following clauses.

### Clause 1

A semiconductor device comprising:

a conductor including a first obverse surface facing a first side in a thickness direction, and a first reverse surface facing an opposite side from the first obverse surface;

a plurality of semiconductor elements including four or more semiconductor elements disposed on the first obverse surface; and

a sealing resin covering the plurality of semiconductor elements and at least a part of the conductor,

wherein the plurality of semiconductor elements are disposed side by side in a first direction perpendicular to the thickness direction,

when a number of semiconductor elements is even,

the plurality of semiconductor elements include a first semiconductor element and a second semiconductor element that are located near a center in the first direction,

a first distance, which is a distance between a center of the first semiconductor element and a center of the second semiconductor element, is greater than a second distance, which is a distance between the center of one of the first semiconductor element and the second semiconductor element and a center of another one of the semiconductor elements that is adjacent to the one of the first semiconductor element and the second semiconductor element in the first direction,

when a number of semiconductor elements is odd,

the plurality of semiconductor elements include a third semiconductor element located near the center in the first direction, a fourth semiconductor element adjacent to the third semiconductor element on a first side in the first direction, and a fifth semiconductor element adjacent to the third semiconductor element on a second side in the first direction, and

a third distance, which is a distance between a center of the third semiconductor element and a center of the fourth semiconductor element, and a fourth distance, which is a distance between the center of the third semiconductor element and a center of the fifth semiconductor element, are each greater than a fifth distance, which is a distance between the center of one of the fourth semiconductor element and the fifth semiconductor element and a center of another one of the semiconductor elements that is adjacent to the one of the fourth semiconductor element and the fifth semiconductor element in the first direction.

### Clause 2

The semiconductor device according to clause 1, wherein when the number of semiconductor elements is even,

the center of the first semiconductor element and the center of the second semiconductor element are located at different positions in a second direction perpendicular to the thickness direction and the first direction, and

when the number of semiconductor elements is odd,

the center of the third semiconductor element is located at a different position in the second direction from the center of the fourth semiconductor element and from the center of the fifth semiconductor element.

### Clause 3

The semiconductor device according to clause 2, wherein the centers of semiconductor elements adjacent in the first direction out of the plurality of semiconductor elements are located at different positions in the second direction.

### Clause 4

The semiconductor device according to any of clauses 1 to 3, wherein when the number of semiconductor elements is even,

the first distance is greater than a sixth distance, which is a distance between the centers of other semiconductor elements adjacent to each other in the first direction out of the plurality of semiconductor elements, and

when the number of semiconductor elements is odd,

each of the third distance and the fourth distance is greater than a seventh distance, which is a distance between the centers of other semiconductor elements adjacent to each other in the first direction out of the plurality of semiconductor elements.

### Clause 5

The semiconductor device according to clause 4, wherein when the number of semiconductor elements is even,

the second distance is greater than the sixth distance, and

when the number of semiconductor elements is odd,

the fifth distance is greater than the seventh distance.

### Clause 6

The semiconductor device according to clause 5, wherein when the number of semiconductor elements is even,

the sixth distance decreases as the other semiconductor elements adjacent to each other in the first direction are located farther from the center in the first direction, and

when the number of semiconductor elements is odd,

the seventh distance decreases as the other semiconductor elements adjacent to each other in the first direction are located farther from the center in the first direction.

### Clause 7

The semiconductor device according to any of clauses 1 to 6, wherein when the number of semiconductor elements is even,

the first distance is at least twice a length of a side of each semiconductor element along the first direction, and

when the number of semiconductor elements is odd,

each of the third distance and the fourth distance is at least twice the length of a side of each semiconductor element along the first direction.

### Clause 8

The semiconductor device according to clause 2, wherein the conductor includes a first portion and a second portion that are spaced apart from each other,

of the plurality of semiconductor elements, only the first semiconductor element is disposed on the first portion,

of the plurality of semiconductor elements, the second semiconductor element and a semiconductor element adjacent to the second semiconductor element are disposed on the second portion,

the center of the first semiconductor element is offset to a first side in the second direction from the center of any other semiconductor element among the plurality of semiconductor elements in the second direction, and

the center of the second semiconductor element is offset to the first side in the second direction from the center of the first semiconductor element in the second direction.

### Clause 9

The semiconductor device according to any of clauses 1 to 8, further comprising a support including a second obverse surface facing the first side in the thickness direction, and a second reverse surface facing an opposite side from the second obverse surface,

wherein the first reverse surface of the conductor is bonded to the second obverse surface.

### Clause 10

The semiconductor device according to clause 9, wherein the support includes an insulating substrate including the second obverse surface, and a metal layer bonded to a surface of the insulating substrate located on an opposite side from the second obverse surface, the metal layer including the second reverse surface.

### Clause 11

The semiconductor device according to clause 10, wherein the insulating substrate is made of a ceramic material.

### Clause 12

The semiconductor device according to clause 9, wherein the conductor is formed from a lead, and

the support is formed from the insulating substrate.

### Clause 13

The semiconductor device according to any of clauses 9 to 12, wherein each of the plurality of semiconductor elements is a switching element.

### Clause 14

The semiconductor device according to clause 13, wherein each of the plurality of semiconductor elements includes an element obverse surface facing the first side in the thickness direction, an element reverse surface facing a second side in the thickness direction, a source electrode and a gate electrode that are disposed on the element obverse surface, and a drain electrode disposed on the element reverse surface.

### Clause 15

The semiconductor device according to clause 10 or 11, wherein a structure made up of the conductor and the support has a thermal capacity of 0.01 to 15 J/K, and

each of the plurality of semiconductor elements has a thermal capacity of 0.0001 to 0.5 J/K.

### Clause 16

The semiconductor device according to clause 10 or 11, wherein a structure made up of the conductor and the support has a thermal resistance of 0.0003 to 1.5 K/W, and

each of the plurality of semiconductor elements has a thermal resistance of 0.0003 to 1.5 K/W.

### Clause 17

The semiconductor device according to clause 13 or 14, wherein each of the plurality of semiconductor elements includes at least one of a wide bandgap semiconductor and an ultra-wide bandgap semiconductor.

### Clause 18

A semiconductor device assembly comprising:

the semiconductor device according to any of clauses 9 to 17;

a cooler; and

a cooling unit that cools the cooler,

wherein the second reverse surface of the support is exposed from the sealing resin, and

the cooler includes a portion in contact with the second reverse surface.

### Clause 19

The semiconductor device assembly according to clause 18, further comprising a control unit,

wherein the semiconductor device includes a temperature detection element disposed on the second obverse surface of the support, and

the control unit controls the cooling unit based on a temperature detected by the temperature detection element.

### Clause 20

The semiconductor device assembly according to clause 19, further comprising a heating unit that heats the cooler,

the control unit controls the heating unit based on a temperature detected by the temperature detection element.

### Clause 21

A vehicle comprising a power conversion device configured to include the semiconductor device according to clause 13 or 14.

REFERENCE NUMERALS

| | |
|---|---|
| A1, A2, A3, A31, A32, A33, and A34: Semiconductor device | |
| B1, B11: Vehicle | B2, B21: Semiconductor device assembly |
| 1, 11-15: Lead | 110: Mounting portion (Conductor, Second portion) |
| 120: Mounting portion (Conductor, First portion) | |
| 130, 140: Mounting portion (Conductor) | |
| 18: Bonding material | 19: Conductive bonding material |
| 2, 21-23: Lead | 28: Conductive bonding material |
| 3: Support | 3a: Second obverse surface |
| 3b: Second reverse surface | 30, 31: Insulating substrate |
| 32: Supporting conductor (Conductor) | 32a: First obverse surface |
| 32b: First reverse surface | 321: First conductor |
| 322: Second conductor | 323: Third conductor |
| 324: Fourth conductor | 325: Fifth conductor |
| 326: Sixth conductor | 327: Seventh conductor |
| 328: Eighth conductor | 33: Metal layer |
| 4, 40A-40N, 40P-40R: Semiconductor element | 41: Element obverse surface |
| 42: Element reverse surface | 43: Source electrode |
| 44: Gate electrode | 45: Drain electrode |
| 47: Conductive bonding material | 5: Wiring portion |
| 501: Wiring | 502: Pad portion |
| 511-515, 521: Bonding portion | 6: Thermistor |
| 62: Insulating member | 63: Conductive bonding material |
| 71-74: Wire | 8: Sealing resin |
| 81: Resin obverse surface | 82: Resin reverse surface |
| 83-86: Resin side surface | 831, 841: Recess |
| 870: Charging facility | 871: AC-DC conversion device (Power conversion device) |
| 872: Power receiving device | 873: Storage battery |
| 874: Drive system | 875: DC-DC conversion device (Power conversion device) |
| 91: Cooler | 911: Mounting surface |
| 912: Flow passage | 913: Mounting hole |
| 92: Mounting member | 93: Fastener |
| 94: Control unit | 95: Cooling unit |
| 96: Heating unit | D1, D12, D13, D14: First distance |
| D21, D21, D23, D24, D25: Second distance | D3: Third distance |
| D4: Fourth distance | D51, D52: Fifth distance |
| D61-D64: Sixth distance | D71-D74: Seventh distance |

1. A semiconductor device comprising:
a conductor including a first obverse surface facing a first side in a thickness direction, and a first reverse surface facing an opposite side from the first obverse surface;
a plurality of semiconductor elements including four or more semiconductor elements disposed on the first obverse surface; and
a sealing resin covering the plurality of semiconductor elements and at least a part of the conductor,
wherein the plurality of semiconductor elements are disposed side by side in a first direction perpendicular to the thickness direction,
when a number of semiconductor elements is even,
the plurality of semiconductor elements include a first semiconductor element and a second semiconductor element that are located near a center in the first direction,
a first distance, which is a distance between a center of the first semiconductor element and a center of the second semiconductor element, is greater than a second distance, which is a distance between the center of one of the first semiconductor element and the second semiconductor element and a center of another one of the semiconductor elements that is adjacent to the one of the first semiconductor element and the second semiconductor element in the first direction,
when a number of semiconductor elements is odd,
the plurality of semiconductor elements include a third semiconductor element located near the center in the first direction, a fourth semiconductor element adjacent to the third semiconductor element on a first side in the first direction, and a fifth semiconductor element adjacent to the third semiconductor element on a second side in the first direction, and
a third distance, which is a distance between a center of the third semiconductor element and a center of the fourth semiconductor element, and a fourth distance, which is a distance between the center of the third semiconductor element and a center of the fifth semiconductor element, are each greater than a fifth distance, which is a distance between the center of one of the fourth semiconductor element and the fifth semiconductor element and a center of another one of the semiconductor elements that is adjacent to the one of the fourth semiconductor element and the fifth semiconductor element in the first direction.

2. The semiconductor device according to claim 1, wherein when the number of semiconductor elements is even,
the center of the first semiconductor element and the center of the second semiconductor element are located at different positions in a second direction perpendicular to the thickness direction and the first direction, and
when the number of semiconductor elements is odd,
the center of the third semiconductor element is located at a different position in the second direction from the center of the fourth semiconductor element and from the center of the fifth semiconductor element.

3. The semiconductor device according to claim 2, wherein the centers of semiconductor elements adjacent in the first direction out of the plurality of semiconductor elements are located at different positions in the second direction.

4. The semiconductor device according to claim 1, wherein when the number of semiconductor elements is even,
the first distance is greater than a sixth distance, which is a distance between the centers of other semiconductor elements adjacent to each other in the first direction out of the plurality of semiconductor elements, and
when the number of semiconductor elements is odd,
each of the third distance and the fourth distance is greater than a seventh distance, which is a distance between the centers of other semiconductor elements adjacent to each other in the first direction out of the plurality of semiconductor elements.

5. The semiconductor device according to claim 4, wherein when the number of semiconductor elements is even,
the second distance is greater than the sixth distance, and
when the number of semiconductor elements is odd,
the fifth distance is greater than the seventh distance.

6. The semiconductor device according to claim 5, wherein when the number of semiconductor elements is even,
the sixth distance decreases as the other semiconductor elements adjacent to each other in the first direction are located farther from the center in the first direction, and
when the number of semiconductor elements is odd,
the seventh distance decreases as the other semiconductor elements adjacent to each other in the first direction are located farther from the center in the first direction.

7. The semiconductor device according to claim 1, wherein when the number of semiconductor elements is even,
the first distance is at least twice a length of a side of each semiconductor element along the first direction, and
when the number of semiconductor elements is odd,
each of the third distance and the fourth distance is at least twice the length of a side of each semiconductor element along the first direction.

8. The semiconductor device according to claim 2, wherein the conductor includes a first portion and a second portion that are spaced apart from each other,
of the plurality of semiconductor elements, only the first semiconductor element is disposed on the first portion,
of the plurality of semiconductor elements, the second semiconductor element and a semiconductor element adjacent to the second semiconductor element are disposed on the second portion,
the center of the first semiconductor element is offset to a first side in the second direction from the center of any other semiconductor element among the plurality of semiconductor elements in the second direction, and
the center of the second semiconductor element is offset to the first side in the second direction from the center of the first semiconductor element in the second direction.

9. The semiconductor device according to claim 1, further comprising a support including a second obverse surface facing the first side in the thickness direction, and a second reverse surface facing an opposite side from the second obverse surface,
wherein the first reverse surface of the conductor is bonded to the second obverse surface.

10. The semiconductor device according to claim 9, wherein the support includes an insulating substrate including the second obverse surface, and a metal layer bonded to a surface of the insulating substrate located on an opposite side from the second obverse surface, the metal layer including the second reverse surface.

11. The semiconductor device according to claim 10, wherein the insulating substrate is made of a ceramic material.

12. The semiconductor device according to claim 9, wherein the conductor is formed from a lead, and
the support is formed from the insulating substrate.

13. The semiconductor device according to claim 9, wherein each of the plurality of semiconductor elements is a switching element.

14. The semiconductor device according to claim 13, wherein each of the plurality of semiconductor elements includes an element obverse surface facing the first side in the thickness direction, an element reverse surface facing a second side in the thickness direction, a source electrode and a gate electrode that are disposed on the element obverse surface, and a drain electrode disposed on the element reverse surface.

15. The semiconductor device according to claim 10, wherein a structure made up of the conductor and the support has a thermal capacity of 0.01 to 15 J/K, and
each of the plurality of semiconductor elements has a thermal capacity of 0.0001 to 0.5 J/K.

16. The semiconductor device according to claim 10, wherein a structure made up of the conductor and the support has a thermal resistance of 0.0003 to 1.5 K/W, and
each of the plurality of semiconductor elements has a thermal resistance of 0.0003 to 1.5 K/W.

17. The semiconductor device according to claim 13, wherein each of the plurality of semiconductor elements includes at least one of a wide bandgap semiconductor and an ultra-wide bandgap semiconductor.

18. A semiconductor device assembly comprising: the semiconductor device according to claim 9;
a cooler; and
a cooling unit that cools the cooler,
wherein the second reverse surface of the support is exposed from the sealing resin, and the cooler includes a portion in contact with the second reverse surface.

19. A vehicle comprising a power conversion device configured to include the semiconductor device according to claim 13.
